(19) United States
(12) Patent Application Publication
(10) Pub. No.: US 2024/0145003 A1
(43) Pub. Date: May 2, 2024

(54) MEMORY BLOCK AND MANUFACTURING METHOD THEREOF

(71) Applicant: WUHAN XINXIN SEMICONDUCTOR MANUFACTURING CO., LTD., Wuhan (CN)

(72) Inventor: Kaiwei CAO, Wuhan (CN)

(21) Appl. No.: 18/145,031

(22) Filed: Dec. 22, 2022

(30) Foreign Application Priority Data
Nov. 1, 2022 (CN) 202211360792.4

(51) Int. Cl. G11C 16/04; G11C 16/08; H01L 27/088

(52) U.S. Cl. CPC G11C 16/0483; G11C 16/08; H01L 27/088

(57) ABSTRACT

The present disclosure provides a memory block and its manufacturing method. The memory block includes a memory array including memory subarray layers, and each memory subarray layer includes a drain region semiconductor layer, a channel semiconductor layer, and a source region semiconductor layer stacked; the drain region semiconductor layer includes drain region semiconductor strips, the channel semiconductor layer includes channel semiconductor strips, and the source region semiconductor layer includes source region semiconductor strips, distributed along a row direction and extending along a column direction; in the memory subarray layers, the drain region semiconductor strips channel semiconductor strips, and source region semiconductor strips disposed in a same column are a column of semiconductor strip structures.

### CROSS REFERENCE

The present disclosure claims priority of Chinese Patent Application No. 202211360792.4, filed on Nov. 1, 2022, the entire contents of which are hereby incorporated by reference in its entirety.

### TECHNICAL FIELD

The present disclosure relates to the field of semiconductor manufacturing technologies, and in particular to a memory block and a manufacturing method thereof.

### BACKGROUND

Two-dimensional (2D) memory blocks are prevalent in electronic devices and may include, for example, NOR-flash memory arrays, NAND-flash memory arrays, dynamic random-access memory (DRAM) arrays, etc. However, the 2D memory arrays are approaching the scaling limit and the storage density cannot be further increased.

In addition, in a NOR-flash memory block, the source region as a bit line (BL) and the drain region as a sense line (SL) are usually led by a connection line at a respective end (i.e., an edge portion of the memory block) and then connected to a connection pad on the edge portion of the memory block for signal transmission, respectively. However, since the source region and drain region are generally long and made of semiconductor material with large resistance, which may greatly affect the speed of read (RD), program (PGM), and other operations performed by the memory block.

### SUMMARY OF THE DISCLOSURE

The present disclosure provides a memory block and its manufacturing method.

An aspect adopted by the present disclosure is to provide a memory block, including: a memory array, including: a plurality of memory cells distributed in a three-dimensional array; wherein the memory array includes a plurality of memory subarray layers stacked sequentially along a height direction, and each memory subarray layer includes a drain region semiconductor layer, a channel semiconductor layer, and a source region semiconductor layer stacked along the height direction; in each memory subarray layer, the drain region semiconductor layer includes a plurality of drain region semiconductor strips distributed along a row direction, the channel semiconductor layer includes a plurality of channel semiconductor strips distributed along a row direction, and the source region semiconductor layer includes a plurality of source region semiconductor strips distributed along a row direction; each drain region semiconductor strip, each channel semiconductor strip, and each source region semiconductor strip extend along a column direction; a plurality of gate strips distributed along the column direction are arranged on each side of each column drain region semiconductor strip, channel semiconductor strip, and source region semiconductor strip, each gate strip extending along the height direction; in the plurality of memory subarray layers, the plurality of drain region semiconductor strips, the plurality of channel semiconductor strips, and the plurality of source region semiconductor strips, that are disposed in a same column, are defined as a column of the semiconductor strip structures; and a plurality of drain/source connection terminal arrays; wherein each of the plurality of drain/source connection terminal arrays is arranged at a predetermined interval in the column direction; each drain/source connection terminal array includes a plurality of drain/source connection terminal subarrays arranged along the row direction, and each drain/source connection terminal subarray includes a plurality of drain/source connection terminals; each drain/source connection terminal is connected to a corresponding drain/source region semiconductor strip of a corresponding column of the semiconductor strip structures; wherein in a same column of the semiconductor strip structures, each drain/source region semiconductor strip is connected to several of the plurality of drain/source connection terminals of several of the plurality of drain/source connection terminal subarrays of several of the plurality of drain/source connection terminal arrays.

Another aspect adopted by the present disclosure is to provide a memory block, including: memory array, including: a plurality of memory cells distributed in a three-dimensional array; wherein the memory array includes a plurality of memory subarray layers stacked sequentially along a height direction, and each memory subarray layer includes a drain region semiconductor layer, a channel semiconductor layer, and a source region semiconductor layer stacked along the height direction; in each memory subarray layer, the drain region semiconductor layer includes a plurality of drain region semiconductor strips distributed along a row direction, the channel semiconductor layer includes a plurality of channel semiconductor strips distributed along a row direction, and the source region semiconductor layer includes a plurality of source region semiconductor strips distributed along a row direction; each drain region semiconductor strip, each channel semiconductor strip, and each source region semiconductor strip extend along a column direction; a plurality of gate strips distributed along the column direction are arranged on each side of each column drain region semiconductor strip, channel semiconductor strip, and source region semiconductor strip, each gate strip extending along the height direction; in the plurality of memory subarray layers, the plurality of drain region semiconductor strips, the plurality of channel semiconductor strips, and the plurality of source region semiconductor strips, that are disposed in a same column, are defined as a column of the semiconductor strip structures; and a drain/source connection terminal array, including a plurality of drain/source connection terminal subarrays; wherein each drain/source connection terminal subarray includes a plurality of drain/source connection terminals arranged along the row direction; each drain/source connection terminal is connected to a corresponding drain/source region semiconductor strip of a corresponding column of the semiconductor strip structures, wherein the corresponding drain/source region semiconductor strip is a corresponding drain region semiconductor strip or a corresponding source region semiconductor strip.

Further another aspect adopted by the present disclosure is to provide a manufacturing method of a memory block, including: providing a semiconductor substrate; wherein the semiconductor substrate includes a substrate and a plurality of memory subarray layers formed on the substrate; each memory subarray layer includes a drain region semiconductor layer, a channel semiconductor layer, and a source region semiconductor layer stacked along a height direction; wherein a plurality of isolation walls and a plurality of gate strips are arranged on the semiconductor substrate, each isolation wall and each gate strip extending along the height direction to the substrate; forming a plurality of drain/source hole arrays in the semiconductor substrate at a predetermined interval along a column direction; wherein each drain/source hole array includes a plurality of drain/source holes distributed along a row direction, each drain/source hole extending along the height direction to the substrate; the plurality of gate strips, the plurality of isolation walls, and the plurality of drain/source holes of a plurality of the drain/source hole arrays, that are in the same column, form a spacing structure; along the row direction, a plurality of the spacing structures are distributed for dividing each memory subarray layer into a plurality of columns of drain region semiconductor strips, channel semiconductor strips, and source region semiconductor strips along the row direction; in the plurality of memory subarray layers, some of the plurality of drain region semiconductor strips, some of the plurality of channel semiconductor strips, and some of the plurality of source region semiconductor strips, that are disposed in a same column, are defined as a column of semiconductor strip structures; and forming a corresponding drain/source connection terminal subarray through several of the plurality of drain/source holes; wherein each drain/source hole correspondingly forms a corresponding drain/source connection terminal subarray, and a plurality of the drain/source connection terminal subarrays correspondingly formed by several of the plurality of drain/source holes in each drain/source hole array constitute a drain/source connection terminal array; each drain/source connection terminal subarray includes a plurality of drain/source connection terminals, each drain/source connection terminal is configured to be connected to a corresponding drain/source region semiconductor strip of a corresponding column of the semiconductor strip structures, wherein the corresponding drain/source region semiconductor strip is a corresponding drain region semiconductor strip or a corresponding source region semiconductor strip; wherein in a same column of the semiconductor strip structures, each drain/source region semiconductor strip is connected to several of the plurality of drain/source connection terminals of several of the plurality of drain/source connection terminal subarrays of several of the plurality of drain/source connection terminal arrays.

### BRIEF DESCRIPTION OF THE DRAWINGS

In order to more clearly illustrate the technical solutions in the embodiments of the present disclosure, the following is a brief description of the drawings required for the description of the embodiments, and it will be obvious that the drawings in the following description are only some embodiments of the present disclosure, and that other drawings can be obtained from these drawings without creative work for those skilled in the art.

FIG. 1 is a sketch of a structure of a memory device according to an embodiment of the present disclosure.

FIG. 2a is a perspective structural schematic view of a memory array according to an embodiment of the present disclosure.

FIG. 2b is another perspective structural schematic view of a memory array according to an embodiment of the present disclosure.

FIG. 3 is further another perspective structural schematic view of a memory array according to an embodiment of the present disclosure.

FIG. 4 is further another perspective structural schematic view of a memory array according to an embodiment of the present disclosure.

FIG. 5 is a perspective structural schematic view of a memory cell according to an embodiment of the present disclosure.

FIG. 6 is a perspective schematic view of a structure in which of two memory cells share the same column of drain region semiconductor strip, channel semiconductor strip, and source region semiconductor strip.

FIG. 7 is a perspective structural schematic view of a memory cell according to another embodiment of the present disclosure.

FIG. 8 is a perspective structural schematic view of a memory cell according to further another embodiment of the present disclosure.

FIG. 9 is a perspective schematic view of a partial structure of a memory block according to another embodiment of the present disclosure.

FIG. 10 is a perspective structural schematic view of a memory cell according to further another embodiment of the present disclosure.

FIG. 11 is a perspective structural schematic view of a memory block according to further another embodiment of the present disclosure.

FIG. 12 is a structural schematic view of a circuit connection of part of memory cells of a memory block according to an embodiment of the present disclosure.

FIG. 13 is a schematic view of a circuitry of the memory block shown in FIG. 11.

FIG. 14 is a schematic sketch of a plan view of the memory block shown in FIG. 11.

FIG. 15 is a schematic view of a memory cell corresponding to each layer of bit lines.

FIG. 16 is a schematic view of a three-dimensional distribution of word lines and bit lines.

FIG. 17 is a flowchart of a manufacturing method of a memory block according to an embodiment of the present disclosure.

FIG. 18 is a schematic view of a structure at a specific operation of a manufacturing method of a memory block according to an embodiment of the present disclosure.

FIG. 19 is a schematic view of a structure at another specific operation of a manufacturing method of a memory block according to an embodiment of the present disclosure.

FIG. 20 is a schematic view of a structure at further another specific operation of a manufacturing method of a memory block according to an embodiment of the present disclosure.

FIG. 21 is a schematic view of a structure at further another specific operation of a manufacturing method of a memory block according to an embodiment of the present disclosure.

FIG. 22 is a schematic view of a structure at further another specific operation of a manufacturing method of a memory block according to an embodiment of the present disclosure.

FIG. 23 is a schematic view of a structure at further another specific operation of a manufacturing method of a memory block according to an embodiment of the present disclosure.

FIG. 24a is a schematic view of a structure at further another specific operation of a manufacturing method of a memory block according to an embodiment of the present disclosure.

FIG. 24b is a schematic view of a structure at further another specific operation of a manufacturing method of a memory block according to an embodiment of the present disclosure.

FIG. 25a is a schematic view of a structure at further another specific operation of a manufacturing method of a memory block according to an embodiment of the present disclosure.

FIG. 25b is a schematic view of a structure at further another specific operation of a manufacturing method of a memory block according to an embodiment of the present disclosure.

FIG. 26 is a schematic view of a structure at further another specific operation of a manufacturing method of a memory block according to an embodiment of the present disclosure.

FIG. 27 is a schematic view of a structure at further another specific operation of a manufacturing method of a memory block according to an embodiment of the present disclosure.

FIG. 28 is a flowchart of a manufacturing method of a memory block according to another embodiment of the present disclosure.

FIG. 29 is a schematic view of a structure at a specific operation of a manufacturing method of a memory block according to another embodiment of the present disclosure.

FIG. 30 is a schematic view of a structure at another specific operation of a manufacturing method of a memory block according to another embodiment of the present disclosure.

FIG. 31 is a schematic view of a structure at further another specific operation of a manufacturing method of a memory block according to another embodiment of the present disclosure.

FIG. 32 is a schematic view of a structure at further another specific operation of a manufacturing method of a memory block according to another embodiment of the present disclosure.

FIG. 33 is a schematic view of a structure at further another specific operation of a manufacturing method of a memory block according to another embodiment of the present disclosure.

FIG. 34 is a schematic view of a structure at further another specific operation of a manufacturing method of a memory block according to another embodiment of the present disclosure.

FIG. 35 is a schematic view of a structure at further another specific operation of a manufacturing method of a memory block according to another embodiment of the present disclosure.

FIG. 36a is a schematic view of a structure at further another specific operation of a manufacturing method of a memory block according to another embodiment of the present disclosure.

FIG. 36b is a schematic view of a structure at further another specific operation of a manufacturing method of a memory block according to another embodiment of the present disclosure.

FIG. 37 is a schematic view of a structure at further another specific operation of a manufacturing method of a memory block according to another embodiment of the present disclosure.

FIG. 38 is a schematic view of a structure at further another specific operation of a manufacturing method of a memory block according to another embodiment of the present disclosure.

FIG. 39a is a schematic view of a structure at further another specific operation of a manufacturing method of a memory block according to another embodiment of the present disclosure.

FIG. 39b is a schematic view of a structure at further another specific operation of a manufacturing method of a memory block according to another embodiment of the present disclosure.

FIG. 40 is a schematic view of a structure at further another specific operation of a manufacturing method of a memory block according to another embodiment of the present disclosure.

FIG. 41 is a schematic view of a structure at further another specific operation of a manufacturing method of a memory block according to another embodiment of the present disclosure.

FIG. 42 is a schematic view of a structure at further another specific operation of a manufacturing method of a memory block according to another embodiment of the present disclosure.

FIG. 43 is a plan schematic view of a memory block according to further another embodiment of the present disclosure.

FIG. 44 is an enlarged view of region R circumscribed in FIG. 43.

FIG. 45 is a plan schematic view of a memory block according to further another embodiment of the present disclosure.

FIG. 46 is a schematic view of a first drain/source connection terminal group and a second drain/source connection terminal group of a drain/source connection terminal subarray, each connected to a corresponding drain/source region semiconductor strip according to an embodiment of the present disclosure.

FIG. 47 is a flowchart of a manufacturing method of a memory block according to further another embodiment of the present disclosure.

FIG. 48a is a schematic view of a structure at a specific operation of a manufacturing method of a memory block according to further another embodiment of the present disclosure.

FIG. 48b is a schematic view of a structure at another specific operation of a manufacturing method of a memory block according to further another embodiment of the present disclosure.

FIG. 49 is a schematic view of a structure at further another specific operation of a manufacturing method of a memory block according to further another embodiment of the present disclosure.

FIG. 50 is a schematic view of a structure at further another specific operation of a manufacturing method of a memory block according to further another embodiment of the present disclosure.

FIG. 51 is a schematic view of a structure at further another specific operation of a manufacturing method of a memory block according to further another embodiment of the present disclosure.

FIG. 52 is a schematic view of a structure at further another specific operation of a manufacturing method of a memory block according to further another embodiment of the present disclosure.

FIG. 53 is a schematic view of a structure at further another specific operation of a manufacturing method of a memory block according to further another embodiment of the present disclosure.

FIG. 54 is a schematic view of a structure at further another specific operation of a manufacturing method of a memory block according to further another embodiment of the present disclosure.

FIG. 55 is a schematic view of a structure at further another specific operation of a manufacturing method of a memory block according to further another embodiment of the present disclosure.

FIG. 56 is a schematic view of a structure at further another specific operation of a manufacturing method of a memory block according to further another embodiment of the present disclosure.

FIG. 57 is a schematic view of a structure at further another specific operation of a manufacturing method of a memory block according to further another embodiment of the present disclosure.

FIG. 58 is a schematic view of a structure at further another specific operation of a manufacturing method of a memory block according to further another embodiment of the present disclosure.

FIG. 59 is a schematic view of a structure at further another specific operation of a manufacturing method of a memory block according to further another embodiment of the present disclosure.

FIG. 60 is a schematic view of a structure at further another specific operation of a manufacturing method of a memory block according to further another embodiment of the present disclosure.

### REFERENCE NUMERALS

Memory block 10; memory array 1; memory subarray layer 1a; drain region semiconductor strip 11; bit line connection line 11a; channel semiconductor strip 12; well region connection line 12a; common well region line 12b; source region semiconductor strip 13; source connection line 13a; common source line 13b; interlayer isolation strip 14a; second single-crystal sacrificial semiconductor layer 14; insulating isolation layer 14′; body structure 15a; protrusion 15b; support post 16; column of semiconductor strip structures 1b; gate strip 2; isolation wall 3; isolation wall hole 31; word line hole 4; storage structure 5; first dielectric layer 51; charge-trapping layer 52; second dielectric layer 53; floating gate 54; first insulating dielectric layer 56; odd word line 8a; even word line 8b; word line connection line 7; drain region portion 11′; channel portion 12′; source region portion 13′; gate portion 2′; storage structure portion 5′; substrate 81; first single-crystal sacrificial semiconductor layer 82; first hard mask layer 83; word line opening 831; first recess 84; second recess 84′; third recess 84a; first insulating dielectric 85; first insulating dielectric layer 85a; second insulating dielectric layer 85b; second insulating dielectric 86; drain region semiconductor layer 11c; channel semiconductor layer 12c′; source region semiconductor layer 13c′; drain/source connection terminal array 9; drain/source connection terminal subarray 9a; drain connection terminal 91a; source connection terminal 91b; first drain/source connection terminal group 92a; second drain/source connection terminal group 92b; drain/source connection plug 94; first insulating material 95a; filling material 95b; insulating layer 95c; drain/source hole 96; drain/source hole array 97; drain/source connection terminal hole 98; second hard mask layer 99.

### DETAILED DESCRIPTION

The technical solutions in embodiments of the present disclosure will be clearly and completely described below in conjunction with the accompanying drawings in the embodiments of the present disclosure, and it is obvious that the described embodiments are only a part of the embodiments of the present disclosure, but not all of them. Based on the embodiments in the present disclosure, all other embodiments obtained by those skilled in the art without creative labor fall within the scope of the present disclosure.

The terms “first”, “second”, and “third” in the present disclosure are intended for descriptive purposes only and are not to be construed as indicating or implying relative importance or implicitly indicating the number of indicated technical features. Therefore, a feature defined with “first”, “second”, or “third” may explicitly or implicitly include at least one such feature. In the description of the present disclosure, “a plurality of” or “multiple” means at least two, e.g., two, three, etc., unless otherwise expressly and specifically limited. All directional indications (e.g., up, down, left, right, forward, backward . . . ) in the present disclosure are intended only to explain the relative position relationship, movement, etc., between components in a particular posture (as shown in the accompanying drawings), and if that particular posture is changed, the directional indications are changed accordingly. In addition, the terms “include” and “have”, and any variations thereof are intended to cover non-exclusive inclusion. For example, a process, method, system, product, or apparatus including a series of steps or units is not limited to the listed steps or units, but optionally further includes steps or units not listed, or optionally further includes other steps or units inherent to the process, method, product, or apparatus.

References herein to “embodiment” mean that particular features, structures, or characteristics described in connection with an embodiment may be included in at least one embodiment of the present disclosure. The presence of the phrase at various positions in the specification does not necessarily mean the same embodiment, nor is it a separate or alternative embodiment that is mutually exclusive with other embodiments. It is understood, both explicitly and implicitly, by those skilled in the art that the embodiments described herein may be combined with other embodiments.

The present disclosure is described in detail below in conjunction with the accompanying drawings and embodiments.

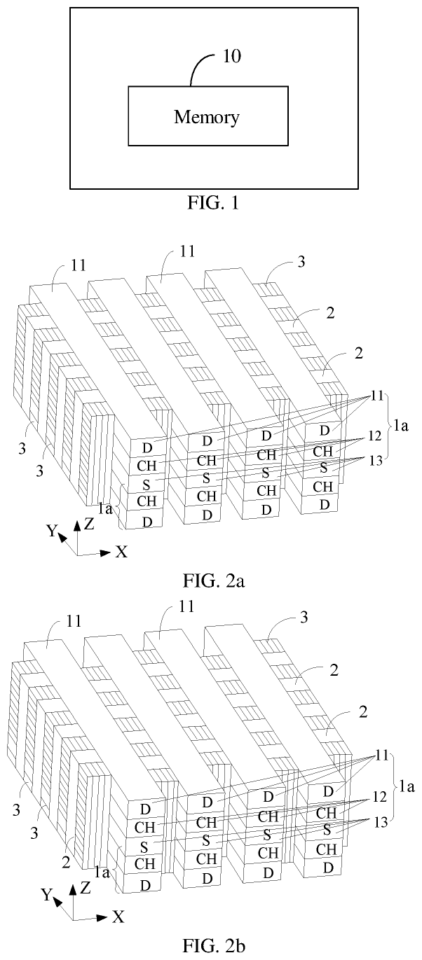

Referring to FIG. 1, FIG. 1 is a sketch of a structure of a memory device according to an embodiment of the present disclosure. A memory device is provided, which may specifically be a non-volatile memory device. The memory device may include one or more memory blocks 10. The specific structure and function of the memory block 10 may be described in connection with the memory block 10 provided in any of the following embodiments. It will be understood by those skilled in the art that a memory array 1 includes a structure in which multiple memory cells are arranged in a three-dimensional array; and the memory block 10 may include, in addition to the memory array 1 formed by the multiple memory cell arrays, other components, such as various types of wires (or connection lines), etc., enabling the memory block 10 to implement various memory operations.

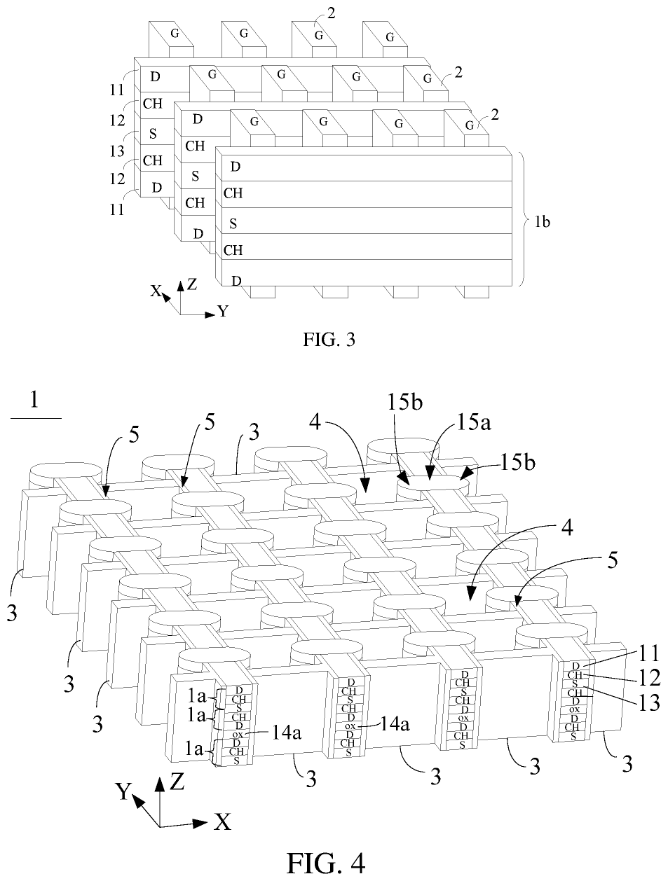

Referring to FIGS. 2a to 3, FIGS. 2a-3 are perspective structural schematic views of a memory array according to an embodiment of the present disclosure. In the embodiments, a memory block 10 is provided, which includes a memory array 1. The memory array 1 includes multiple memory cells distributed in a three-dimensional array.

As shown in FIG. 2a, the memory array 1 includes multiple memory subarray layers 1a stacked sequentially along a height direction Z. Each memory subarray layer 1a includes a drain region semiconductor layer, a channel semiconductor layer, and a source region semiconductor layer stacked along the height direction Z. The drain region semiconductor layer, the channel semiconductor layer, and the source region semiconductor layer may each be a single-crystal semiconductor layer grown by epitaxy. The height direction Z is a direction perpendicular to the substrate (e.g., substrate 81 of FIG. 9). The sequential stacking indicates a sequential arrangement on the substrate from bottom to top, and the stacking represents an arrangement and does not express or imply a structure or a top-to-bottom relationship of the layers.

In each memory subarray layer 1a, the drain region semiconductor layer (D) includes multiple drain region semiconductor strips 11 spaced along a row direction X, each drain region semiconductor strip 11 extending along a column direction Y. The channel semiconductor layer (CH) includes multiple channel semiconductor strips 12 spaced along the row direction X, each channel semiconductor strip 12 extending along the column direction Y. The source region semiconductor layer (S) includes multiple source region semiconductor strips 13 spaced along the row direction X, each source region semiconductor strip 13 extending along the column direction Y. Each drain region semiconductor strip 11, channel semiconductor strip 12, and source region semiconductor strip 13 is a single-crystal semiconductor strip, respectively. It is understood by those skilled in the art that each drain region semiconductor strip 11, channel semiconductor strip 12, and source region semiconductor strip 13 may be a single-crystal semiconductor strip formed by processing the drain region semiconductor layer, channel semiconductor layer, and source region semiconductor layer formed by epitaxy, respectively. As shown in FIGS. 2a-3, multiple gate strips 2 (G) are arranged on each side of each column of drain region semiconductor strips 11, channel semiconductor strips 12, and source region semiconductor strips 13, respectively, the multiple gate strips 2 distributed on a side of each column of drain region semiconductor strips 11, channel semiconductor strips 12, and source region semiconductor strips 13 are spaced along the column direction Y, and each gate strip 2 extends along the height direction Z, such that corresponding parts of the multiple drain region semiconductor strips 11, channel semiconductor strips 12, and source region semiconductor strips 13 in the same column in the multiple memory subarray layers 1a share a same gate strip 2.

As shown in FIG. 2b, among the multiple gate strips 2, each gate strip in the column and the gate strip in the adjacent column are staggered in the row direction X. Of course, as shown in FIG. 2a, each gate strip 2 in the same column and a corresponding gate strip 2, in an adjacent column, corresponding to the gate strip 2 in the row direction X, may be aligned with each other in the column direction Y. The staggered arrangement may reduce the influence of an electric field between the corresponding two gate strips 2 in adjacent columns.

In the height direction Z, a projection of at least a part of each gate strip 2 coincides with a projection of a part of a corresponding channel semiconductor strip 12 in each memory subarray layer 1a on a projection plane. The projection plane is a plane defined by the height direction Z and the column direction Y, i.e., the projection plane extends along the height direction Z and the column direction Y. As shown in FIGS. 2a-3, for the purpose of description, it is defined that a column of drain region semiconductor strip 11, channel semiconductor strip 12, and source region semiconductor strip 13 in each memory subarray layer 1a constitutes a semiconductor strip structure; two adjacent memory subarray layers 1a may share a common source, i.e., the two adjacent memory subarray layers 1a share a same source region semiconductor layer (S). Therefore, two semiconductor strip structures corresponding to the two memory subarray layers 1a share a same source region semiconductor strip 13. Of course, it is understood by those skilled in the art that the two adjacent memory subarray layers 1a may be arranged with a non-common source, i.e., each memory subarray layer 1a has an independent source region semiconductor layer, such that the two semiconductor strip structures corresponding to the two adjacent memory subarray layers 1a each has its own independent source region semiconductor strip 13. In the multiple memory subarray layers 1a, the drain region semiconductor strips 11, channel semiconductor strips 12, and source region semiconductor strips 13 in the same column constitute a column of semiconductor strip structures 1b, i.e., a stacked structure 1b. The column of semiconductor strip structures 1b includes multiple semiconductor strip structures, and the number of the semiconductor strip structures in the column of semiconductor strip structures 1b is the same as the number of the memory subarray layers 1a. As shown in FIGS. 2a-3, each column of semiconductor strip structures 1b includes two semiconductor strip structures, but those skilled in the art can understand that a column of semiconductor strip structures 1b may include multiple stacked semiconductor strips. As shown in FIG. 4, which is a sketch of a perspective structure of a memory array according to another embodiment of the present disclosure, where a column of semiconductor strip structures 1b includes three semiconductor strip structures.

In other words, it is understood by those skilled in the art that the memory array 1 includes multiple stacked structures 1b distributed along the row direction X, each stacked structure 1b extending along the column direction Y. Each stacked structure 1b includes drain region semiconductor strips 11, channel semiconductor strips 12, and source region semiconductor strips 13 stacked along the height direction. Each drain region semiconductor strip 11, channel semiconductor strip 12, and source region semiconductor strip 13 extends along the column direction Y. Multiple gate strips 2 spaced along the column direction Y are arranged on each of two sides of each stacked structure 1b, and each gate strip 2 extends along the height direction Z.

A projection of a part of each semiconductor strip structure coincides with a projection of a corresponding part of a corresponding gate strip 2 on the projection plane. In particular, a projection of a part of the channel semiconductor strip 12 in each semiconductor strip structure coincides with a projection of a part of a corresponding gate strip 2 on the projection plane. In this way, a part of the gate strip 2, a corresponding part of the channel semiconductor strip 12, a part of the drain region semiconductor strip 11 adjacent to the corresponding part of the channel semiconductor bar 12, and a part of the source region semiconductor strip 13 adjacent to the corresponding part of the channel semiconductor bar 12 are configured to form a memory cell. For example, as shown in FIGS. 2a-3, for the gate strip 2 of the first column along the row direction X and the first row along the column direction Y, a projection of a part of the gate strip 2 coincides with a projection of a corresponding part of the channel semiconductor strip 12 of the first column of the drain region semiconductor strip 11, the channel semiconductor strip 12, and the source region semiconductor strip 13 (a semiconductor strip structure with a D/CH/S structure) of the first memory subarray layer 1a in the height direction Z. That is, the part of the gate strip 2 of the first column and the first row, the corresponding part of the first column of the channel semiconductor strip 12 of the first memory subarray layer 1a in the height direction Z, and a part of the drain region semiconductor 11 and a part of the source region semiconductor 13, that are matched with the corresponding part of the first column of the channel semiconductor strip 12 of the first memory subarray layer 1a in the height direction Z, are configured to form a memory cell.

It will be understood by those skilled in the art that, a channel is required to be formed in a semiconductor region between the semiconductor drain region and the semiconductor source region; and the gate is arranged on a side of the semiconductor region between the semiconductor drain region and the semiconductor source region for constituting a semiconductor device. Therefore, as shown in FIGS. 2a-3, the part of each gate strip 2 whose projection overlaps with the projection of a channel semiconductor strip 12 in an adjacent stacked structure 1b on the above projection plane is configured as a gate, i.e., a control gate of the corresponding memory cell; the part of the channel semiconductor strip 12 whose projection overlaps with the projection of the gate strip 2 on the above projection plane, i.e., the corresponding part of the channel semiconductor strip 12, is configured as the channel region (well region) for forming a channel therein; and the drain region semiconductor strip 11 and the source region semiconductor strip 13 adjacent to the channel semiconductor strip 12 each has a part arranged just above or below the corresponding part of the channel semiconductor strip 12, i.e., the parts of the drain region semiconductor strip 11 and the source region semiconductor strip 13 exactly match the corresponding part of the channel semiconductor strip 12 as the semiconductor drain region and the semiconductor source region. Therefore, the parts of the drain region semiconductor strip 11 and the source region semiconductor strip 13, the corresponding part of the channel semiconductor strip 12 sandwiched between the parts of the drain region semiconductor strip 11 and the source region semiconductor strip 13, cooperating with the part of the gate strip 2 as the control gate, are configured to form a memory cell.

Therefore, as shown in FIGS. 2a-3, the memory array 1 of the present disclosure is formed with multiple memory cells arranged in an array, and the multiple memory cells are included by the drain region semiconductor strips 11, the channel semiconductor strips 12, the source region semiconductor strips 13, and the gate strips 2. In particular, the memory array 1 of the present disclosure includes multiple memory subarray layers 1a stacked sequentially along the height direction Z. Each memory subarray layer 1a includes a layer of drain region semiconductor strips 11, a layer of channel semiconductor strips 12, a layer of source region semiconductor strips 13, and parts of gate strips 2 matching the above layers, such that each memory subarray layer 1a includes a layer of array-arranged memory cells along the height direction Z, and the stacked multiple memory subarray layers 1a constitute multiple layers of memory cells arrayed along the height direction Z.

In the present disclosure, each drain region semiconductor strip 11 is a semiconductor strip of a first doping type, such as an N-type doped semiconductor strip. In some embodiments, each drain region semiconductor strip 11 serves as a bit line (BL) of a memory block.

Each channel semiconductor strip 12 is a semiconductor strip of a second doping type, such as a P-type doped semiconductor strip. In some embodiments, each channel semiconductor strip 12 serves as a well region of a memory cell.

Each source region semiconductor strip 13 is also a semiconductor strip of the first doping type, such as an N-type doped semiconductor strip. In some embodiments, each source region semiconductor strip 13 serves as a source line (SL) of the memory block.

Of course, it is understood by those skilled in the art that in other types of memory devices, each drain region semiconductor strip and each source region semiconductor strip may also be a P-type doped semiconductor strip, while each channel semiconductor strip 12 is an N-type doped semiconductor strip. The present disclosure does not limit thereto.

Referring further to FIGS. 2a-3, in the height direction Z, two adjacent memory subarray layers 1a include a drain region semiconductor layer, a channel semiconductor layer, a source region semiconductor layer, a channel semiconductor layer, and a drain region semiconductor layer laminated in sequence to share the common source region semiconductor layer. As shown in FIGS. 2a-3, the common source region semiconductor strip 13 is arranged between two adjacent channel semiconductor strips 12 in the height direction Z in the same column, and two drain region semiconductor strips 11 are arranged respectively on two sides of the two adjacent channel semiconductor strips 12. That is, in the height direction Z, the same column of semiconductor strip structures 1b of two adjacent memory subarray layers 1a includes the drain region semiconductor strip 11, the channel semiconductor strip 12, the source region semiconductor strip 13, the channel semiconductor strip 12, and the drain region semiconductor strip 11 laminated in sequence, thereby forming two semiconductor strip structures which share the same source region semiconductor strip 13. In this way, the storage density of the memory block 10 may be further increased while reducing cost and process.

Referring together to FIG. 4, the memory array 1 includes multiple memory subarray layers 1a stacked sequentially along the height direction Z. Each memory subarray layer 1a includes a drain region semiconductor layer, a channel semiconductor layer, and a source region semiconductor layer stacked along the height direction Z.

In each memory subarray layer 1a, the drain region semiconductor layer, the channel semiconductor layer, and the source region semiconductor layer include multiple drain region semiconductor strips 11, multiple channel semiconductor strips 12, and multiple source region semiconductor strips 13, respectively, spaced along the row direction X.

Two adjacent memory subarray layers 1a include a drain region semiconductor layer, a channel semiconductor layer, a source region semiconductor layer, a channel semiconductor layer, and a drain region semiconductor layer sequentially stacked to share the same source region semiconductor layer.

An interlayer isolation layer is arranged between every two memory subarray layers 1a to isolate from the other two memory subarray layers 1a. That is, an interlayer isolation layer is arranged between each two consecutive memory subarray layers 1a and another two consecutive memory subarray layers 1a, the another two consecutive memory subarray layers 1a being adjacent to the each two consecutive memory subarray layers 1a. For example, in the height direction Z, an interlayer isolation layer is arranged between the first/second memory subarray layers 1a and the third/fourth memory subarray layers 1a; another interlayer isolation layer is arranged between the third/fourth memory subarray layers 1a and the fifth/sixth memory subarray layers 1a, and so on. The first/second memory subarray layers mean the first memory subarray layer and the second memory subarray layer which share a common source region semiconductor layer, and the third/fourth memory subarray layers mean the third memory subarray layer and the fourth memory subarray layer which share another common source region semiconductor layer, while the fifth/sixth memory subarray layers mean the fifth memory subarray layer and the sixth memory subarray layer which share another common source region semiconductor layer. It is understood that the one interlayer isolation layer is disposed between the second memory subarray layer 1a and the third memory subarray layer 1a; and the other interlayer isolation layer is disposed between the fourth memory subarray layer 1a and the fifth memory subarray layer 1a.

Specifically, as shown in FIG. 4, one interlayer isolation strip 14a is arranged between every two adjacent semiconductor strip structures in the same column of semiconductor strip structures in the height direction Z. Similarly, an interlayer isolation strip 14a is arranged between every two adjacent semiconductor strip structures in another column of semiconductor strip structures. It is understood by those skilled in the art that multiple interlayer isolation strips 14a in the same horizontal plane constitute an interlayer isolation layer to isolate from the semiconductor strip structures in the other two memory subarray layers 1a.

In other words, in the present disclosure, each stacked structure 1b may include multiple stacked substructures, each stacked substructure including a drain region semiconductor strip 11, a channel semiconductor strip 12, a source region semiconductor strip 13, a channel semiconductor strip 12, and a drain region semiconductor strip 11 stacked sequentially along the height direction Z, thereby sharing the same source region semiconductor strip 13. In the stacked structure 1b, an interlayer isolation strip 14a is arranged between two adjacent stacked substructures to isolate them from each other. That is, in two adjacent memory subarray layers 1a, the drain region semiconductor strip 11, channel semiconductor strip 12, source region semiconductor strip 13, channel semiconductor strip 12, and drain region semiconductor strip 11 in the same column form a stacked substructure, such that two adjacent memory subarray layers 1a share a common source region semiconductor strip 13.

Referring further to FIG. 4 or FIG. 2a, multiple isolation walls 3 are distributed in the memory array 1, and the multiple isolation walls 3 are arranged in a matrix in the row direction X and the column direction Y. As shown in FIG. 2a, multiple isolation walls 3 distributed along the column direction Y are arranged on each of two sides of each column of drain region semiconductor strips 11, channel semiconductor strips 12, and source region semiconductor strips 13. Each isolation wall 3 extends along the height direction Z and the row direction X to separate at least parts of two adjacent columns of drain region semiconductor strips 11, channel semiconductor strips 12, and source region semiconductor strips 13. That is, the multiple isolation walls 3 distributed along the column direction Y are arranged on each of the two sides of each stacked structure 1b to separate at least parts of the two adjacent columns of stacked structures 1b. In some embodiments, particularly during the manufacturing process of the memory block 10, the isolation walls 3 may further serve as support structures that may support two adjacent columns of the stacked structures 1b during and/or after the manufacturing process. In addition, apart of each side of each stacked structure 1b may be arranged with support posts (not shown and described in detail below), respectively, to support the two adjacent columns of the stacked structures 1b during and/or after the manufacturing process of the memory array 1.

A region between two adjacent isolation walls 3 in the same column in the column direction Y is configured to define a word line hole 4. That is, any two adjacent isolation walls 3 in the same column, cooperating with two columns of semiconductor strip structures 1b (i.e., stacked structures 1b) on both sides thereof, may define multiple regions for the word line holes 4, and these regions may be processed such that corresponding word line holes 4 may be defined. That is, the multiple columns of drain region semiconductor strips 11, channel semiconductor strips 12, and source region semiconductor strips 13 extending along the column direction Y pass through the multiple rows of isolation walls 3 extending along the row direction X, to define the multiple word line holes 4 cooperating with the multiple isolation walls 3. Each word line hole 4 extends along the height direction Z.

Each word line hole 4 is configured to fill a gate material to form a corresponding gate strip 2. That is, a gate strip 2 is filled between two adjacent isolation walls 3 in the same column direction Y.

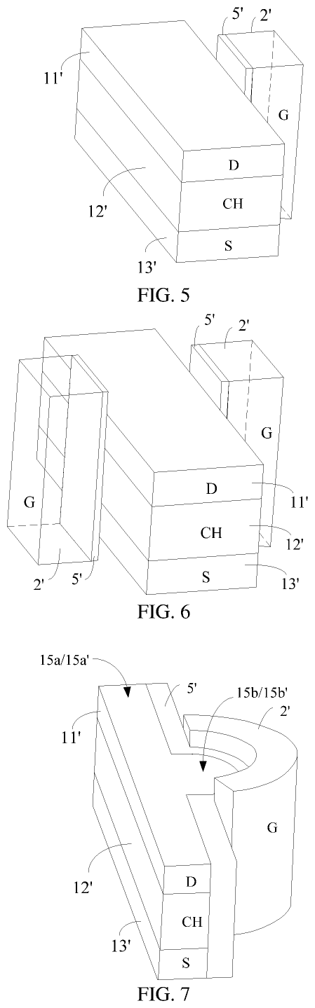

Referring together to FIG. 5, FIG. 5 is a perspective structural schematic view of a memory cell according to an embodiment of the present disclosure. As shown in FIG. 5, the memory cell includes a drain region portion 11′, a channel portion 12′, a source region portion 13′, and a gate portion 2′. The drain region portion 11′, the channel portion 12′, and the source region portion 13′ are stacked along the height direction Z, respectively. The channel portion 12′ is disposed between the drain region portion 11′ and the source region portion 13′. The gate portion 2′ is disposed on a side of the drain region portion 11′, the channel portion 12′, and the source region portion 13′. The drain region portion 11′, the channel portion 12′, and the source region portion 13′ are each a single-crystal semiconductor.

In addition, a projection of the gate portion 2′ at least partially coincides with a projection of the channel portion 12′ on a projection plane in the height direction Z. The projection plane is located on a side of the drain region portion 11′, the channel portion 12′, and the source region portion 13′, and extends along the height direction Z and the column direction Y.

As shown in FIG. 5, it is easily understood by those skilled in the art that the drain region portion 11′ is a part of one of the drain region semiconductor strips 11 shown in FIGS. 2a-4, the channel portion 12′ is a part of one of the channel semiconductor strips 12 shown in FIGS. 2a-4, and the source region portion 13′ is a part of one of the source region semiconductor strips shown in FIGS. 2a-4. Therefore, in the height direction Z, the multiple memory subarray layers 1a includes multiple memory cells.

In addition, as shown in FIG. 5, a storage structure portion 5′ is sandwiched between the gate portion 2′ and the drain region portion 11′, the channel portion 12′, and the source region portion 13′. The storage structure portion 5′ may be configured to store an electric charge; the gate portion 2′, the drain region portion 11′, the channel portion 12′, the source region portion 13′, together with the storage structure portion 5′ sandwiched between the gate portion 2′ and the channel portion 12′, constitutes a memory cell. The memory cell may indicate logical data 1 or logical data 0 by a state whether any storage charge is stored or not in the storage structure portion 5′, thereby enabling storage of data. The storage structure portion 5′ may include a charge trapping storage structure portion, a floating gate storage structure portion, or other types of capacitive storage structure portions.

Therefore, it will be understood by those skilled in the art that in the memory array 1 shown in FIGS. 2a-4, a storage structure 5 is also arranged between the gate strip 2 and the drain region semiconductor strip 11, the channel semiconductor strip 12, and the source region semiconductor strip 13, such that each memory cell can store electric charges by its corresponding storage structure portion 5′.

In addition, it should be noted that for the convenience of the accompanying drawings showing the storage structure portion 5′, the drain region portion 11′, the channel portion 12′, the source region portion 13′, the gate portion 2′, and the storage structure portion 5 shown in FIG. 5′ are shown for illustrative purposes only and do not represent actual dimensions or proportions.

It will be understood by those skilled in the art that, as above, the part of the gate strip 2 whose projection coincides with the projection of the adjacent channel semiconductor strip 12 on the above projection plane is configured as the control gate of the memory cell, such that the part of the gate strip 2 as the gate portion 2′ is the part whose projection coincides with the projection of the channel semiconductor 12 on the projection plane; the part of the channel semiconductor strip 12 whose projection coincides with the projection of the gate strip 2 on the above projection plane is the corresponding part of the channel semiconductor strip 12 as the well region, such that the part of the channel semiconductor strip 12 as the channel portion 12′ is the part of the channel semiconductor strip 12 whose projection coincides with the projection of the gate strip 2 on the projection plane; the parts of the drain region semiconductor strip 11 and the source region semiconductor strip 13 as the drain region portion 11′ and the source region portion 13′, i.e., the part of the drain region semiconductor strip 11 or the source region semiconductor strip 13 arranged above or below the channel portion 12′, are configured as the semiconductor drain region and the semiconductor source region, respectively.

Similarly, the storage structure portion 5′ is a part of the storage structure 5 disposed between the channel portion 12′ and the gate portion 2′.

Referring further to FIG. 2a-FIG. 4, agate strip 2 is flanked by two adjacent columns of drain region semiconductor strips 11, channel semiconductor strips 12, and source region semiconductor strips 13. Therefore, these two adjacent columns of drain region semiconductor strips 11, channel semiconductor strips 12, and source region semiconductor strips 13 share the same gate strip 2. That is, for a gate strip 2 in a memory subarray layer 1a, the gate strip cooperates with corresponding parts of the drain region semiconductor strip 11, channel semiconductor strip 12, and source region semiconductor strip 13 on the left side of the gate strip 2 to form a memory cell, and cooperates with corresponding parts of the drain region semiconductor strip 11, channel semiconductor strip 12, and source region semiconductor strip 13 on the right side of the gate strip 2 to form another memory cell. In other words, in a same row, two gate strips 2 are arranged on the left and right sides of one column of drain region semiconductor strip 11, channel semiconductor strip 12, and source region semiconductor strip 13 in one memory subarray layer 1a. In this way, the one column of drain region semiconductor strip 11, channel semiconductor strip 12, and source region semiconductor strip 13 cooperates with a part of the gate strip 2 on the left side to constitute a memory cell, and cooperates with a part of the gate strip 2 on the right side to constitute another memory cell. That is, in the same row, a column of drain region semiconductor strip 11, channel semiconductor strip 12, and source region semiconductor strip 13 in one memory subarray layer 1a is shared by two gate strips 2 on its left and right sides.

Specifically, further referring to FIG. 6, FIG. 6 is a perspective schematic view of a structure in which of two memory cells share the same column of drain region semiconductor strip, channel semiconductor strip, and source region semiconductor strip. As shown in FIG. 6, the source region portion 13′, channel portion 12′, and drain region portion 11′ stacked along the height direction Z′ cooperate with the gate portion 2′ on the left side and the storage structure portion 5′ between them to constitute a memory cell; similarly, the drain region portion 11′, the channel portion 12′, and the source region portion 13′ cooperate with the gate portion 2′ on the right side and the storage structure portion 5′ between them to constitute another memory cell. In this way, both the two memory cells share the same drain region portion 11′, channel portion 12′, and the source region portion 13′.

For ease of understanding, it may be considered that the drain region portion 11′, the channel portion 12′, and the source region portion 13′ cooperate with the gate portion 2′ on the left side and the storage structure portion 5′ between them to form a memory cell (bit); the drain region portion 11′, the channel portion 12′, and the source region portion 13′ cooperate with the gate portion 2′ on the right side and the storage structure portion 5′ between them to form another memory cell (bit).

Therefore, returning to FIGS. 2a-4, it will be understood by those skilled in the art that a storage structure 5 is first arranged on each of the left and right sides in each word line hole 4, and the gate material is filled in the word line hole 4 to form the gate strip 2. That is, the two adjacent columns of drain region semiconductor strips 11, channel semiconductor strips 12, and source region semiconductor strips 13 in conjunction with the storage structures 5 share the same gate strip 2.

In conjunction with FIGS. 2a-3 and 5-6, in some embodiments, each of the above drain region semiconductor strip 11, channel semiconductor strip 12, and source region semiconductor strip 13 is a standard strip structure. That is, each drain region semiconductor strip 11, channel semiconductor strip 12, and source region semiconductor strip 13 has a standard rectangular cross-section at each position along the respective extension direction. The memory cell corresponding to the embodiments may be illustrated specifically in FIGS. 5 and 6.

In other embodiments, in conjunction with FIG. 4 and FIG. 7, FIG. 7 is a perspective structural schematic view of a memory cell according to another embodiment of the present disclosure. Each drain region semiconductor strip 11, channel semiconductor strip 12, and source region semiconductor strip 13 includes a body structure 15a and multiple protrusions 15b, respectively. The body structure 15a extends along the column direction Y and is in the shape of a strip. The multiple protrusions 15b are distributed on both sides of the body structure in two columns, and each column includes multiple protrusions 15b spaced apart, each protrusion 15b extending from the body structure 15a in the row direction X toward a corresponding gate strip 2 (word line hole 4) in a direction deviating from the body structure 15a. In other words, in each column of drain region semiconductor strips 11, channel semiconductor strips 12, and source region semiconductor strips 13, two columns of protrusions 15b extend from the strip-shaped body structure 15a toward the gate strips 2 (word line holes 4) on each side. Therefore, it is understood by those skilled in the art that a surface of the storage structure 5 formed in the word line hole 4 and a surface of the gate strip 2 near the drain region semiconductor strip 11, the channel semiconductor strip 12, and the source region semiconductor strip 13 are curved concave surfaces.

As shown in FIG. 7, for each memory cell, the drain region portion 11′, the channel portion 12′, and the source region portion 13′ include a body portion 15a′ and a protrusion portion 15b′, and each of the storage structure portion 5′ and the gate portion 2′ includes a concave surface corresponding to the protrusion portion 15b′ to wrap a surface of the protrusion 15b away from the body structure 15a.

In the present disclosure, by making each drain region semiconductor strip 11, channel semiconductor strip 12, and source region semiconductor strip 13 include multiple protrusions 15b that are raised toward the two sides, it is possible to increase the surface area of each drain region semiconductor strip 11, channel semiconductor strip 12, and source region semiconductor strip 13, thereby increasing the area of a corresponding region of the channel portion 12′ and the gate portion 2′ in each memory cell, thereby enhancing the performance of the memory block 10.

Specifically, the convex surface of the protrusion 15b away from the body structure 15a may be an arc or other form of convex surface, where the arc may include a columnar semicircular surface. The protrusions 15b of each column of drain region semiconductor strip 11, channel semiconductor strip 12, and source region semiconductor strip 13 form a columnar semicircle. The gate strip 2 corresponding to the protrusions 15b is arranged with a concave surface toward the drain region semiconductor strip 11, the channel semiconductor strip 12, and the source region semiconductor strip 13, and the concave surface is a curved surface corresponding to the convex surface of the protrusions 15b to ensure that the gate strip 2 matches the channel semiconductor strip 12 at the corresponding position.

In some embodiments, as shown in FIG. 4, the storage structure 5 extends inside the word line hole 4 in the height direction Z and is arranged between the gate strip 2 and the adjacent drain region semiconductor strip 11, the channel semiconductor strip 12, and the source region semiconductor strip 13, such that the storage structures 5 may form the multiple memory cells together with the parts of the drain region semiconductor strips 11, the channel semiconductor strips 12, and the source region semiconductor strips 13 at corresponding positions. In the present disclosure, the storage structure 5 may be a charge trapping storage structure, a floating gate storage structure, or other types of capacitive dielectric structures.

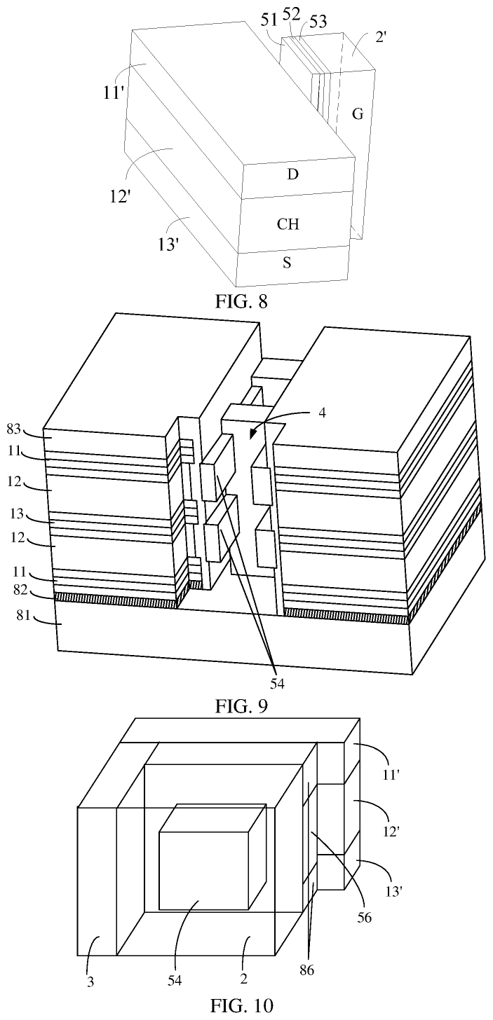

Referring to FIG. 8, FIG. 8 is a perspective structural schematic view of a memory cell according to further another embodiment of the present disclosure. In the embodiments, the storage structure 5 is a charge trapping storage structure. As shown in FIG. 8, the storage structure portion 5′ of the memory cell includes a first dielectric portion 51, a charge-trapping portion 52, and a second dielectric portion 53. The first dielectric portion 51 is disposed between the charge-trapping portion 52 and the stacked drain region portion 11′, the channel portion 12′, and the source region portion 13′; the charge-trapping portion 52 is disposed between the first dielectric portion 51 and the second dielectric portion 53; and the second dielectric portion 53 is disposed between the charge-trapping portion 52 and the gate portion 2′. The charge-trapping portion 52 is configured to store an electrical charge to enable the memory cell to store data.

Therefore, with reference to FIG. 8, it will be understood by those skilled in the art that the storage structure 5 in the memory array shown in FIGS. 2a-4 of the present disclosure includes a first dielectric layer, a charge-trapping layer, and a second dielectric layer, the first dielectric layer being disposed between the charge-trapping layer and the drain region semiconductor strip 11, the channel semiconductor strip 12, and the source region semiconductor strip 13, the charge-trapping layer being disposed between the first dielectric layer and the second dielectric layer, and the second dielectric layer being disposed between the charge-trapping layer and the gate strip 2.

The first dielectric layer (first dielectric portion 51) and the second dielectric layer (second dielectric portion 53) may be made of an insulating material, such as silicon oxide. The charge-trapping layer (charge-trapping portion 52) may be made of a storage material with charge energy trapping properties, in particular, the charge-trapping layer may be made of silicon nitride. Therefore, the first dielectric layer (first dielectric portion 51), the charge-trapping layer (charge-trapping portion 52), and the second dielectric layer (second dielectric portion 53) form an ONO storage structure. Specifically, reference thereto may be made to a manufacturing method involving a memory block of a charge trapping storage structure in the following embodiments.

In other embodiments, referring to FIG. 9, FIG. 9 is aperspective schematic view of a partial structure of a memory block 10 according to another embodiment of the present disclosure. In the embodiments, the storage structure 5 is a floating gate storage structure, and the floating gate storage structure extends at least partially within the word line hole 4 in the height direction Z and is arranged between the gate strip 2 and the drain region semiconductor strip 11, the channel semiconductor strip 12, and the source region semiconductor strip 13.

Specifically, in conjunction with FIG. 9-FIG. 10, FIG. 10 is a perspective structural schematic view of a memory cell according to further another embodiment of the present disclosure. For each memory cell, the floating gate storage structure includes multiple floating gates 54 and an insulating dielectric wrapping each floating gate 54. As shown in FIG. 9, as can be seen through the word line hole 4, the multiple floating gates 54 are spaced along the height direction Z, and each floating gate 54 is arranged on a side of the channel semiconductor strip 12 along the row direction X and faces a corresponding part of the channel semiconductor strip 12. As shown in FIG. 10, the insulating dielectric wrapping the floating gate 54 includes a first insulating dielectric layer 56 between the channel semiconductor strip 12 and the floating gate 54 (referring also to the first insulating dielectric layer 85a shown in FIG. 41 below), and a second insulating dielectric layer covering several other faces of the floating gate 54 (not shown in FIG. 10, referring to the second insulating dielectric layer 85b shown in FIG. 41 below). That is, the insulating dielectric is present between the floating gate 54 and the corresponding part of the channel semiconductor strip 12, between two adjacent floating gates 54, and between the floating gate 54 and the gate strip 2. The insulating dielectric wraps every surface of the floating gate 54 to completely isolate the floating gate 54 from the rest of the structure.

Among them, the floating gate 54 may be made of polycrystalline silicon. The insulating dielectric may be made of an insulating material such as silicon oxide. Specifically, reference thereto may be made to a manufacturing method involving a memory block of a floating gate storage structure in the following embodiments.

In the memory cell of the charge trapping storage structure shown in FIG. 8 and FIGS. 2a-4, the storage structure 5 is adopted with a first dielectric layer (first dielectric portion 51), a charge-trapping layer (charge-trapping portion 52), and a second dielectric layer (second dielectric portion 53) to form an ONO storage structure.

The ONO storage structure is characterized by the fact that the charges injected into can be fixed near an injection point, while the floating gate storage structure (e.g., FIGS. 9-11 is adopted with polysilicon as a floating gate) is characterized by the fact that the charges injected into can be uniformly distributed in the entire floating gate 54. In other words, in the ONO storage structure, the charges can only move in the injection/removal direction, i.e., the stored charges can only be fixed near the injection point and cannot move arbitrarily in the charge-trapping layer, especially cannot move in the extension direction of the charge-trapping layer. Therefore, for the ONO storage structure, the charge-trapping layer only needs to have an insulating dielectric on its front and back side, and the charges stored in each memory cell will be fixed near the injection point of the charge-trapping portion 52 and will not move along the same layer of the charge-trapping layer to the charge-trapping portion 52 in another memory cell. While in the floating gate storage structure, the charge can not only move in the injection/removal direction, but also can move arbitrarily in the floating gate 54. Therefore, when the floating gate 54 is a continuous structure, the stored charge can move in the direction of extension of the floating gate 54 and thus move to the floating gate 54 in another memory cell. Therefore, for the floating gate storage structure, the floating gates 54 of each memory cell are independent, and each surface of each floating gate needs to be covered by an insulating dielectric, and needs to be isolated from each other, to prevent the charges stored in the floating gate 54 in one memory cell from moving to the floating gates 54 in the other memory cells.

That is, for the memory cell and memory block of the charge trapping storage structure shown in FIGS. 8 and 2a-4, the storage structure 5 may extend from top to bottom in the word line hole 4, and it is sufficient to arrange a first dielectric layer and a second dielectric layer on both sides of the charge-trapping layer, respectively.

In contrast, in the floating gate storage structure shown in FIGS. 9-11, the floating gates 54 of each memory cell are independent, and each surface of each floating gate 54 needs to be covered by an insulating dielectric, and needs to be isolated from each other, to prevent the charges stored in the floating gates 54 in one memory cell from moving to the floating gates in other memory cells.

It will be understood by those skilled in the art that some parts of the insulating dielectric (e.g., the second insulating dielectric layer 85b mentioned above) are interconnected with each other, as long as it is possible to ensure that the floating gates 54 of each memory cell are independent of each other and that the surfaces of each floating gate 54 are wrapped with the insulating dielectric. Therefore, parts of the insulating dielectric (e.g., the second insulating dielectric layer 85b mentioned above) that wraps the floating gates 54 in the word line hole 4 may extend substantially in the height direction, thereby wrapping the floating gates 54 of each memory cell. Specifically, reference to the memory block 10 with a floating gate storage structure may be made to a manufacturing method involving a memory block of a floating gate storage structure in the following embodiments.

In addition, it will be understood by those skilled in the art that the storage structure 5 may be adopted with other types of storage structures, such as ferroelectric, variable resistance, or other types of capacitive storage structures.

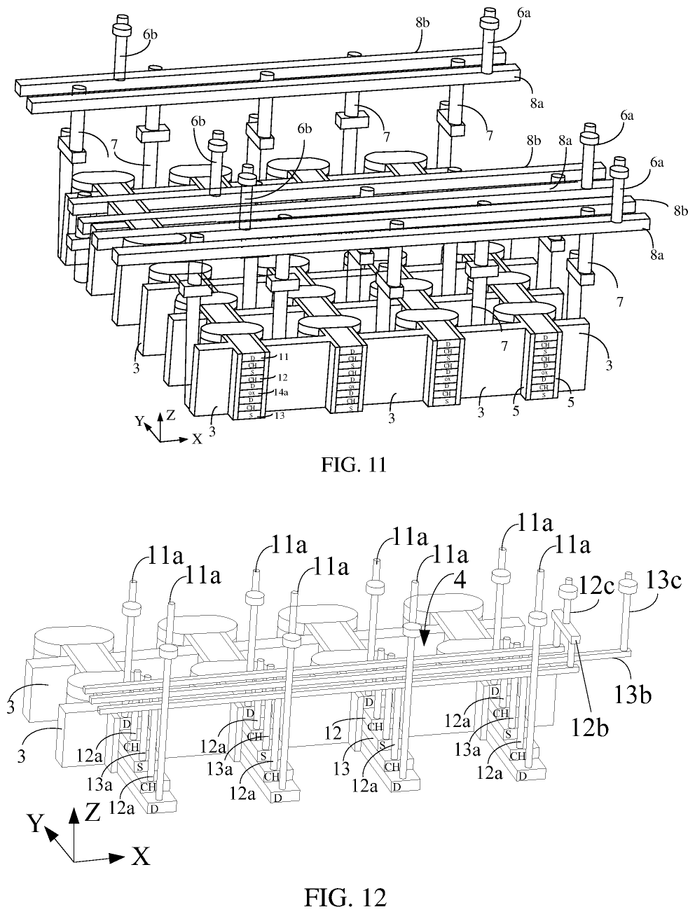

In some embodiments, referring to FIG. 11, FIG. 11 is a perspective structural schematic view of a memory block 10 according to further another embodiment of the present disclosure. In FIG. 11, only three layers of memory subarray layers 1a are shown, which are merely schematic, and it will be understood by those skilled in the art that the memory block 10 includes multiple layers of memory subarray layers 1a, with each two layers of memory subarray layers 1a separated from each other by an interlayer isolation layer (formed by multiple interlayer isolation strips 14a). The memory block 10 further includes multiple word lines (WL) and multiple word line connection lines 7.

As above, the part of the gate strip 2 whose projection overlaps with the projection of the channel semiconductor strip 12 in an adjacent stacked structures 1b on the above projection plane is configured as the control gate of the corresponding memory cell. Therefore, each gate strip 2 is configured to form the control gate (CG) of multiple memory cells. As is known, the control gates of a row of memory cells need to be connected to a corresponding word line, through which a voltage is applied to the control gates of the row of the memory cells, thereby controlling the memory cells to perform various memory operations.

In the present disclosure, as shown in FIG. 11, multiple word lines are arranged on top of multiple memory subarray layers 1a and are spaced apart in the column direction Y, with each word line extending along the row direction X. Each word line is connected to multiple word line connection lines 7. The multiple word line connection lines 7 connected to the same word line extend along the height direction Z, respectively, and extend to the gate strips 2 in the multiple word line holes 4 in the same row, respectively, to be connected to the gate strips 2 in the corresponding word line holes 4, thereby realizing the connection of the word line to the control gates of the multiple memory cells in the same row of the multiple memory subarray layers 1a. It can be understood that the multiple word line holes 4 and the multiple word line connection lines 7 are arranged in a one-to-one correspondence.

Specifically, the word line of the same row may be an individual word line connected to the gate strip 2 in each word line hole 4 of the same row. Of course, the word lines of the same row may include multiple different types of word lines; the gate strips 2 in multiple word line holes 4 of the same row may each be connected to the multiple different types of word lines of the corresponding row. In some embodiments, as shown in FIG. 11, multiple gate strips 2 in the same row are configured to be connected to two corresponding word lines, i.e., each row of word line includes an odd word line 8a and an even word line 8b. It should be noted that one odd word line 8a and one even word line 8b connected to the multiple gate strips 2 of the same row in the present disclosure are defined as one row of word line corresponding to one row of gate strips 2.

Specifically, the memory cells of the same row in the multiple memory subarray layers 1a are connected to the odd word line 8a of the corresponding row through the odd word line holes 4 of the same row, respectively; the others of the memory cells of the same row in the multiple memory subarray layers 1a are connected to the even word line 8b of the corresponding row through the even word line holes 4 of the same row, respectively. For example, a first part of the memory cells of the first row are connected to the odd word line 8a of the first row through the first word line hole 4, the third word line hole 4, the fifth word line hole 4 . . . , respectively; a second part of the memory cells of the first row are connected to the even word line 8b of the first row through the second word line hole 4, the fourth word line hole 4, the sixth word line hole 4 . . . , respectively. That is, the odd word line 8a of the word line of the same row is connected to multiple memory cells (the first part of the memory cells) in the multiple memory subarray layers 1a corresponding to the odd word line holes 4 of this row; the even word line 8b of the word line of the same row are connected to multiple memory cells (the second part of the memory cells) in the multiple memory subarray layers 1a corresponding to the even word line holes 4 of this row.

As above, each drain region semiconductor strip 11, channel semiconductor strip 12, and source region semiconductor strip 13 has odd word line holes 4 distributed on one side thereof and even word line holes 4 distributed on the other side thereof. Therefore, a part of the drain region semiconductor strip 11, channel semiconductor strip 12, and source region semiconductor strip 13 in each same column in each memory subarray layer 1a may cooperate with an odd gate strip 2 in an odd word line hole 4 on one side thereof and a storage structure arranged between the gate strip 2 and the drain region semiconductor strip 11, channel semiconductor strip 12, and source region semiconductor strip 13, to form a memory cell, i.e., a first memory cell; and may cooperated with an even word line hole 4 on the other side thereof and a storage structure 5 arranged therebetween, to form another memory cell, i.e., a second memory cell.

In other words, the gate strip 2 filled in each word line hole 4 may be configured to form a memory cell (bit) in conjunction with the drain region semiconductor strip 11, the channel semiconductor strip 12, the source region semiconductor strip 13, and the storage structure 5 on the left side in each memory subarray layer 1a; and may be configured to form another memory cell (bit), i.e., a second memory cell, in conjunction with the drain region semiconductor strip 11, the channel semiconductor strip 12, the source region semiconductor strip 13, and the storage structure 5 on the right side in each memory subarray layer 1a.

Therefore, for an odd word line hole 4, the left half or right half of each drain region semiconductor strip 11, channel semiconductor strip 12, and source region semiconductor strip 13 in the same column in each memory subarray layer 1a may cooperate with the corresponding gate strip 2 in the odd word line hole 4 to form a first memory cell. Specifically, in each memory subarray layer 1a, for each column of drain region semiconductor strip 11, channel semiconductor strip 12, and source region semiconductor strip 13: for example, word line holes 4 on the left side of the first column of drain region semiconductor strip 11, channel semiconductor strip 12, and source region semiconductor strip 13 counting from left to right are odd word line holes, and a part of the drain region semiconductor strip 11, channel semiconductor strip 12, and source region semiconductor strip 13 of that column cooperate with a gate strip 2 in a corresponding odd word line hole 4 on its left side for forming a first memory cell. Word line holes 4 on the right side of the second column of the drain region semiconductor strip 11, channel semiconductor strip 12, and source region semiconductor strip 13 counting from left to right are odd word line holes, and a part of the drain region semiconductor strip 11, channel semiconductor strip 12, and source region semiconductor strip 13 of this column cooperate with a gate strip 2 in a corresponding odd word line hole 4 on its right side also for forming a first memory cell.

Similarly, for an even word line hole 4, the other half of each drain region semiconductor strip 11, channel semiconductor strip 12, and source region semiconductor strip 13 in the same column in each memory subarray layer 1a may cooperate with a corresponding gate strip 2 in the even word line hole 4 to form a second memory cell. Specifically, in each memory subarray layer 1a, for each column of drain region semiconductor strip 11, channel semiconductor strip 12, and source region semiconductor strip 13: for example, word line holes 4 on the right side of the first column of drain region semiconductor strip 11, channel semiconductor strip 12, and source region semiconductor strip 13 from left to right are even word line holes, and a part of the drain region semiconductor strip 11, channel semiconductor strip 12, and source region semiconductor strip 13 of that column cooperate with a gate strip 2 in a corresponding even word line hole 4 on its right side for forming a second memory cell. Word line holes 4 on the left side of the second column of the drain region semiconductor strip 11, channel semiconductor strip 12, and source region semiconductor strip 13 from left to right are even word line holes, and a part of the drain region semiconductor strip 11, channel semiconductor strip 12, and source region semiconductor strip 13 of this column cooperate with a gate strip 2 in a corresponding even word line hole 4 on its left side also for forming a second memory cell.

Therefore, in the present disclosure, each gate strip 2 in the memory array 1 is connected to a corresponding word line, and the gate strips 2 in the same row are connected to the corresponding row of word line. The gate strips 2 in the odd word line hole 4 in the same row are connected to the odd word lines 8a in the corresponding row of word line, and the gate strips 2 in the even word line hole 4 in the same row are connected to the even word lines 8b in the corresponding row of word line. In other words, all the first memory cells of the same row in the multiple memory subarray layers 1a are each connected to an odd word line 8a of the corresponding row through odd gate strips 2 in odd word line holes 4 of the same row, and all the second memory cells of the same row in the multiple memory subarray layers 1a are each connected to an even word line 8a of the corresponding row through even gate strips 2 in even word line holes 4 of the same row.

Of course, in other embodiments, it may be, in the same row, every adjacent three, four, or five word line holes 4, etc. are configured as a group, then each line word line includes three, four, five, etc. different types of word lines, and the gate strip 2 in each word line hole 4 in each group is connected to a different type of word line.

Furthermore, as shown in FIG. 11, in the present disclosure, the number of rows of word lines may be defined to be the same as the number of rows of word line holes 4. That is, as shown in FIG. 11, although the gate strips 2 in the word line holes 4 of the same row are connected to a corresponding odd word line 8a and a corresponding even word line 8b, one odd word line 8a and one even word line 8b corresponding to the word line holes 4 of the same row may be defined as one row of word lines corresponding to the row of gate strips 2 (word line holes 4). That is, each row of word line includes one odd word line 8a and one even word line 8b, and the number of rows of word lines is the same as the number of rows of the word line holes 4. It should also be noted that, as shown in FIG. 11, in each row, each of the left side and right side of a word line hole 4 not disposed on ends of the memory array correspond to a column of drain region semiconductor strips 11, channel semiconductor strips 12, and source region semiconductor strips 13. However, from left to right, for a word line hole 4 disposed on a left end of the memory array (first end), only the right side of the word line hole 4 corresponds to a column of drain region semiconductor strips 11, channel semiconductor strips 12, and source region semiconductor strips 13; for a word line hole 4 disposed on a right end of the memory array (last end), only the left side of the word line hole 4 corresponds to a column of drain region semiconductor strips 11, channel semiconductor strips 12, and source region semiconductor strips 13. Therefore, it is understood by those skilled in the art that in each row, the word line hole 4 at the first end and the word line hole 4 at the last end functionally constitute a complete word line hole.

As shown in FIG. 11, in the embodiments, multiple word lines may be arranged above the multiple memory subarray layers 1a in the memory block 10, each of which is connected to corresponding word line holes 4 through word line connection lines 7.

Of course, it is understood by those skilled in the art that multiple word lines may be arranged on another stacked chip, and the stacked chip may be stacked with and electrically connected to a chip in which the memory block 10 is located. For example, the stacked chip may be stacked with the chip in which the memory block 10 is located through hybrid bonding. An end of each word line connection line 7 in the memory block 10 away from the corresponding gate strip 2 serves as a word line connection terminal of the memory block 10 for connecting to the stacked chip stacked together in the height direction Z of the memory block 10.

In addition, as shown in FIG. 11, in another embodiments, the memory block 10 may further include multiple word line lead lines 6a or 6b, each word line further corresponding to a word line lead line 6a or 6b, respectively, with the word line lead line 6a or 6b extending in the height direction Z and away from the gate strip 2 with respect to the word line connection line 7. An end of the word line lead line 6a or 6b away from the word line is configured as a word line connection terminal for connection to the stacked chip stacked together in the height direction Z of the memory block 10. That is, the word lines are arranged on the memory array chip and the control circuit is arranged on the other chip. Of course, those skilled in the art can understand that each word line may be connected to the control circuit on the chip on which the memory block 10 is located through a corresponding word line lead line 6a or 6b, i.e., the relevant lines, memory array, and control circuit are arranged on the same chip.

Referring further to FIG. 12, FIG. 12 is a structural schematic view of a circuit connection of part of memory cells of a memory block according to an embodiment of the present disclosure. As shown in FIG. 12, for each column of drain region semiconductor strips 11, channel semiconductor strips 12, and source region semiconductor strips 13 of the multiple memory subarray layers 1a: the multiple drain region semiconductor strips 11 in the same column are led out through different bit line connection lines 11a arranged on an end of each drain region semiconductor strip 11, the bit line connection line 11a extending along the height direction Z as shown in FIG. 12. For example, for the drain region semiconductor strips 11, the channel semiconductor strips 12, and the source region semiconductor strips 13 in the first column, the drain region semiconductor strip 11 in the first memory subarray layer 1a is led out at its end by a bit line connection line 11a, where an end of the bit line connection line 11a away from the drain region semiconductor strip 11 may be configured as a bit line connection terminal; the drain region semiconductor strip 11 in the second memory subarray layer 1a is led out at its end by another bit line connection line 11a, and an end of the another bit line connection line 11a away from the corresponding drain region semiconductor strip 11 is configured as another bit line connection terminal; . . . , and so on. Therefore, each drain region semiconductor strip 11 may serve as a bit line and receive a bit line voltage through each bit line connection terminal.

It will be understood by those skilled in the art that the memory block 10 may be connected to another stacked chip stacked together in the height direction Z of the memory block 10 through the bit line connection terminal, and provide a bit line voltage to each drain region semiconductor strip 11 in the memory block 10 as a bit line through the bit line connection terminal through another stacked chip. Of course, the bit line connection terminal may be further configured to be connected to the control circuit on the chip where the memory block 10 is located, i.e., the relevant lines, the memory array 1, and the control circuit are arranged on the same chip.

Similarly, for each column of drain region semiconductor strips 11, channel semiconductor strips 12, and source region semiconductor strips 13 of the multiple memory subarray layers 1a, the multiple source region semiconductor strips 13 in the same column are led out through different source line connection lines 13a disposed on an end of each source region semiconductor strip, and the source connection lines 13a extend along the height direction Z.

As shown in FIG. 12, all of the source connection lines 13a in the memory block 10 may be connected to the same common source line 13b, respectively, and a source voltage is applied to the source region semiconductor strips 13 in the memory block 10 through the common source line 13b and the source connection lines 13a.

Of course, it is understood by those skilled in the art that in other embodiments, the memory block 10 may include multiple common source lines 13b, such as a predetermined number of the multiple common source lines 13b, and the source region semiconductor strips 13 in the multiple memory subarray layers 1a may be connected to different multiple common source lines 13b via corresponding source connection lines 13a according to a predetermined rule. In addition, also similar to the bit line connection line 11a corresponding to the drain region semiconductor strip 11, an end of the source connection line 13a corresponding to each source region semiconductor strip 13 away from the source region semiconductor strip 13 may be configured as a source connection terminal to receive the source voltage.

Referring further to FIG. 12, the memory block 10 may further include a common source lead line 13c connected to the common source line 13b, where the common source line 13b is connected to all source connection lines 13a in the memory block 10. The common source lead line 13c extends away from the memory array 1 in the memory block 10 and in the height direction Z. An end of the common source lead line 13c away from the common source line 13b may be configured as a common source connection terminal for connecting to another stacked chip stacked together in the height direction Z in the memory block 10. Of course, the common source connection terminal may further be configured to connect to the control circuit on the chip on which the memory block 10 is located, i.e., the relevant lines, the memory array, and the control circuit are arranged on the same chip.

Of course, it can be understood by those skilled in the art that the common source line 13b may be arranged in another stacked chip stacked with the memory block 10 in the height direction Z. That is, an end of the source connection line 13a away from the corresponding source region semiconductor strip 13 may be configured as a source connection terminal for connection with another stacked chip stacked with the memory block 10 in the height direction Z, such that the common source line 13b are arranged in another stacked chip.

As above, for each column of drain region semiconductor strips 11, channel semiconductor strips 12, and source region semiconductor strips 13 of the multiple memory subarray layers 1a, the multiple channel region semiconductor strips 12 in the same column are led out through different well region connection lines 12a disposed on an end of each channel semiconductor strip 12, and the well region connection lines 12a extend along the height direction Z.

As shown in FIG. 12, all of the well region connection lines 12a in the memory block 10 are each connected to the same common well region line 12b, thereby uniformly applying a well region voltage to all the channel semiconductor strips 12 in the memory block 10 through the common well region line 12b.

Of course, it will be understood by those skilled in the art that the corresponding well region connection line 12a of each channel semiconductor strip 12 in the memory block 10 may be connected to multiple separate well voltage lines 12b to apply a well voltage to each channel semiconductor strip 12 separately. For example, similar to the above, an end of the well region connection line 12a corresponding to each channel semiconductor strip 12 away from the channel semiconductor strip 12 serves as a well connection terminal which is configured to receive a separate well voltage.

Referring further to FIG. 12, all of the well region connection lines 12a in the memory block 10 are each connected to the same common well region line 12b; the memory block 10 may further include a common well region lead line 12c connected to the common well region line 12b, with the common well region lead line 12c extending away from the memory array 1 in the memory block 10 and along the height direction Z. An end of the common well region lead line 12c away from the common well region line 12b may be configured as a common well region connection terminal for connection to another stacked chip stacked with the memory block 10 in the height direction Z. Of course, the common well region connection terminal may further be configured for connection to the control circuit on the chip on which the memory block 10 is located, i.e., the associated lines, the memory array 1, and the control circuit are arranged on the same chip. That is, through the common well region line 12b it is possible to connect all the channel semiconductor strips 12 in the memory block 10 together to receive the same well voltage. In the embodiments, the channel semiconductor strip 12 may be a p-type semiconductor strip forming a p-well, and all the channel semiconductor strips 12 in the memory block 10 are connected together through the common well region line 12b, receiving the same well voltage through the common well region line 12b. In addition, in the embodiments, the memory block 10 may read signals through the same common source line 13b.

Of course, it will be understood by those skilled in the art that the common well region line 12b may be arranged in another stacked chip stacked together with the memory block 10 in the height direction Z. That is, an end of the well region connection line 12a away from the corresponding channel semiconductor strip 12 may be configured as a well region connection terminal for connection to another stacked chip stacked together with the memory block 10 in the height direction Z, thereby arranging the common well region line 12b in another stacked chip.

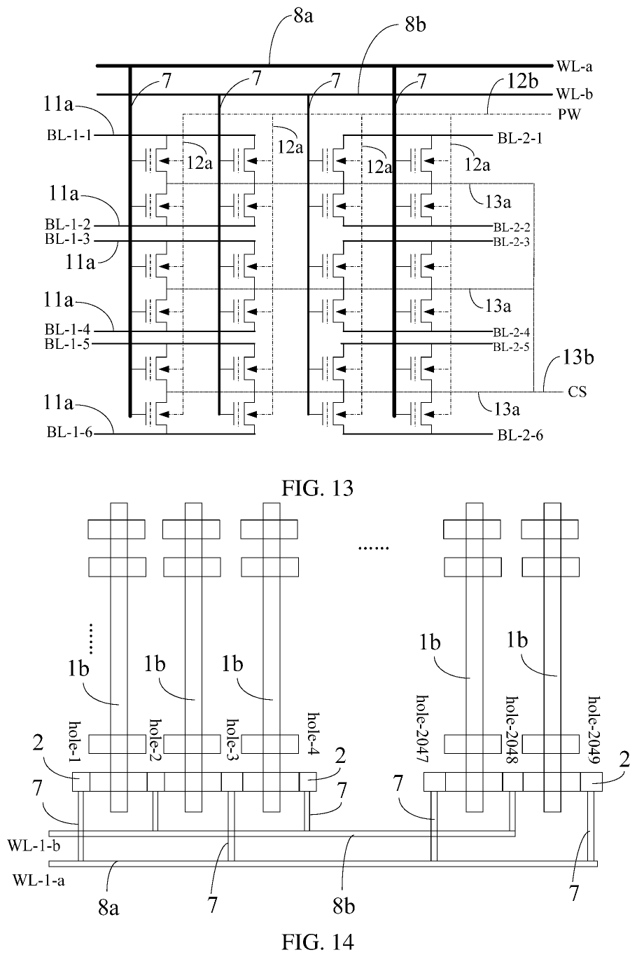

Furthermore, it is noted that, as shown in FIGS. 11 and 13, in the present disclosure, various wires, such as word line, word line connection line 7, word line lead line 6a or 6b, common source line 13b, common well region line 12b, etc. are arranged on a same side of the memory array 1 in the memory block 10, i.e., arranged above the memory array 1. Therefore, it may be ensured that the drain region semiconductor strips 11, the channel semiconductor strips 12, and the source region semiconductor strips 13 in the memory array 1 may be each formed as single-crystal semiconductor strips by epitaxial growth, while only polycrystalline semiconductor strips can be formed by the deposition method. Compared to polycrystalline semiconductor strips formed by deposition, the drain region semiconductor strips 11, channel semiconductor strips 12, and source region semiconductor strips 13 formed by epitaxial growth of the present disclosure may have superior device performance and greatly improve the performance of the relevant memory device. Specifically, when comparing the memory cell adopted with a single-crystal semiconductor (single-crystal drain region semiconductor strip 11, channel semiconductor strip 12, and source region semiconductor strip 13) to the memory cell adopted with a polycrystalline semiconductor, the memory cell with the polycrystalline semiconductor has more interfaces, along which electrons move when passing through the polycrystalline semiconductor, i.e., the distance of electron movement increases and the current decreases significantly. According to a practical empirical test, the current of the memory cell with a polycrystalline semiconductor is only 1/10 of the current of the memory cell with a single-crystal semiconductor. Therefore, the memory block 10 of the present disclosure, with the memory cell with a single-crystal semiconductor, may greatly improve the performance of the memory device. In addition, the low current of the memory cell with the polycrystalline semiconductor affects the read window between the read/write operation (PGM) and the erase operation (ERS) of the memory cell, which has a great impact on the reliability of the memory device, especially for the NOR memory device. In addition, for NOR memory devices, when a hot carrier injection (HCI) method is applied for read/write operations, a single-crystal semiconductor must be adopted to accomplish this.

In addition, since the various wires in the present disclosure are arranged on the same side of the memory array 1 in the memory block 10, it is more convenient to perform the bonding stacking process in three dimensions with the stacked chips, thereby improving the performance of the related memory devices, and manufacturing the chips separately is conducive to optimizing the process and reducing the manufacturing time.

It can be understood by those skilled in the art that in some embodiments, in order for the memory block 10 to obtain better performance, the outermost memory cell may generally serve as a virtual memory cell (dummy cell) and does not perform actual storage works. For example, the memory cells included in the lowermost memory subarray layer 1a may be configured as virtual memory cells. In addition, in some embodiments, the leftmost and rightmost columns of the memory block 10 are each arranged with a column of drain region semiconductor strips 11, channel semiconductor strips 12, and source region semiconductor strips 13, respectively. The memory cells formed by the leftmost column of the drain region semiconductor strips 11, the channel semiconductor strips 12, and the source region semiconductor strips 13, together with the gate strips 2 in the word line holes 4 on the right side and the storage structures 5 between them, and the memory cells formed by the rightmost column of drain region semiconductor strips 11, channel semiconductor strips 12 and source region semiconductor strips 13, together with the gate strips 2 in the word line hole 4 on the left side and the storage structures 5 between them, are also taken as virtual memory cells not participating in the actual storage work.

Therefore, in the present disclosure, unless intentionally pointed out, the memory subarray layers 1a in the entire specification do not include the lowermost memory subarray layer involved in the virtual memory cells (dummy cells); nor do the drain region semiconductor strips 11, the channel semiconductor strips 12, and the source region semiconductor strips 13 include the leftmost column of drain region semiconductor strips 11, channel semiconductor strips 12, and source region semiconductor strips 13, and the rightmost column of drain region semiconductor strips 11, channel semiconductor strips 12, and source region semiconductor strips 13, involved in the virtual memory cells (dummy cells).

Therefore, as above, in a same row, from left to right, the first word line hole 4 only corresponds to a column of drain region semiconductor strips 11, channel semiconductor strips 12, and source region semiconductor strips 13 on the right side; the last word line hole 4 only corresponds to a column of drain region semiconductor strips 11, channel semiconductor strips 12, and source region semiconductor strips 13 on the left side. Therefore, those skilled in the art can understand that the first and last word line holes functionally constitute a complete word line hole.

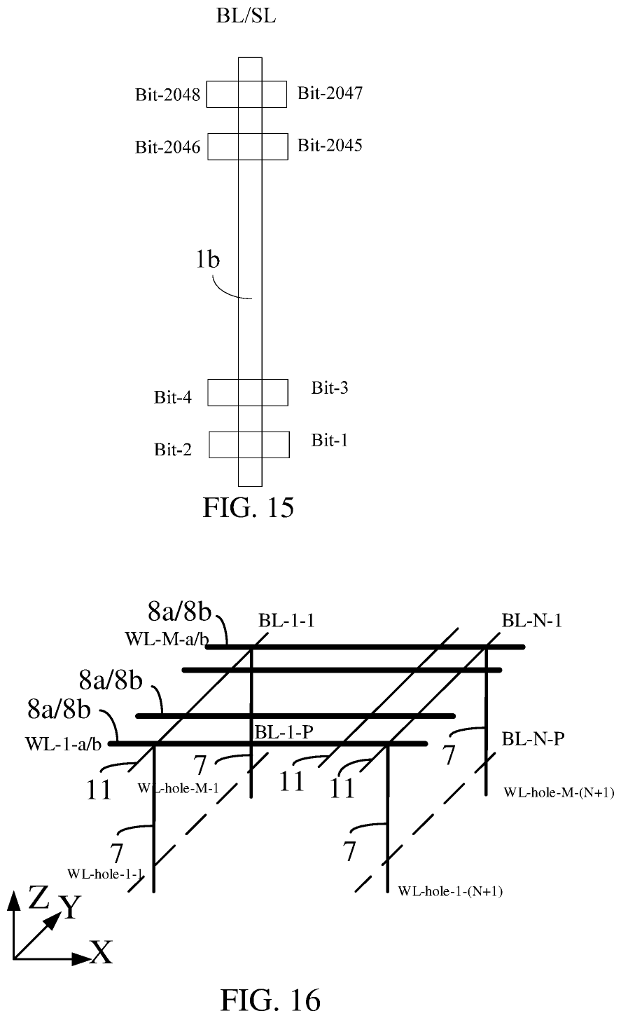

In conjunction with FIGS. 13-16, FIG. 13 is a schematic view of a circuitry of the memory block 10 shown in FIG. 11, FIG. 14 is a schematic sketch of a plan view of the memory block 10 shown in FIG. 11, FIG. 15 is a schematic view of a memory cell corresponding to each layer of bit lines, and FIG. 16 is a schematic view of a three-dimensional distribution of word lines and bit lines.

As shown in FIG. 13, the memory block 10 includes multiple memory subarray layers 1a (six layers herein illustrated in FIG. 13), and the drain region semiconductor strips 11 in the multiple memory subarray layers 1a serve as bit lines, such as BL-1-1, BL-1-2, BL-1-3, BL-1-4, BL-1-5, BL-1-6; multiple columns of drain region semiconductor strips 11 in each memory subarray layer 1a constitute multiple columns of bit lines, such as BL-1-1, BL-2-1, . . . ; the source region semiconductor strips 13 in the multiple memory subarray layers 1a in memory block 10 are connected to a common source line 13b; the well region semiconductor strips 12 in the multiple memory subarray layers 1a in memory block 10 are connected to a common well region line 12b. In addition, the gate strip 2 in the same word line hole 4, together with the drain region semiconductor strips 11, the channel region semiconductor strips 12, and the source region semiconductor strips 13 on the left and right sides, forms two columns of memory cells (as shown in the middle two columns of memory cells), respectively. The gate strips 2 corresponding to the odd word holes 4 are connected to an odd word line WL-a, such as the first, fourth column memory cells, which correspond to the first word line holes and third word line holes, respectively; and the gate strips 2 corresponding to the even word holes 4 are connected to an even word line WL-b, such as the second, third column memory cells, which correspond to the second word line holes.

As shown in FIGS. 14-16, in each memory subarray layer 1a, for the drain region semiconductor strips 11, channel semiconductor strips 12, and source region semiconductor strips 13 extending along the column direction, one column of semiconductor strip structures 1b forms a memory cell (bit) with the gate strip 2 in the left word line hole 4 and another memory cell (bit) with the gate strip 2 in the right word line hole 4. The first row of odd word line holes 4, such as hole-1, hole-3, . . . , are connected to the first row of odd word line WL-1-a, and the first row of even word line holes, such as hole-2, hole-4, . . . , are connected to the first row of even word line WL-1-b.

As shown in FIG. 16, assume that the memory block 10 includes P layers of memory subarray layer 1a, M rows of word lines, and N columns of bit lines. Then, each memory subarray layer 1a includes N columns of drain region semiconductor strips 11 as bit lines, such as shown as BL-1-1, . . . , BL-N-1; for the P-th memory subarray layer 1a, such as BL-1-1, . . . , BL-N-P as shown, the memory block 10 includes N*P drain region semiconductor strips 11 as bit lines. M rows of word lines, e.g., WL-1-a/b, . . . , WL-M-a/b, each have a projection crossed with a projection of each of the N columns of bit lines on a projection plane defined by the row direction X and column direction Y, respectively, to form multiple memory cells. P, M and N are all natural numbers greater than 0.

According to the above conditions, it is understood by those skilled in the art that in the same row direction X, the memory block 10 includes (N+1) word line holes 4, such as shown as WL-hole-1-1, . . . , WL-hole-1-(N+1); and in the same column direction Y, the memory block 10 includes M word line holes 4, such as shown as WL-hole-1-(N+1), . . . , WL-hole-M-(N+1). A side of each column of drain region semiconductor strips 11, channel semiconductor strips 12, and source region semiconductor strips 13 corresponds to M word line holes 4. Each row of word lines (one odd word line 8a and one even word line 8b) corresponds to (N+1) word line holes 4. As above, in the same row, the word line holes 4 at the first and last ends each correspond to only one memory cell in each memory subarray layer 1a, and therefore the word line holes 4 at the first and last ends can be functionally regarded as a complete word line hole; while other word line holes 4 correspond to two memory cells (one on each of the left and right sides) in each memory subarray layer 1a. Therefore, each row of word lines corresponds to N*2*P memory cells. When N is an even number, an odd word line 8a corresponds to (N/2+1) word line holes, which includes word line holes 4 at the first and last ends of the same row, that is, an odd word line 8a also corresponds to N/2 complete word line holes 4, corresponding to (N/2)*P*2 memory cells. An even word line 8b corresponds to N/2 word line holes 4, corresponding to (N/2)*P*2 memory cells. In other words, the number of memory cells corresponding to an odd word lines 8a and the number of memory cells corresponding to an even word lines 8b are the same.

In some embodiments, assume that the memory block 10 specifically includes 8 layers of the memory subarray layers 1a and 1024 rows of word lines, each row of word lines includes an odd word line 8a and an even word line 8b, each layer of the memory subarray layer 1a includes 2048 columns of the drain region semiconductor strips 11 as bit lines, and the memory block 10 includes 2048*8 of the drain region semiconductor strips 11 as bit lines.

In the same row direction X, the memory block 10 includes (2048+1=2049) word line holes 4; in the same column direction Y, the memory block 10 includes 1024 word line holes 4. Each drain region semiconductor strip 11 as a bit line corresponds to 1024 word line holes 4, corresponding to 1024*2 memory cells. Each row of word lines corresponds to (2048+1=2049) word line holes 4. The word line holes 4 at the first and last ends each correspond to only one memory cell in each memory subarray layer 1a, which functionally constitutes a complete word line hole 4, which corresponds to 2048*2*8=32K memory cells. N is an even number 2048, then an odd word line 8a corresponds to (2048/2+1=1025) word line holes, which includes the word line holes 4 at the first and last ends of the same row, that is, an odd word line 8a also corresponds to 1024 complete word line holes 4, which corresponds to (2048/2)*8*2 memory cells; an even word line 8b corresponds to 2048/2 word line holes 4, which corresponds to (2048/2)*8*2 memory cells.

In the memory block 10, ⅛ of the memory cells corresponding to a word line, that is, 1024*2 memory cells, may be defined as one memory page (128 complete word line holes 4). In the memory block 10, 32K memory cells corresponding to one word line may be defined as a sector, which can be understood that one sector corresponds to 2 word lines, (2048+1) word line holes 4 (2048 complete word line holes 4), and 2048*2*8 memory cells (bit).

In the memory block 10, 16 sectors may be defined to form a sub memory block 10 (eblk) including 0.5M memory cells (2048*2*8*16=1024*2*2*8*16=1024*1024*0.5). In specific embodiments, the memory block 10 includes 64 sub memory blocks 10 including 32M memory cells. Each memory block 10 shares a common source line 13b and a common well region line 12b.

The memory block 10 provided in the embodiments includes a memory array 1, and the memory array 1 includes multiple memory cells distributed in a three-dimensional array; the memory array 1 includes multiple memory subarray layers 1a stacked sequentially along a height direction Z, and each memory subarray layer 1a includes a drain region semiconductor layer, a channel semiconductor layer, and a source region semiconductor layer stacked along the height direction Z; the drain region semiconductor layer, channel semiconductor layer, and source region semiconductor layer in each memory subarray layer 1a include multiple drain region semiconductor strips 11, channel semiconductor strips 12, and source region semiconductor strips 13, respectively, distributed along a row direction X, and each drain region semiconductor strip 11, channel semiconductor strip 12, and source region semiconductor strip 13 extends along a column direction Y; multiple gate strips 2 distributed along the column direction Y are arranged on each side of each column of drain region semiconductor strips 11, channel semiconductor strips 12, and source region semiconductor strips 13, each gate strip 2 extending along the height direction Z; in the height direction Z, a projection of at least a part of each gate strip 2 coincides with a projection of a part of a corresponding channel semiconductor strip 12 in each memory subarray layer 1a on a projection plane, the projection plane extending along the height direction Z and the column direction Y. A part of the gate strip 2, a corresponding part of the channel semiconductor strip 12, a part of the drain region semiconductor strip 11 adjacent to the corresponding part of the channel semiconductor bar 12, and a part of the source region semiconductor strip 13 adjacent to the corresponding part of the channel semiconductor bar 12 are configured to form a memory cell. The memory block 10 has a higher storage density compared to a two-dimensional memory array.

As above, the memory block 10 of the present disclosure includes at least two structures of memory cells. In some embodiments, in combination with FIG. 5, FIG. 7, FIG. 8 and FIG. 10, a memory cell is provided that includes a drain region portion 11′, a channel portion 12′, a source region portion 13′ and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and extends along the height direction Z. In the height direction Z, a projection of the gate portion 2′ partially overlaps with a projection of the channel portion 12′ on a projection plane extending along the height direction Z. A storage structure portion 5′ is arranged between the gate portion 2′ and the drain region portion 11′, the channel portion 12′, and the source region portion 13′.

The drain region portion 11′ is a part of the drain region semiconductor layer, the channel portion 12′ is a part of the channel semiconductor layer, and the source region portion 13′ is a part of the source region semiconductor layer of the memory block 10 provided in the above embodiments. The specific structures, functions, and stacking methods of the drain region portion 11′, the channel portion 12′, the source region portion 13′, and the storage structure portion 5′ can be found in those of the drain region semiconductor layer, the channel semiconductor layer, the source region semiconductor layer, and the storage structure 5′ in each of the memory subarray layers 1a described above, and the same or similar technical effects can be achieved, which will not be repeated herein.

When the drain region portion 11′, the channel portion 12′, and the source region portion 13′ are each in a strip structure and the storage structure portion 5′ is a charge trapping storage structure portion, the specific structure of the memory cell can be seen in FIG. 5, and other structures of the memory cell can be seen in the relevant description of FIG. 5 above. When the drain region portion 11′, the channel portion 12′, and the source region portion 13′ each include the body structure 15a and multiple protrusions 15b, and the storage structure portion 5′ is a charge trapping storage structure portion, the specific structure of the memory cell can be seen in FIG. 7, and other structures of the memory cell can be found in the above description of FIG. 7. When the storage structure portion 5′ is a floating gate storage structure portion, the specific structure of the memory cell can be seen in FIG. 10 and FIG. 11, and other structures of the memory cell can be seen in the above description of FIG. 10 and FIG. 11.

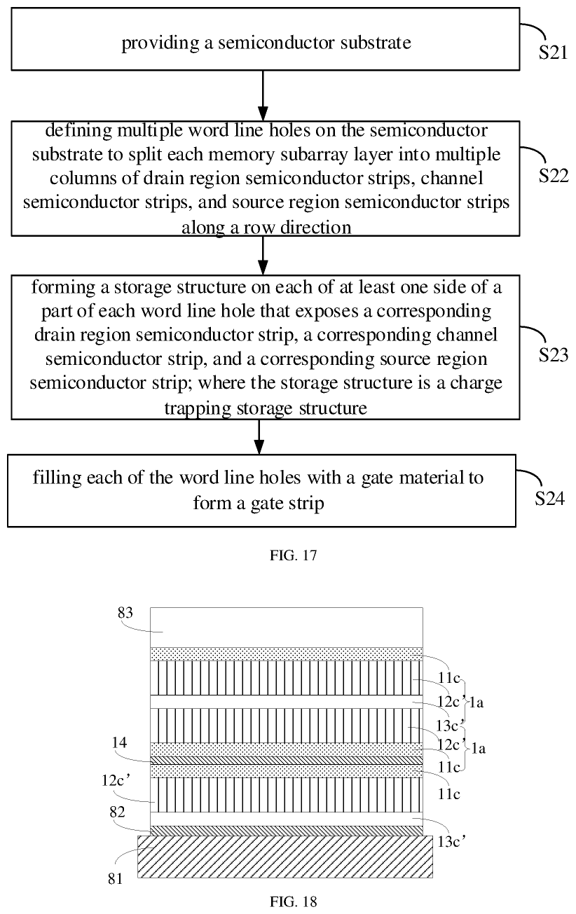

Referring to FIG. 17, FIG. 17 is a flowchart of a manufacturing method of a memory block according to an embodiment of the present disclosure. In the embodiments, a manufacturing method of a memory block is provided that may be configured to prepare the memory block 10 provided in FIG. 2a-FIG. 4 of the above embodiments, and the storage structure 5 of the memory block 10 is a charge trapping storage structure. Specifically, the method includes operations at blocks illustrated in FIG. 17.

At step S21: providing a semiconductor substrate.

Referring to FIG. 18, FIG. 18 is a cross-sectional view of a semiconductor substrate according to an embodiment of the present disclosure. The semiconductor substrate includes a substrate 81, a first single-crystal sacrificial semiconductor layer 82 arranged on the substrate 81, and two memory subarray layers 1a and a second single-crystal sacrificial semiconductor layer 14 stacked and formed alternately in sequence on the first single-crystal sacrificial semiconductor layer 82, until another two memory subarray layers 1a are formed uppermost.

The substrate 81 may be a single-crystal substrate 81; specifically, it may be made of single-crystal silicon. The first single-crystal sacrificial semiconductor layer 82 and/or the second single-crystal sacrificial semiconductor layer 14 may be made of silicon germanium (SiGe). The multiple memory subarray layers 1a are sequentially layered in a height direction Z perpendicular to the substrate 81. Each memory subarray layer 1a includes a drain region semiconductor layer 11c, a channel semiconductor layer 12c′, and a source region semiconductor layer 13c′ stacked along the height direction Z. Two adjacent memory subarray layers 1a in the height direction Z may share a common source region. The two adjacent memory subarray layers 1a may include sequentially stacked drain region semiconductor layer 11c, channel semiconductor layer 12c′, source region semiconductor layer 13c′, channel semiconductor layer 12c′, and drain region semiconductor layer 11c, to achieve sharing the common source region semiconductor layer 13c′. Therefore, for common-source memory subarray layers 1a, a second single-crystal sacrificial semiconductor layer 14 is arranged on every two memory subarray layers 1a to isolate from the other two memory subarray layers 1a. The second single-crystal sacrificial semiconductor layer 14 may be made of a silicon germanium (SiGe) semiconductor material.

It should be noted that the structure shown in FIG. 18 only exemplarily illustrates part of the structure of the semiconductor substrate; it is understood by those skilled in the art that between the first single-crystal sacrificial semiconductor layer 82 and the second single-crystal sacrificial semiconductor layer 14 shown in FIG. 18, two memory subarray layers 1a sharing a common source region semiconductor layer 13c′ are arranged. For the sake of brevity of the accompanying drawings, one layer of the memory subarray layer 1a is shown schematically only for illustrative purposes only.

In some embodiments, step S21 may specifically include the following.

Step S211a: providing a substrate 81.

The substrate 81 may be a single-crystal substrate 81; specifically, it may be a single-crystal silicon.

Step S212a: forming multiple memory subarray layers 1a sequentially on the substrate 81 along the height direction Z.

Step S212a may specifically include the following.

Step a: forming the first single-crystal sacrificial semiconductor layer 82 on the substrate 81 by epitaxial growth.

The first single-crystal sacrificial semiconductor layer 82 may be silicon germanium (SiGe).

Step b: forming two memory subarray layers 1a and a second single-crystal sacrificial semiconductor layer 14 alternately in sequence by epitaxial growth on the first single-crystal sacrificial semiconductor layer 82; continuing to form another two memory subarray layers 1a, optionally continuing to repeatedly stack another second single-crystal sacrificial semiconductor layer 14 and another two common-source memory subarray layers 1a, until forming uppermost two common-source memory subarray layers.

The material of the second single-crystal sacrificial semiconductor layer 14 is the same as the material of the first single-crystal sacrificial semiconductor layer 82, which may also be silicon germanium (SiGe).

It is understood by those skilled in the art that the purpose of providing the first single-crystal sacrificial semiconductor layer 82 on the substrate 81 first is to avoid electrical leakage caused by the multiple memory subarray layers 1a directly contacting the substrate 81. However, as above, the device performance of the lowermost memory subarray layer 1a in the memory block of the present disclosure is poor, and therefore, the memory cells in the lowermost memory subarray layer 1a are generally configured as virtual memory cells and do not participate in the actual memory work. Therefore, it is understood by those skilled in the art that the first single-crystal sacrificial semiconductor layer 82 may not be arranged on the substrate 81, and a single memory subarray layer 1a or two common-source memory subarray layers 1a are formed directly on the substrate 81 as virtual memory cells, on which the second single-crystal sacrificial semiconductor layer 14 and two common-source memory subarray layers 1a are alternately formed by epitaxial growth until the uppermost layer of two common-source memory subarray layers 1a are formed. That is, the lowermost one memory subarray layer 1a or two common-source memory subarray layers 1a, as a virtual memory cell(s), does not participate in the actual memory work, and therefore, it can also prevent electrical leakage to the substrate 81.

Two adjacent memory subarray layers 1a share a common source region, and each two common-source memory subarray layers may be formed in a manner including the following.

Step b1: forming a first single-crystal semiconductor layer of a first doping type by epitaxial growth on the first single-crystal sacrificial semiconductor layer 82 or the second single-crystal sacrificial semiconductor layer 14 of the lower layer.

Specifically, a semiconductor material gas and a first type of dopant ion gas may be simultaneously introduced to form one layer of the first single-crystal semiconductor layer of the first doping type on the first single-crystal sacrificial semiconductor layer 82 or the second single-crystal sacrificial semiconductor layer 14 of the lower layer by epitaxial growth. The first single-crystal semiconductor layer serves as a drain region semiconductor layer 11c (or a source region semiconductor layer 13c′). The first type of dopant ion may be an arsenic ion. The semiconductor material may be an existing semiconductor material for forming the drain region (or source region).

Step b2: forming a second single-crystal semiconductor layer of a second doping type on the first single-crystal semiconductor layer by epitaxial growth.

Specifically, a semiconductor material gas and a second type of dopant ion gas may be simultaneously fed to form one layer of the second single-crystal semiconductor layer of the second doping type on the first single-crystal semiconductor layer by epitaxial growth. The second single-crystal semiconductor layer serves as a channel semiconductor layer 12c′. The second type of dopant ion may be a BF²⁺ ion. The semiconductor material may be an existing semiconductor material for forming a well region.

Step b3: forming a third single-crystal semiconductor layer of the first doping type on the second single-crystal semiconductor layer by epitaxial growth.

Specifically, a semiconductor material gas and a first type of dopant ion gas may be simultaneously fed to form one layer of the third single-crystal semiconductor layer of the first doping type on the second single-crystal semiconductor layer by epitaxial growth. The third single-crystal semiconductor layer serves as a source region semiconductor layer 13c′ (or a drain region semiconductor layer 11c). The first type of dopant ion may be an arsenic ion. The semiconductor material may be an existing semiconductor material for forming the source drain region (or drain region).

In a specific implementation of step S212a, one layer of the second single-crystal sacrificial semiconductor layer 14 is further formed between every two memory subarray layers 1a. Each two adjacent memory subarray layers 1a separated by the second single-crystal sacrificial semiconductor layer 14 in the height direction Z includes sequentially stacked drain region semiconductor layer 11c, channel semiconductor layer 12c′, source region semiconductor layer 13c′, channel semiconductor layer 12c′, and drain region semiconductor layer 11c to share the same source region semiconductor layer 13c′.

Step b4: forming a fourth single-crystal semiconductor layer of a second doping type on the third single-crystal semiconductor layer by epitaxial growth.

This step b4 is performed in a similar manner to step b2. The fourth single-crystal semiconductor layer serve as the channel semiconductor layer 12c′.

Step b5: forming a fifth single-crystal semiconductor layer of a first doping type on the fourth single-crystal semiconductor layer by epitaxial growth.

This step b5 is performed in a similar manner as step b1. The fifth single-crystal semiconductor layer serve as the drain region semiconductor layer 11c (or source region semiconductor layer 13c′).

The first single-crystal semiconductor layer, the second single-crystal semiconductor layer, and the third single-crystal semiconductor layer form a memory subarray layer 1a; the third single-crystal semiconductor layer, the fourth single-crystal semiconductor layer, and the fifth single-crystal semiconductor layer form another memory subarray layer 1a; and the two memory subarray layers 1a share the third single-crystal semiconductor layer as the shared source region semiconductor layer 13c′.

It is understood that, in the embodiments, after step b5, one layer of the second single-crystal sacrificial semiconductor layer 14 is formed on the fifth single-crystal semiconductor layer, after which steps b1-b5 may be repeated on the second single-crystal sacrificial semiconductor layer 14 until a predetermined number of layers of the memory subarray layers 1a is formed.

That is, a second single-crystal sacrificial semiconductor layer 14 is formed between every two memory subarray layers 1a. Moreover, each adjacent two memory subarray layers 1a separated by the second single-crystal sacrificial semiconductor layer 14 in the height direction Z includes sequentially stacked drain region semiconductor layer 11c, channel semiconductor layer 12c′, source region semiconductor layer 13c′, channel semiconductor layer 12c′, and drain region semiconductor layer 11c to share the same source region semiconductor layer 13c′.

Step S213a: forming a first hard mask layer 83 on the multiple memory subarray layers 1a, and defining multiple isolation wall holes 31 in the first hard mask layer 83 and the multiple memory subarray layers 1a, and filling the multiple isolation wall holes 31 with an isolation material to form multiple isolation walls 3 to form a semiconductor substrate.

The first hard mask layer 83 may be made of a silicon dioxide material or a silicon nitride.

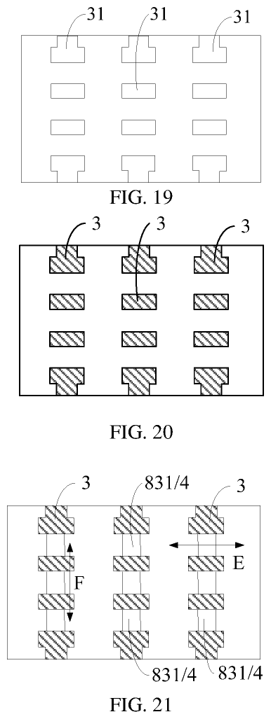

Specifically, referring to FIG. 19, FIG. 19 is a top view of defining multiple isolation wall holes 31 in the memory subarray layers 1a. The multiple isolation wall holes 31 may be formed by etching, and the isolation wall holes 31 are arranged in a matrix in the row direction X and column direction Y, with each isolation wall hole 31 extending in the height direction Z to a surface of the substrate 81. The specific structure of forming the isolation walls 3 in the isolation wall holes 31 can be seen in FIG. 20, which is a top view of the multiple isolation walls 3 formed in the isolation wall holes 31 shown in FIG. 19. Specifically, the isolation wall 3 near an edge of the memory block 10 in the column direction Y extends further in the column direction Y to the edge of the memory block 10 to ensure that the isolation wall 3 at the edge of the column direction Y can completely isolate two adjacent columns of stacked structures 1b. Specifically, in some embodiments, the isolation wall 3 near the edge of the memory block 10 in the column direction Y is a T-shaped isolation wall 3, i.e., the isolation wall 3 includes a lateral portion and a protruding portion toward the edge of the memory block 10 in the column direction Y, and the protruding portion is in contact with the edge of the memory block 10 in the column direction Y to completely isolate the two adjacent columns of stack structures 1b to prevent a short circuit between the two columns of the drain region semiconductor strips 11, the channel semiconductor strips 12, and the source region semiconductor strips 13. The isolation wall 3 and the first hard mask layer 83 may be made of the same material.

In other embodiments, step S21 specifically includes the following operations.

Step S211b: providing the substrate 81.

Step S212b: forming multiple isolation walls 3 on the substrate 81, where the multiple isolation walls 3 are arranged in a matrix in the row direction X and the column direction Y, each isolation wall 3 extending along the height direction Z perpendicular to the substrate 81.

Step S213b: forming multiple memory subarray layers 1a sequentially on the substrate 81 and between the multiple isolation walls 3 along the height direction Z.

The specific implementation process of forming the multiple memory subarray layers 1a is the same or similar to the specific implementation process of forming the multiple memory subarray layers 1a in step S212a above, and the same or similar technical effect can be achieved, as described above.

Step S214b: forming a first hard mask layer 83 on the above structure to form the semiconductor substrate.

Specifically, the first hard mask layer 83 may be formed on the product structure after being processed by step S213b, with the first hard mask layer 83 being disposed on a side surface of the multiple memory subarray layers 1a away from the substrate 81.

At step S22: defining multiple word line holes on the semiconductor substrate to split each memory subarray layer into multiple columns of drain region semiconductor strips, channel semiconductor strips, and source region semiconductor strips along a row direction.

In some embodiments, step S22 specifically includes the following.

Step S221: forming the multiple word line openings 831 on the first hard mask layer 83.

Referring to FIG. 21, FIG. 21 is a top view of forming the multiple word line openings 831 and word line holes 4 on the semiconductor substrate. The multiple word line openings 831 may be formed on the first hard mask layer 83 by etching. The multiple word line openings 831 are arranged in a matrix in the row direction X and the column direction Y.

Step S222: etching the multiple memory subarray layers 1a under the first hard mask layer 83 to form multiple word line holes 4.

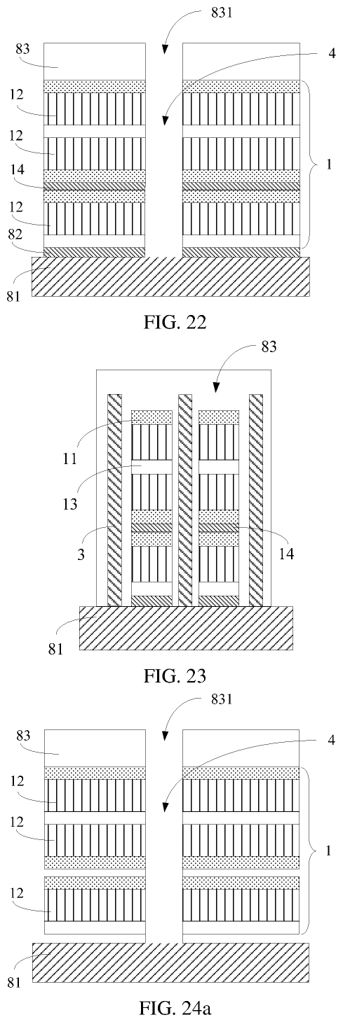

Referring to FIGS. 21 to 23, FIG. 22 is a cross-sectional view in the E direction of the product corresponding to FIG. 21; and FIG. 23 is a cross-sectional view in the F direction of the product corresponding to FIG. 21. Specifically, the word line holes 4 may be formed by etching, and as shown in FIG. 21, the multiple word line holes 4 are spaced apart from the isolation walls 3; and the multiple word line holes 4 are arranged in a matrix in the row direction X and column direction Y, and each memory subarray layer 1a is divided into multiple columns of drain region semiconductor strips 11, channel semiconductor strips 12, and source region semiconductor strips 13 along the row direction X. As shown in FIG. 22, each word line hole 4 extends along the height direction Z, and the left and right sides (such as the left and right sides in the orientation of FIG. 22) of each word line hole 4 at a non-edge position expose parts of two columns of drain region semiconductor strips 11, channel semiconductor strips 12, and source region semiconductor strips 13 of the multiple memory subarray layers 1a, respectively. Each word line hole 4's both sides in the left-right direction are the drain region semiconductor strips 11, channel semiconductor strips 12 and, source region semiconductor strips 13; both sides in the front-rear direction are isolation walls 3. In this step, an etchant with a high etch ratio for the semiconductor material and a low etch ratio for the isolation wall 3 may be applied to process the formation of the word line holes 4. In addition, as shown in FIGS. 2-4, the leftmost edge word line holes 4 correspond to only one column of the drain region semiconductor strips 11, channel semiconductor strips 12 and, source region semiconductor strips 13 on right side; similarly, the rightmost edge word line holes 4 correspond to only one column of the drain region semiconductor strips 11, channel semiconductor strips 12 and, source region semiconductor strips 13 on left side. However, it is understood by those skilled in the art that the leftmost edge line holes 4 and the rightmost edge line holes 4 can be considered as a combination to form a complete word line hole, and the differences in the edge word line holes 4 will not be specifically noted subsequently.

As shown in FIGS. 2 and 4, the multiple word line holes 4 together with the multiple isolation walls 3 divide the drain region semiconductor layer 11c in each memory subarray layer 1a into multiple drain region semiconductor strips 11 spaced at intervals along the row direction X; the channel semiconductor layer 12c′ into multiple channel semiconductor strips 12 spaced at intervals along the row direction X; and the source region semiconductor layer 13c′ into multiple source region semiconductor strips 13 spaced at intervals along the row direction X. The other specific structures and functions of each drain region semiconductor strip 11, channel semiconductor strip 12, and source region semiconductor strip 13 can be found in the above description and will not be repeated here. In addition, as shown in FIG. 23, the interior of the isolation wall 3 may be silicon oxide with a layer of silicon nitride material wrapped around the outside, and the silicon nitride material wrapped around the outside may be the same as the material of the first hard mask layer 83.

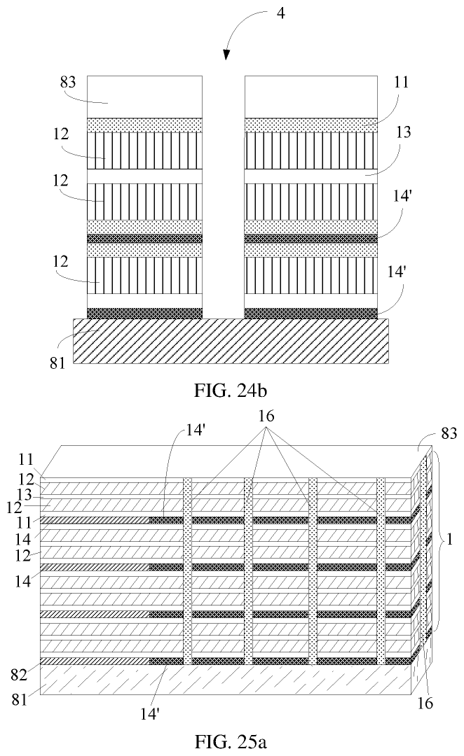

In a specific implementation, referring to FIGS. 24a-24b, FIG. 24a is a schematic view of the structure shown in FIG. 21 after being processed by step S223; FIG. 24b is a schematic view of the structure shown in FIG. 24a after being filled with the insulating material; after step S222, the method may further include the following.

Step S223: removing the first single-crystal sacrificial semiconductor layer 82 and the second single-crystal sacrificial semiconductor layer 14 through the word line holes 4.

Specifically, the first single-crystal sacrificial semiconductor layer 82 and the second single-crystal sacrificial semiconductor layer 14 may be removed by etching.

Step S224: depositing on regions where the removed first single-crystal sacrificial semiconductor layer 82 and the second single-crystal sacrificial semiconductor layer 14 were located to fill the regions with an insulating material, thereby replacing the first single-crystal sacrificial semiconductor layer 82 and the second single-crystal sacrificial semiconductor layer 14 with an insulating isolation layer 14′.

The insulating material may be filled through atomic layer deposition. The insulating material may specifically be silicon oxide. It will be understood by those skilled in the art that after step S223 removing the first single-crystal sacrificial semiconductor layer 82 and the second single-crystal sacrificial semiconductor layer 14, the isolation walls 3 may provide sufficient support to the adjacent stacked structures 1b to facilitate subsequent execution of step S224.

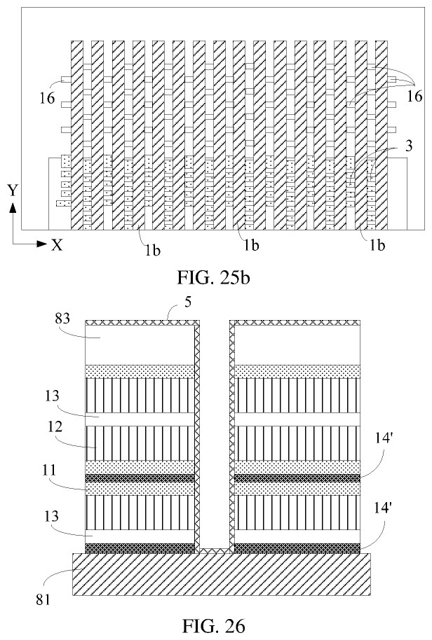

Further, it will be understood by those skilled in the art that in some embodiments, the memory array 1 further includes a support post 16. Specifically, referring to FIG. 25a and FIG. 25b. FIG. 25a is a schematic view of a perspective structure of a memory array according to an embodiment of the present disclosure; and FIG. 25b is a partial plan schematic view of a memory array according to an embodiment of the present disclosure.

As shown in FIGS. 25a and 25b, the memory array 1 further includes multiple support posts 16, each of which extends along the height direction Z of the memory array 1.

As described above, the first single-crystal sacrificial semiconductor layer 82 and the second single-crystal sacrificial semiconductor layer 14 are required to be replaced with the insulating isolation layer 14′. In this step, the first single-crystal sacrificial semiconductor layer 82 and the second single-crystal sacrificial semiconductor layer 14 are partially replaced with the insulating isolation layer 14′, but in subsequent steps, all of the first single-crystal sacrificial semiconductor layer 82 and the second single-crystal sacrificial semiconductor layer 14 are replaced with the insulating isolation layer 14′ as required for electrical isolation. That is, during the manufacturing of the memory array 1, after etching off the first single-crystal sacrificial semiconductor layer 82 and/or the second single-crystal sacrificial semiconductor layer 14, the memory subarray layers 1a in the relevant regions are overhanging. In these relevant regions, when the isolation walls 3 are provided, the isolation walls 3 can provide sufficient support to the overhanging memory subarray layers 1a in these regions to prevent the memory subarray layers 1a from collapsing.

However, the isolation walls 3 may not present in some regions. For example, in a drain/source lead region, the memory subarray layers 1a in this region are not required to manufacture the memory cells, and the drain region semiconductor strips 11, source region semiconductor strips 13, and/or channel semiconductor strips 12 in the memory subarray layers 1a in this region are required to be led out to be connected with corresponding wires. Therefore, in these regions, multiple support posts 16 are required to be arranged between two columns of the stacked structures 1b. In this way, after etching the first single-crystal sacrificial semiconductor layer 82 and/or the second single-crystal sacrificial semiconductor layer 14 in the stacked structures 1b in these regions during the manufacturing of the memory array 1, the support posts 16 can provide sufficient support to the overhanging memory subarray layers 1a to prevent the memory subarray layers 1a from collapsing, and can support the frame of the memory array 1 and maintain the structural stability of the memory array 1.

It will be understood by those skilled in the art that each support post 16 may be made of the same material as the isolation wall 3 and manufactured in the same process steps as the isolation wall 3. That is, the isolation wall 3 and the support post 16 are similar in nature, except that the isolation wall 3 is arranged in the region of the memory array 1 where the memory cells are required to be manufactured, and it serves to support and form the word line holes 4 during the manufacturing of the memory array 1; whereas the support post 16 is formed in another region of the memory array 1 where the memory cell is not required to be manufactured, for example, the drain/source lead region, and it serves to support the memory array 1 during the manufacturing process. Of course, in other embodiments, the support post 16 may be arranged in the region of the memory array 1 where the memory cells are required to be manufactured. For example, when the distance between two adjacent isolation walls 3 is far, and the isolation wall 3 does not provide sufficient support, then the support post 16 may be arranged in this region as needed to assist the isolation wall 3 to provide support. That is, the support post 16 may be arranged according to the actual needs, which is not limited by the present disclosure.

The material of the support post 16 may be silicon oxide or silicon nitride.

Step S23: forming a storage structure on each of at least one side of a part of each word line hole that exposes a corresponding drain region semiconductor strip, a corresponding channel semiconductor strip, and a corresponding source region semiconductor strip; where the storage structure is a charge trapping storage structure.

The product structure after processing by step S23 can be seen specifically in FIG. 26, which is a schematic view of the structure shown in FIG. 24b after processing by step S23. In some embodiments, step S23 specifically includes the following.

Step S231: depositing a first dielectric layer on the semiconductor substrate defining the word line holes 4.

Specifically, one layer of the first dielectric layer is deposited within each word line hole 4 and on a surface of the first hard mask layer 83 away from the substrate 81. The first dielectric layer within each word line hole 4 covers surfaces of the parts of the drain region semiconductor strips 11, channel semiconductor strips 12, and source region semiconductor strips 13 that are exposed on both sides of the word line hole 4. For example, in conjunction with FIG. 4, parts of the first stacked structures 1b and the second stacked structures 1b are exposed through word line hole 4 of the first row and the second column (hereinafter referred to as a first word line hole 4), the first dielectric layer in the first word line hole 4 covers the part of the first column of storage structures 1b exposed through the first word line hole 4, and the part of the second column of semiconductor strip structures 1b exposed through the first word line hole 4.

Step S232: depositing a charge-trapping layer on the first dielectric layer.

The charge-trapping layer is disposed on a side surface of the first dielectric layer away from a corresponding column of semiconductor strip structures 1b.

Step S233: depositing a second dielectric layer on the charge-trapping layer.

The second dielectric layer is disposed on a side surface of the charge-trapping layer away from the first dielectric layer.

At step S24: filling each of the word line holes with a gate material to form a gate strip.

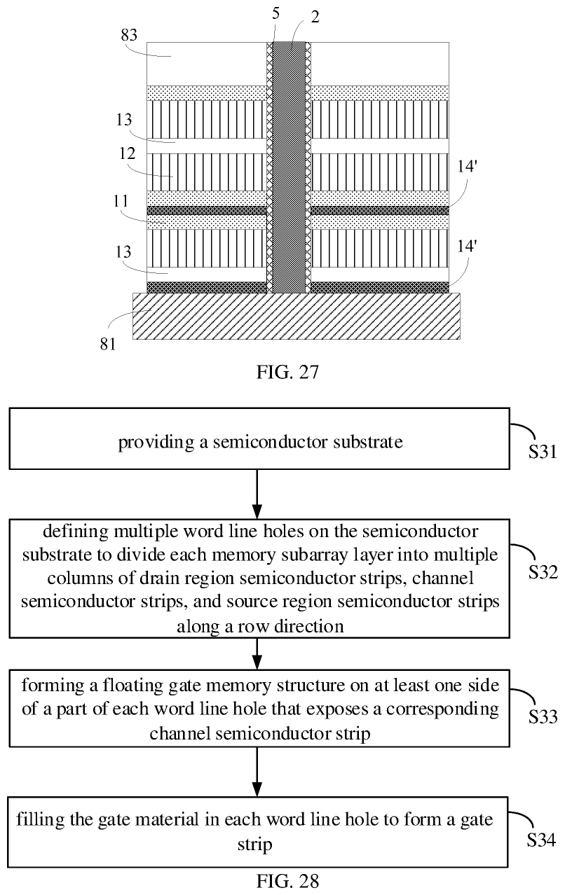

The product structure after processing by step S24 is specified in FIG. 5 and FIG. 27, where FIG. 27 is a schematic view of the structure shown in FIG. 26 after processing by step S24. As shown in FIG. 5, a projection of at least a part of each gate strip 2 coincides with a projection of a part of a corresponding channel semiconductor strip 12 in each memory subarray layer 1a on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, a part of the source region semiconductor strip 13 adjacent to the corresponding part of the channel semiconductor strip 12, and a part of the charge trapping storage structure form a memory cell.

As above, in the embodiments, the storage structure 5 is a charge trapping storage structure, such as an ONO type charge trapping storage structure, such that it can hold the electric charges injected into near the injection point. The electric charges can only move in the injection/removal direction (substantially perpendicular to the extension direction of the charge-trapping layer 52), and cannot move freely in the charge-trapping layer 52, especially not in the extension direction of the charge-trapping layer 52. For the charge trapping storage structure, the charge-trapping layer 52 is only required to have an insulating dielectric arranged on its front and back side, and the charge stored in each memory cell will be fixed near the injection point of the charge-trapping portion and will not move to the charge-trapping portion in other memory cells along the same layer of the charge-trapping layer 52. Therefore, in its corresponding manufacturing method, it is only necessary to form a first dielectric layer 51 and a second dielectric layer 53 on both sides of the charge-trapping layer 52, respectively, to separate the charge-trapping layer 52 from the drain region semiconductor strip 11, the channel semiconductor strip 12, the source region semiconductor strip 13 and the gate strip 2, and its manufacturing method is relatively simple.

Specifically, the above manufacturing method of memory blocks may be configured to prepare the memory blocks involved in the following embodiments. The memory block 10 includes a memory array 1, which includes multiple memory cells distributed in a three-dimensional array. The memory array 1 includes multiple stacked structures 1b distributed along the row direction X, each stacked structure 1b extending along the column direction Y, and each stacked structure 1b includes drain region semiconductor strips 11, channel semiconductor strips 12, and source region semiconductor strips 13 stacked along the height direction Z. Each drain region semiconductor strip 11, channel semiconductor strip 12, and source region semiconductor strip 13 extends along column direction Y, and each drain region semiconductor strip 11, channel semiconductor strip 12, and source region semiconductor strip 13 is a single-crystal semiconductor strip.

Multiple gate strips 2 are arranged on each of two sides of each stacked structure 1b along the column direction Y, and each gate strip 2 extends along the height direction Z. In the height direction Z, a projection of at least a part of each gate strip 2 coincides with a projection of a part of a corresponding channel semiconductor strip 12 on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor bar 12, and a part of the source region semiconductor strip 13 adjacent to the corresponding part of the channel semiconductor bar 12 form a memory cell. Specifically, a charge trapping storage structure is arranged between each gate strip 2 and corresponding drain region semiconductor strips 11, channel semiconductor strips 12, and source region semiconductor strips 13 in the multiple memory subarray layers 1a. The specific structure and function of the charge trapping storage structure, and the position relationship with the memory array 1, etc., can be found in the relevant description above.

Specifically, each stacked structure 1b includes multiple stacked substructures, each stacked substructure including a drain region semiconductor strip 11, a channel semiconductor strip 12, a source region semiconductor strip 13, a channel semiconductor strip 12, and a drain region semiconductor strip 11 stacked sequentially along the height direction Z to share the same source region semiconductor strip 13. Specifically, an interlayer isolation layer is arranged between two adjacent stacked substructures (i.e., the above-mentioned insulating isolation layer 14′) to isolate the two adjacent stacked substructures from each other.

Multiple isolation walls 3 distributed along the column direction Y are arranged on each side of each stacked structure 1b, and each isolation wall 3 extends along the height direction Z and the row direction X to separate at least part of the two adjacent columns of the stacked structures 1b. The isolation walls 3 further serve as support structures to support the two adjacent columns of the stacked structures 1b in the manufacturing process as shown above to facilitate the subsequent manufacturing process. Of course, after the manufacturing process, the isolation walls 3 may be further configured as support structures to support the two adjacent columns of the stacked structures 1b. The isolation wall 3 near an edge of the memory block 10 in the column direction Y is a T-shaped wall to completely isolate the two adjacent columns of the stacked structures 1b. Of course, the isolation wall 3 at the edge in the column direction Y may take other shapes, such as extending in the column direction Y to the edge of the memory block 10 in the column direction Y, etc., as long as it can completely isolate the two adjacent columns of the stacked structures 1b at the edge of the memory block 10 in the column direction Y.

In the column direction Y, a gate strip 2 is arranged between two adjacent isolation walls 3 on the same column; parts of two adjacent columns of the stacked structures 1b share the same gate strip 2.

Other structures and functions of the memory block 10 provided in the embodiments can be found in the specific description of the memory block 10 provided in any of the above embodiments where the storage structure is a charge trapping storage structure, and will not be repeated herein.

The memory cell corresponding to the above manufacturing method includes: a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and along the height direction Z. In the height direction Z, a projection of the gate portion 2′ at least partially coincides with a projection of the channel portion 12′ on a projection plane, the projection plane extending along the height direction Z and the drain region portion 11′. A charge trapping storage structure portion is arranged between the gate portion 2′ and the drain region portion 11′, the channel portion 12′, and the source region portion 13′.

The specific structure and position of the charge trapping storage structure portion can be found in the above description. Other structures and functions of the memory cell can be found in the description of the memory cell with the charge trapping storage structure portion 5′ involved in the above embodiments, which will not be repeated herein.

In other embodiments, referring FIG. 28, FIG. 28 is a flowchart of a manufacturing method of a memory block according to another embodiment of the present disclosure. A storage structure of the memory block 10 herein is a floating gate storage structure. Another manufacturing method of a memory block is provided, which may be configured to prepare the memory block 10 corresponding to FIGS. 9-FIG. 11 above. The method specifically includes operations at blocks illustrated in FIG. 28.

At step S31: providing a semiconductor substrate.

At step S32: defining multiple word line holes on the semiconductor substrate to divide each memory subarray layer into multiple columns of drain region semiconductor strips, channel semiconductor strips, and source region semiconductor strips along a row direction.

The specific implementation process of step S31-step S32 is the same or similar to the specific implementation process of step S21-step S22 above, and can achieve the same or similar technical effect, as can be seen above, which will not be repeated herein.

It should be noted that the subsequent steps are the relevant steps after the first single-crystal sacrificial semiconductor layer 82 and the second single-crystal sacrificial semiconductor layer 14 are replaced by the insulating isolation layer 14′ using the word line holes 4. The relevant process steps of the embodiments are the same as the relevant process steps of the previous embodiments, and will not be repeated herein.

At step S33: forming a floating gate storage structure on at least one side of a part of each word line hole that exposes a corresponding channel semiconductor strip.

Step S33 may specifically include the following.

Step S331: forming a first insulating dielectric layer 85a on at least one side of a part of each word line hole 4 that exposes a corresponding drain region semiconductor strip 11, channel semiconductor strip 12, and source region semiconductor strip 13.

In some embodiments, step S331 specifically includes the following.

Step A: removing a part of the corresponding channel semiconductor strip 12 exposed by each word line hole 4 to define a first recess 84.

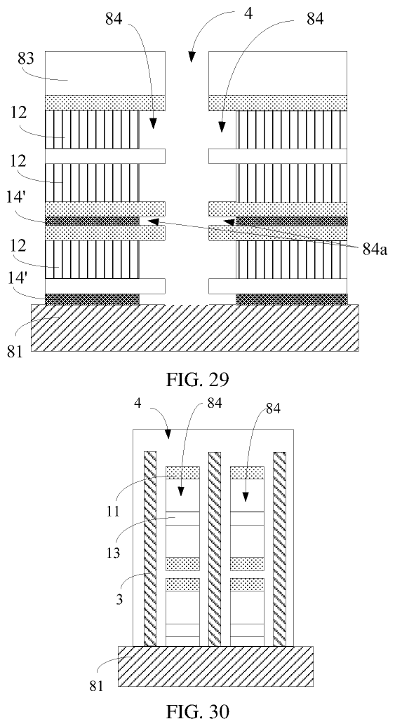

Referring to FIGS. 29-30, FIG. 29 is a schematic view of the structure shown in FIG. 24b defining the first recess 84; FIG. 30 is a cross-sectional view of the product corresponding to FIG. 29 in another direction. Specifically, parts of the channel semiconductor strips 12 exposed on both sides of each word line hole 4 may be removed by etching to define the first recesses 84, for example by acid etching.

In the embodiments, etching may be performed using an etchant with a high etch ratio for the channel semiconductor strips 12 and the insulating isolation layers 14′, and with a low etch ratio for the drain region semiconductor strips 11 and the source region semiconductor strips 13. For example, when the drain region semiconductor strips 11 and the source region semiconductor strips 13 are N-type semiconductor strips and the channel semiconductor strips 12 are P-type semiconductor strips, then an etchant with a high etch ratio for the P-type semiconductor material and with a low etch ratio for the N-type semiconductor material may be applied for selective etching, such that only the parts of the channel semiconductor strips 12 and the insulating isolation layers 14′ exposed on both sides of the word line hole 4 are etched, thereby defining the first recesses 84.

It will be understood by those skilled in the art that when acid etching is performed on a part of the channel semiconductor strips 12, the etchant etches a part of the insulating isolation layers 14′ while etching the part of the channel semiconductor strip 12, defining third recesses 84a, as shown in FIG. 29. Although this etching is unfavorable, the third recesses 84a will be backfilled in subsequent steps, in particular with the same material as the insulating isolation layer 14′.

Although in FIG. 29, the third recesses 84a are formed by etching, in other embodiments, the third recesses 84a may not be necessarily formed when the etching selection ratio is well controlled.

Step B: filling the multiple first recesses 84 each with a first insulating dielectric 85.

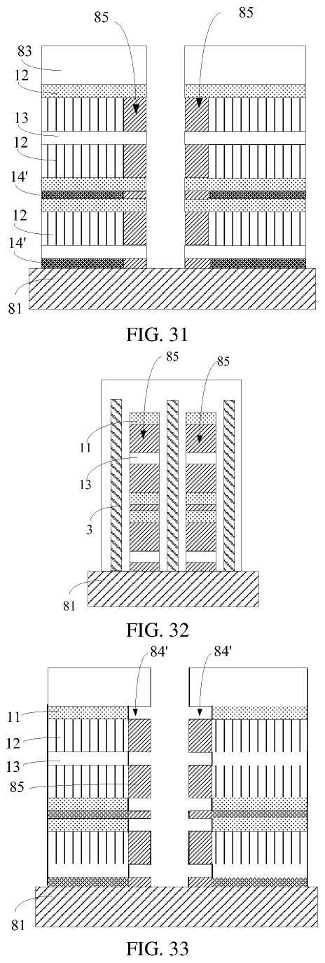

Referring to FIGS. 31-32, FIG. 31 is a schematic view of the formation of the first insulating dielectric 85 on the structure shown in FIG. 29; FIG. 32 is a cross-sectional view in the F-direction of the product corresponding to FIG. 31. Specifically, the first insulating dielectric 85 may be filled in the first recesses 84 by deposition. The third recesses 84a may be also filled with the first insulating dielectric 85 by deposition. The first insulating dielectric 85 may be made of the same material as the insulating layer 14′, e.g., silicon oxide.

When the first recesses 84 are filled with the first insulating dielectric 85, the third recess 84a, formed by etching off parts of the insulating layers 14′, are also filled with the first insulating dielectric 85. Since the material of the first insulating dielectric 85 is silicon oxide, which is the same material as the insulating isolation layers 14′, the device performance will not be affected.

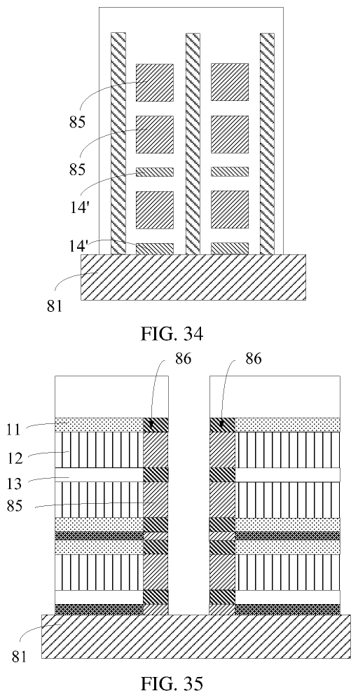

In some embodiments, referring to FIGS. 33-35, FIG. 33 is a schematic view of the structure shown in FIG. 31 after defining the second recesses 84′; FIG. 34 is a cross-sectional view of the F-direction of the product corresponding to FIG. 33; and FIG. 35 is a schematic view of the structure shown in FIG. 33 after forming a second insulating dielectric 86. After step B, the method may further include the following.

Step C: removing parts of corresponding drain region semiconductor strips 11 and parts of corresponding source region semiconductor strips 13 exposed on both sides of each word line hole 4 to define multiple second recesses 84′; where each second recess 84′ exposes at least a part of a corresponding first insulating dielectric 85.

The second recesses 84′ may be defined by etching. A vertical cross-sectional view of the product after removing the parts of the drain region semiconductor strips 11 and the parts of the source region semiconductor strips 13 exposed on both sides of each word line hole 4 to define the multiple second recesses 84′ can be seen in FIG. 33. Specifically, in this step, an etchant with a low etch ratio for the channel semiconductor strip 12 and with a high etch ratio for the drain region semiconductor strip 11 and source region semiconductor strips 13 may be applied. For example, when the drain region semiconductor strips 11 and the source region semiconductor strips 13 are N-type semiconductor strips and the channel semiconductor strips 12 are P-type semiconductor strips, an etchant with a high etch ratio for the N-type semiconductor material and with a low etch ratio for the P-type semiconductor material may be applied for selective etching, such that only the parts of the drain region semiconductor strips 11 and the parts of the source region semiconductor strips 13 exposed on both sides of the exposed line hole 4 are etched to define the second recesses 84′.

Step D: forming a second insulating dielectric 86 in each second recess 84′.

The second insulating dielectric 86 may be formed by deposition. The second insulating dielectric 86 may be made of silicon nitride. After Step D, step E is performed.

Step E: removing the first insulating dielectric 85 in the first recesses 84 to empty the first recesses 84, and depositing a first insulating dielectric layer 85a on walls of the first recesses 84.

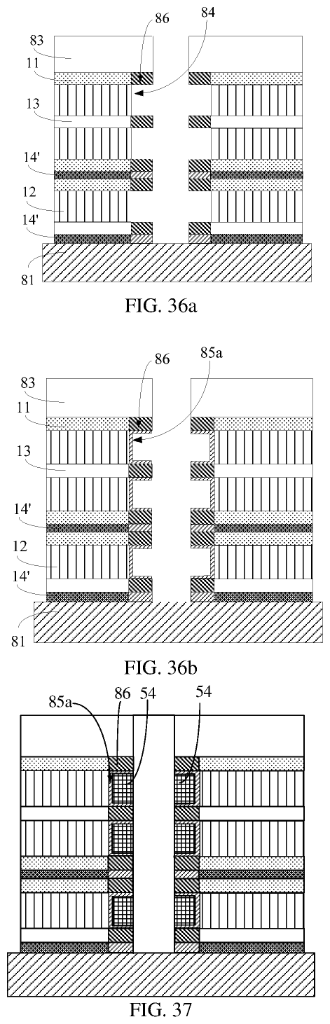

As shown in FIGS. 36a-36b, FIG. 36a is a schematic view of the structure after removing the first insulating dielectric 85 in the first recesses 84; FIG. 36b is a schematic view of the structure shown in FIG. 35 forming the first insulating dielectric layer 85a. In this step, etching may be performed using an etchant with a high etch ratio for the first insulating dielectric 85 and with a low etch ratio for the second insulating dielectric 86, e.g., an etchant with a high etch ratio for silicon oxide and with a low etch ratio for silicon nitride. Further, by controlling the amount of etchant, etch speed, and etch time to etch off the first insulating dielectric 85. Thereafter, a first insulating dielectric layer 85a is formed by deposition or growth in the first recesses 84 where the first insulating dielectric 85 was etched off; the first insulating dielectric layer 85a has a gate-shaped (U-shaped) cross-section for defining a floating gate slot.

Step S332: forming a floating gate 54 on a side surface of a part of the first insulating dielectric layer 85a away from a corresponding channel semiconductor strip 12.

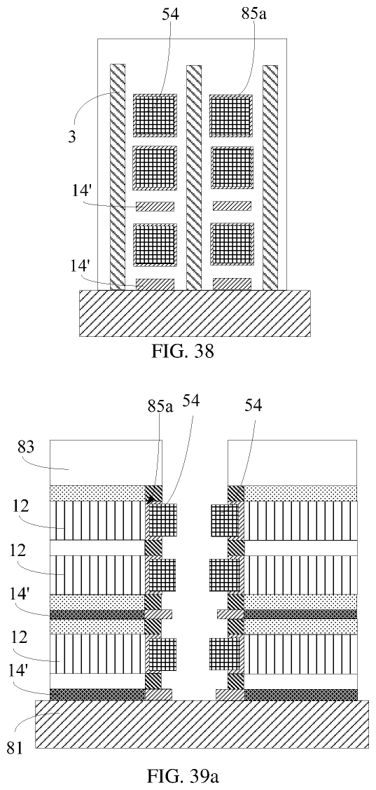

The structure of the product after step S332 can be seen in FIGS. 37-38. FIG. 37 is a schematic view of the structure shown in FIG. 36b forming the floating gate 54; FIG. 38 is a cross-sectional view of the product corresponding to FIG. 37 in another direction.

Specifically, a floating gate material may be deposited in the floating gate slot to form the floating gate 54, and the floating gate material may include polycrystalline silicon material.

Step S333: forming a second insulating dielectric layer 85b on a side wall of each word line hole, and the second insulating dielectric layer 85b cooperates with the first insulating dielectric layer 85a to wrap any surface of each floating gate 54.

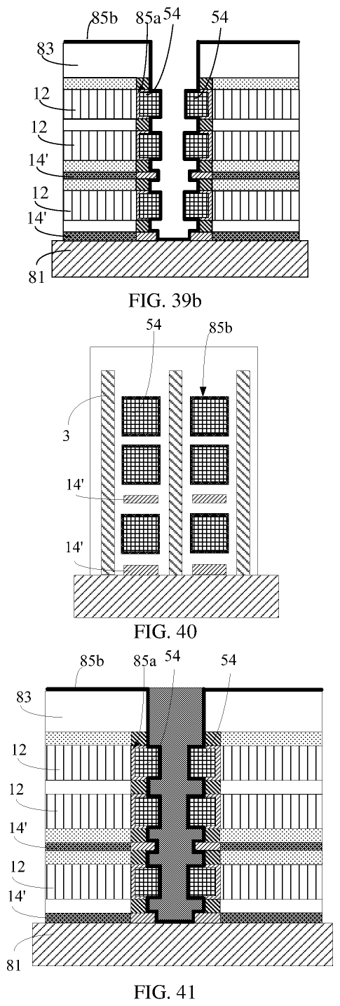

In some embodiments, referring to FIG. 39a, FIG. 39 is a schematic view of the structure after removing a part of the first hard mask layer around each word line hole and a part of the second insulating dielectric in each second recess. Step S333 may specifically include the following.

Step 3331: removing a part of the first hard mask layer 83 around each word line hole 4 and a part of the second insulating dielectric 86 in each second recess 84′, to widen the word line hole 4 and expose at least a part of each floating gate 54.

It will be understood that after Step 3331, the first insulating dielectric layer 85a wraps only a part of the floating gate 54.

Referring to FIGS. 39b-40, FIG. 39b is a schematic view of the second insulating dielectric layer 85b;

FIG. 40 is a cross-sectional view of the F-direction of the product corresponding to FIG. 39b.

Step 3332: forming the second insulating dielectric layer 85b on the side wall of each of widened word line hole 4 such that the second insulating dielectric layer 85b wraps around an exposed portion of each floating gate 54.

As can be seen in FIG. 39b, the first insulating dielectric layer 85a and the second insulating dielectric layer 85b completely wrap and isolate various surfaces of the floating gates 54. The second insulating dielectric layer 85b includes a multilayer structure including a silicon oxide layer, a silicon nitride layer, and another silicon oxide layer. By widening the word line hole 4, it is ensured that the second insulating dielectric layer 85b partially covers each of five surfaces of the floating gate 54. In this way, the second insulating dielectric layer 85b and the first insulating dielectric layer 85a can wrap any surface of the floating gate 54. Specifically, as shown in FIG. 39b, apart of the second insulating dielectric layer 85b covers the five surfaces of each floating gate 54, where four of the five surfaces of each floating gate 54 are at least partially covered by the part of the second insulating dielectric layer 85b and the remaining one of the five surfaces is fully covered by the second insulating dielectric layer 85b. Further, the first insulating dielectric layer 85a, in addition to covering the surface of the floating gate 54 near the channel semiconductor strip 12, also covers parts of the other four surfaces of the floating gate 54. Therefore, the first insulating dielectric layer 85a, in conjunction with the second insulating dielectric layer 85b, may wrap all surfaces of the floating gates 54.

Step S34: filling the gate material in each word line hole to form a gate strip.

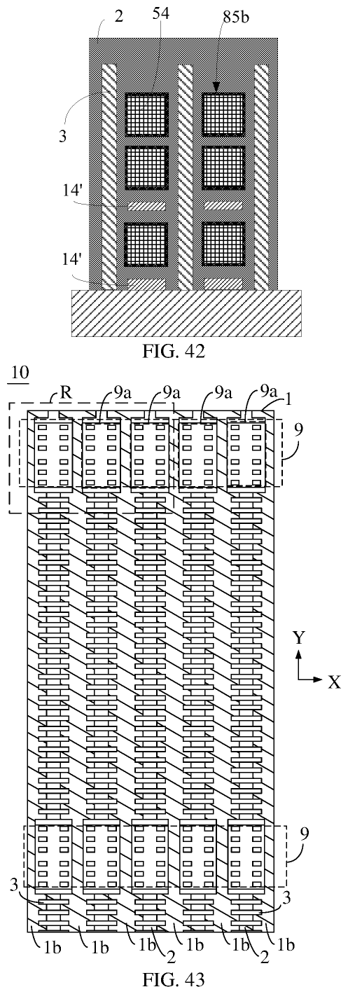

The structure of the product after step S34 can be seen in FIGS. 41-42, where FIG. 41 is a schematic view of the formation of gate strips 2; FIG. 42 is a cross-sectional view of the product corresponding to FIG. 41 in another direction. The gate strip 2 wraps all other surfaces of the floating gate 54 other than those wrapped by the first insulating dielectric layer 85a to improve the coupling rate. That is, a surface of the gate strip 2 extends in the extension direction of the second insulating dielectric layer 85b, thereby sandwiching the second insulating dielectric layer 85b and wrapping the five surfaces of the floating gate 54, and four of the five surfaces of the floating gate 54 are at least partially wrapped by the gate strip 2 through the second insulating dielectric layer 85b. The specific structure of each memory cell in the memory block 10 produced by this manufacturing method can be seen in FIG. 10.

A projection of at least a part of each gate strip 2 coincides with a projection of a part of a corresponding channel semiconductor strip 12 in each memory subarray layer 1a on a projection plane, the projection plane extending along the height direction Z and the column direction Y. A part of the gate strip 2, a corresponding part of the channel semiconductor strip 12, a part of the drain region semiconductor strip 11 adjacent to the corresponding part of the channel semiconductor strip 12, a part of the source region semiconductor strip 13 adjacent to the corresponding part of the channel semiconductor strip 12, and a part of a corresponding floating gate storage structure, form a memory cell.

In the embodiments, the storage structure 5 is a floating gate storage structure, as above, and the floating gate storage structure is characterized by the fact that the charge injected in can be uniformly distributed in the entire floating gate 54, and the charge can move not only in the injection/removal direction (substantially perpendicular to the extension direction of the floating gate), but also in the floating gate 54, particularly in the extension direction of the floating gate 54. Therefore, in the floating gate storage structure, the floating gate 54 of each memory cell is independent, and each surface of each floating gate 54 is required to be covered by an insulating dielectric to be isolated from each other, thereby preventing the charges stored in the floating gates 54 in one memory cell from moving to the floating gates 54 in other memory cells. Therefore, in the manufacturing method thereof, the floating gate 54 of each memory cell is independent, and the insulating dielectric formed by the first insulating dielectric layer 85a and the second insulating dielectric layer 85b can completely wrap and isolate the various surfaces of the floating gates 54, such that the floating gates 54 of each memory cell are independent and the charge stored in each floating gate 54 cannot move to the floating gates 54 of other memory cells.

Specifically, the manufacturing method may be configured to prepare the memory block involved in the following embodiments. The memory block 10 includes a memory array 1, which includes multiple memory cells distributed in a three-dimensional array. The memory array 1 includes multiple stacked structures 1b distributed along the row direction X, each stacked structure 1b extending along the column direction Y, and each stacked structure 1b includes drain region semiconductor strips 11, channel semiconductor strips 12, and source region semiconductor strips 13 stacked along the height direction Z. Each drain region semiconductor strip 11, channel semiconductor strip 12, and source region semiconductor strip 13 extends along column direction Y, and each drain region semiconductor strip 11, channel semiconductor strip 12, and source region semiconductor strip 13 is a single-crystal semiconductor strip.

Multiple gate strips 2 are arranged on each of two sides of each stacked structure 1b along the column direction Y, and each gate strip 2 extends along the height direction Z. In the height direction Z, a projection of at least a part of each gate strip 2 coincides with a projection of a part of a corresponding channel semiconductor strip 12 on a projection plane extending along the height direction Z and the column direction Y. A part of the gate strip 2, a corresponding part of the channel semiconductor strip 12, a part of the drain region semiconductor strip 11 adjacent to the corresponding part of the channel semiconductor bar 12, and a part of the source region semiconductor strip 13 adjacent to the corresponding part of the channel semiconductor bar 12 form a memory cell. Specifically, a floating gate storage structure is arranged between each gate strip 2 and corresponding drain region semiconductor strips 11, channel semiconductor strips 12, and source region semiconductor strips 13 in the multiple memory subarray layers 1a. The floating gate storage structure includes multiple first insulating dielectric layers 85a, multiple floating gates 54, and the second insulating dielectric layer 85b. Each first insulating dielectric layer 85a is disposed between at least a corresponding channel semiconductor strip 12 and a corresponding floating gate 54, the floating gate 54 is located disposed a corresponding first insulating dielectric layer 85a and the second insulating dielectric layer 85b, and the second dielectric layer 85b is disposed between the floating gates 54 and the gate strip 2.

Specifically, each stacked structure 1b includes multiple stacked substructures, each stacked substructure including a drain region semiconductor strip 11, a channel semiconductor strip 12, a source region semiconductor strip 13, a channel semiconductor strip 12, and a drain region semiconductor strip 11 stacked sequentially along the height direction Z to share the same source region semiconductor strip 13. Specifically, an interlayer isolation layer is arranged between two adjacent stacked substructures to isolate the two adjacent stacked substructures from each other.

Multiple isolation walls 3 distributed along the column direction Y are arranged on each side of each stacked structure 1b, and each isolation wall 3 extends along the height direction Z and the row direction X to separate at least part of the two adjacent columns of the stacked structures 1b. The isolation walls 3 further serve as support structures to support the two adjacent columns of the stacked structures 1b. The isolation wall 3 near an edge of the memory block 10 in the column direction Y is a T-shaped wall to completely isolate the two adjacent columns of the stacked structures 1b.

In the column direction Y, a gate strip 2 is arranged between two adjacent isolation walls 3 on the same column; parts of two adjacent columns of the stacked structures 1b share the same gate strip 2.

Other structures and functions of the memory block 10 provided in the embodiments can be found in the specific description of the memory block 10 provided in any of the above embodiments where the storage structure is a floating gate storage structure, and will not be repeated herein.

The memory cell corresponding to the above manufacturing method includes: a drain region portion 11′, a channel portion 12′, a source region portion 13′, and a gate portion 2′. The drain region portion 11′, the channel portion 12′, and the source region portion 13′ are stacked along the height direction Z, and the gate portion 2′ is disposed on one side of the drain region portion 11′, the channel portion 12′, and the source region portion 13′, and along the height direction Z. In the height direction Z, a projection of the gate portion 2′ and a projection the channel portion 12′ on a projection plane extending along the height direction Z at least partially coincide, the projection plane being located on a side of the drain region portion 11′, the channel portion 12′, and the source region portion 13′ and extending along the height direction Z and column direction Y. A floating gate storage structure portion is arranged between the gate portion 2′ and the drain region portion 11′, the channel portion 12′, and the source region portion 13′.

The floating gate storage structure portion specifically includes a corresponding first insulating dielectric layer 85a, a corresponding floating gate 54, and a part of the second insulating dielectric layer 85b. The first insulating dielectric layer 85a is disposed between the channel portion 12′ and the floating gate 54, the floating gate 54 is disposed between the first insulating dielectric layer 85a and the part of the second insulating dielectric layer 85b, and the part of the second insulating dielectric layer 85b is disposed between the floating gate 54 and the gate strip 2. The part of the second insulating dielectric layer 85b covers five surfaces of the floating gate 54. One of the five surfaces of the floating gate 54 is fully covered by the second insulating dielectric layer 85b. The part of the second insulating dielectric layer 85b includes a multilayer structure including a part of a silicon oxide layer, a part of a silicon nitride layer, and a part of another silicon oxide layer.

Other structures and functions of the memory cell can be found in the description of the memory cell for which the storage structure portion 5′ is a floating gate storage structure portion involved in the above-described embodiments, and will not be repeated herein.

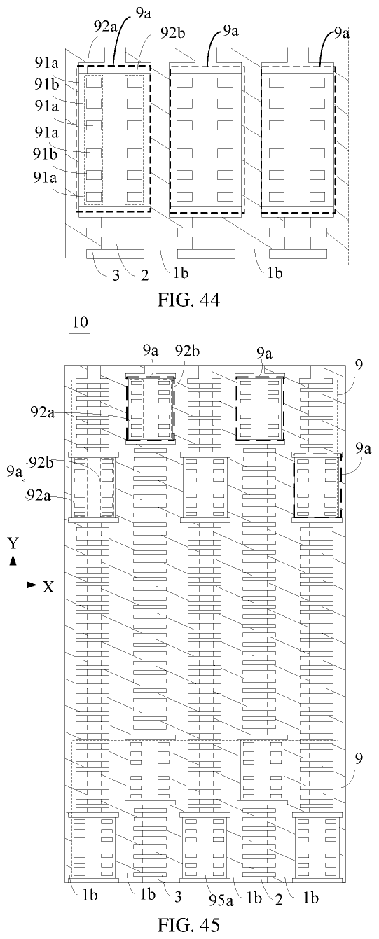

Referring to FIGS. 1 to 44, FIG. 43 is a plan schematic view of a memory block according to further another embodiment of the present disclosure; and FIG. 44 is an enlarged view of region R in FIG. 43. In the embodiments, another memory block 10 is provided, which differs from the memory block 10 provided in any of the above embodiments in that the memory block 10 further includes multiple drain/source connection terminal arrays 9. The multiple drain/source connection terminal arrays 9 are arranged on the memory array 1, with a drain/source connection terminal array 9 arranged at a predetermined interval of the memory array 1 in the column direction Y. It should be noted that the planar schematic views involved in the present disclosure are only part of the schematic views of the corresponding structure, and the other side edge of the corresponding structure are not shown.

As shown in FIG. 43, each drain/source connection terminal array 9 includes multiple drain/source connection terminal subarrays 9a distributed along the row direction X. The multiple drain/source connection terminal subarrays 9a distributed along the row direction X in each drain/source connection terminal array 9 are aligned with each other in column direction Y. Alternatively, as shown in FIG. 45, the multiple drain/source connection terminal arrays 9 are aligned with each other in the column direction Y. Alternatively, as shown in FIG. 45, FIG. 45 is a top schematic view of a memory block according to further another embodiment of the present disclosure. Each drain/source connection terminal array 9 includes multiple drain/source connection terminal subarrays 9a distributed along the row direction X, and each two adjacent drain/source connection terminal subarrays 9a are staggered with each other in the column direction Y; in this way, it may be avoided that two adjacent drain/source connection terminal subarrays 9a in the column direction Y interrupt each other due to the limited size of the memory array 1.

In conjunction with FIG. 44, each drain/source connection terminal subarray 9a includes multiple drain/source connection terminals 91a/91b disposed along the row direction X, i.e., including multiple drain connection terminals 91a and multiple source connection terminals 91b. Each drain/source connection terminal 91a/91b is connected to a drain region/source region semiconductor strip 11/13 in a corresponding column of semiconductor strip structures 1b, respectively, and each drain/source connection terminal 91a/91b in each drain/source connection terminal subarray 9a is connected to the drain/source region semiconductor strips 11/13 in corresponding two adjacent columns of semiconductor strip structures 1b. That is, some of the multiple drain/source ends 91a/91b in each drain/source end subarray 9a are connected to some of the drain/source region semiconductor strips 11/13 in one column of semiconductor strip structures 1b, others are connected to some of the drain/source region semiconductor strips 11/13 in another adjacent column of semiconductor strip structures 1b.

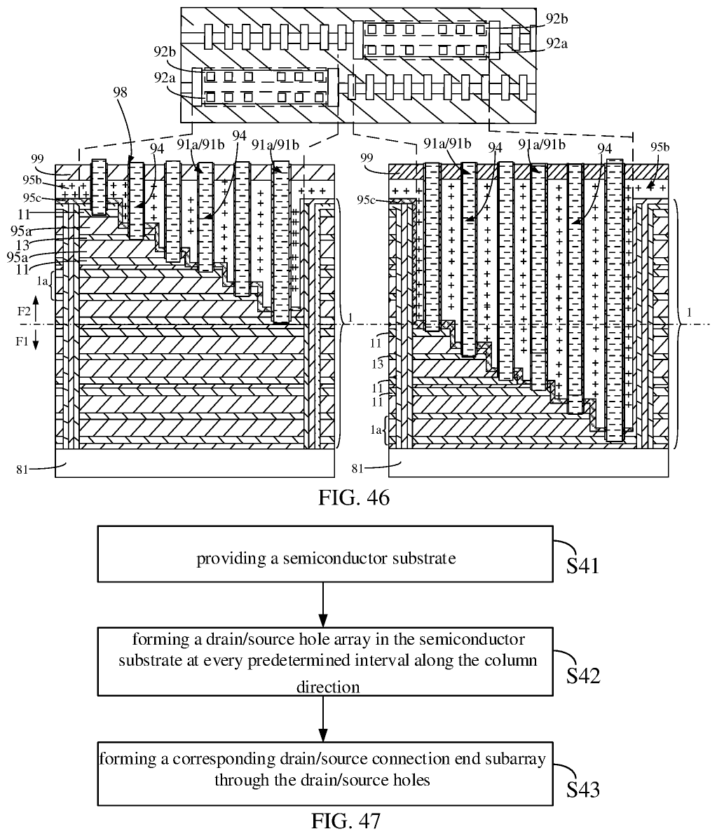

Referring to FIG. 45 and FIG. 46, FIG. 46 is a schematic view of a first drain/source connection terminal group 92a and a second drain/source connection terminal group 92b of a drain/source connection terminal array 9a, each connected to a corresponding drain/source region semiconductor strip 11/13 according to an embodiment of the present disclosure. Each drain/source connection terminal array 9 includes multiple first-type drain/source connection terminal subarrays and multiple second-type drain/source connection terminal subarrays alternately distributed along the row direction X. In the embodiments, as shown in FIG. 45 and FIG. 46, the drain/source connection terminal subarray 9a above along the column direction Y in the same drain/source connection terminal array 9 may be a first-type drain/source connection terminal subarray, while the drain/source connection terminal subarray 9a below may be a second-type drain/source connection terminal subarray. The first-type drain/source connection terminal subarray is connected drain/source region semiconductor strips 11/13 in a low zone F1 of a corresponding column of semiconductor strip structures 1b, and the second-type drain/source connection terminal subarray is connected to drain/source region semiconductor strips 11/13 in a high zone F2 of a corresponding column of semiconductor strip structures 1b, and the two above-mentioned columns may be the same or different.

Each drain/source connection terminal subarray 9a of the multiple first-type drain/source connection terminal subarrays and the second-type drain/source connection terminal subarrays includes a first drain/source connection terminal group 92a and a second drain/source connection terminal group 92b. As shown in FIG. 46, the multiple drain/source connection terminals 91a/91b in the first drain/source connection terminal group 92a are each connected to a part of a drain/source region semiconductor strip 11/13 in a corresponding column of semiconductor strip structures 1b by a corresponding drain/source connection plug 94; and the multiple drain/source connection terminals 91a/91b in the second drain/source connection terminal group 92b are each connected to a part of a drain/source region semiconductor strip 11/13 in an adjacent column of semiconductor strip structures 1b by a corresponding drain/source connection plug 94. Each drain/source connection terminal 91a/91b in the first drain/source connection terminal group 92a corresponds to a drain/source connection plug 94; and each drain/source connection terminal 91a/91b in the second drain/source connection terminal group 92b corresponds to a drain/source connection plug 94.

The multiple drain/source connection terminals 91a/91b in the first drain/source connection terminal group 92a of the first-type drain/source connection terminal subarray correspond to the drain/source region semiconductor strips 11/13 of the low zone F1 of one of the two corresponding adjacent columns of semiconductor strip structures 1b; and the multiple drain/source connection terminals 91a/91b in the first drain/source connection terminal group 92a are connected to the drain/source region semiconductor strips 11/13 of the low zone F1 of the corresponding column of semiconductor strip structures 1b by multiple drain/source connection plugs 94. Each drain/source connection terminal 91a/91b of the first drain/source connection terminal group 92a corresponds to a drain/source connection plug 94. It will be understood by those skilled in the art that an exposed part of the drain/source connection plugs 94 may serve as the corresponding drain/source connection terminal 91a/91b.

Those skilled in the art can understand that the same drain/source region semiconductor strip 11/13 in any of the above-mentioned columns of semiconductor strip structures 1b corresponds to multiple corresponding drain/source connection terminals 91a/91b in a corresponding column of one or more drain/source connection terminal arrays 9. For example, in conjunction with FIG. 43, the second column of semiconductor strip structures 1b corresponds to two drain/source connection terminal arrays 9 (a first drain/source connection terminal array 9 and a second drain/source connection terminal array 9), and first drain region semiconductor strips 11 in the column of semiconductor strip structures 1b are correspondingly connected to a drain connection terminal 91a of the first drain/source connection terminal array 9 of the corresponding column in the column direction Y, and correspondingly connected to a drain connection terminal 91a of the second drain/source connection terminal arrays 9 of the corresponding column in the column direction Y.

In this way, each drain/source region semiconductor strip 11/13 can be connected to multiple drain/source connection terminals 91a/91b, such that a part of each drain/source region semiconductor strip 11/13 that is at corresponding positions of two adjacent drain/source connection terminals 91a/91b may directly transmit signals through the drain/source connection terminals 91a/91b at the corresponding positions, for performing read (RD), program (PGM), and other operations; compared with leading through a connection line at the end of each drain/source region semiconductor strip 11/13 (i.e., the edge portion of the memory block 10) and performing related operations of the entire drain/source region semiconductor strip 11/13 through the connection line, the resistance may be reduced to facilitate signal transmission and improve the speed of read (RD), program (PGM), and other operations of the memory block 10 in the present disclosure.

The multiple drain/source connection terminals 91a/91b of the second drain/source connection terminal group 92b in the first-type drain/source connection terminal subarray correspond to the drain/source region semiconductor strips 11/13 of the low zone F1 of the other of the two corresponding adjacent columns of semiconductor strip structures 1b; and the multiple drain/source connection terminals 91a/91b in the second drain/source connection terminal group 92b are connected the drain/source region semiconductor strips 11/13 of the low zone F1 of the other of the two corresponding adjacent columns of semiconductor strip structures 1b through multiple drain/source connection plugs 94.

It should be noted that the drain/source region semiconductor strips 11/13 of the low zone F1 and the high zone F2 of the column of semiconductor strip structures 1b involved in the present disclosure may be divided by a middle layer of the column of semiconductor strip structures 1b as a dividing line. For example, when the column of semiconductor strip structures 1b corresponds to eight layers of memory subarray layer 1a, the drain/source region semiconductor strips 11/13 of the low zone F1 of the column of semiconductor strip structures 1b refers to the drain/source region semiconductor strip 11/13 corresponding to the fifth memory subarray layer 1a to the eighth memory subarray layer 1a counting from top to bottom, and the drain/source region semiconductor strip 11/13 of the high zone F2 of the column of semiconductor strip structures 1b refers to the drain/source region semiconductor strips 11/13 corresponding to the first memory subarray layer 1a to the fourth memory subarray layer 1a from top to bottom.

The multiple drain/source connection terminals 91a/91b in the first drain/source connection terminal group 92a of the second-type drain/source connection terminal subarray correspond to the drain/source region semiconductor strips 11/13 of the high zone F2 of one of the two corresponding adjacent columns of semiconductor strip structures 1b; and the multiple drain/source connection terminals 91a/91b in the first drain/source connection terminal group 92a are connected to the drain/source region semiconductor strips 11/13 of the high zone F2 of the corresponding column of semiconductor strip structures 1b by multiple drain/source connection plugs 94. Each drain/source connection terminal 91a/91b of the first drain/source connection terminal group 92a corresponds to a drain/source connection plug 94.

The multiple drain/source connection terminals 91a/91b of the second drain/source connection terminal group 92b in the second-type drain/source connection terminal subarray correspond to the drain/source region semiconductor strips 11/13 of the high zone F2 of the other of the two corresponding adjacent columns of semiconductor strip structures 1b; and the multiple drain/source connection terminals 91a/91b in the second drain/source connection terminal group 92b are connected the drain/source region semiconductor strips 11/13 of the high zone F2 of the other of the two corresponding adjacent columns of semiconductor strip structures 1b through multiple drain/source connection plugs 94. Each drain/source connection terminal 91a/91b of the second drain/source connection terminal group 92b corresponds to a drain/source connection plug 94.

For example, in conjunction with FIG. 44, the drain/source connection terminal array 9 includes a first-type drain/source connection terminal subarray, a second-type drain/source connection terminal subarray, and a first-type drain/source connection terminal subarray alternately distributed along the row direction X. Therein, from left to right, the multiple drain/source connection terminals 91a/91b in the first drain/source connection terminal group 92a of the first first-type drain/source connection terminal subarray are correspondingly connected to the drain/source region semiconductor strips 11/13 of the low zone F1 of the first column of semiconductor strip structures 1b; the multiple drain/source connection terminals 91a/91b in the second drain/source connection terminal group 92b of the first first-type drain/source connection terminal subarray are correspondingly connected to the drain/source region semiconductor strips 11/13 of the low zone F1 of the second column of semiconductor strip structures 1b. For the first second-type drain/source connection terminal subarray adjacent to the first first-type drain/source connection terminal subarray, the multiple drain/source connection terminals 91a/91b in the first drain/source connection terminal group 92a of the first second-type drain/source connection terminal subarray are correspondingly connected to the drain/source region semiconductor strips 11/13 of the high zone F2 of the second column of semiconductor strip structures 1b; the multiple drain/source connection terminals 91a/91b in the second drain/source connection terminal group 92b of the first second-type drain/source connection terminal subarray are correspondingly connected to the drain/source region semiconductor strips 11/13 of the high zone F2 of the third column of semiconductor strip structures 1b.

In other embodiments, referring further to FIG. 45, the multiple drain/source connection terminal arrays 9 includes multiple first-type drain/source connection terminal arrays and multiple second-type drain/source connection terminal arrays alternately distributed along the column direction Y in the same column. In the embodiments, as shown in FIG. 45, the upper drain/source connection terminal arrays 9 may be the first-type drain/source connection terminal arrays, and the lower drain/source connection terminal arrays 9 may be the second-type drain/source connection terminal arrays.

The first drain/source connection terminal group 92a in each drain/source connection terminal subarray 9a of each first-type drain/source connection terminal array (e.g., an upper drain/source connection terminal array 9) is configured to be connected to drain/source region semiconductor strips 11/13 of the low zone F1 in a corresponding column of semiconductor strip structures 1b. The second drain/source connection terminal group 92b in each drain/source connection terminal subarray 9a of each first-type drain/source connection terminal array is configured to be connected to drain/source region semiconductor strips 11/13 of the low zone F1 in another adjacent corresponding column of semiconductor strip structures 1b. That is, each drain/source connection terminal group 92a/92b in the same drain/source connection terminal array 9 is configured to be connected to drain/source region semiconductor strips 11/13 of either the low zone F1 or the high zone F2.

The first drain/source connection terminal group 92a in each drain/source connection terminal subarray 9a in each second-type drain/source connection terminal array (e.g., the lower drain/source connection terminal array 9) is configured to be connected to drain/source region semiconductor strips 11/13 of the high zone F2 in a corresponding column of semiconductor strip structures 1b; the second drain/source connection terminal group 92b in each drain/source connection terminal subarray 9a in each second-type drain/source connection terminal array is configured to be connected to drain/source region semiconductor strips 11/13 of the high zone F2 in another adjacent corresponding column of semiconductor strip structures 1b.

It will be understood by those skilled in the art that each of the drain/source connection terminal groups 92a/92b in one of the two adjacent drain/source connection terminal arrays 9 is configured to be connected to the drain/source region semiconductor strip 11/13 of the low zone F1; each of the drain/source connection terminal groups 92a/92b in the other drain/source connection terminal array 9 is configured to be connected to the drain/source region semiconductor strips 11/13 of the high zone F2.

As described above, in the above embodiments of the present disclosure, the drain/source region semiconductor strips 11/13 in each column of semiconductor strip structures 1b are connected to the drain/source connection terminals 91a/91b in corresponding two adjacent drain/source connection terminal subarrays 9a distributed in the row direction X, respectively; and/or, the drain/source region semiconductor strips 11/13 in each column of semiconductor strip structures 1b are connected to the drain/source connection terminals 91a/91b in corresponding two adjacent drain/source connection terminal subarrays 9a distributed in the column direction Y, respectively.

Of course, in other embodiments, it will be understood by those skilled in the art that each drain/source connection terminal subarray 9a in the drain/source connection terminal array 9 may have other designs as long as the drain/source connection terminals 91a/91b in the drain/source connection terminal subarray 9a may lead out the drain/source region semiconductor strips 11/13 in each corresponding column of semiconductor strip structures 1b.

For example, in some embodiments, each drain/source connection terminal array 9 includes multiple drain/source connection terminal subarrays 9a distributed in the X direction, each drain/source connection terminal subarray 9a including a first drain/source connection terminal group 92a and a second drain/source connection terminal group 92b, where multiple drain/source connection terminals 91a/91b in the first drain/source connection terminal group 92a correspond to drain/source region semiconductor strip 11/13 of the low zone F1 of one of corresponding two adjacent columns of semiconductor strip structures 1b; and multiple drain/source connection terminals 91a/91b in the second drain/source connection terminal group 92b corresponding to drain/source region semiconductor strips 11/13 of the high zone F2 of the other of the corresponding two adjacent columns of semiconductor strip structures 1b.

It will be understood by those skilled in the art that the above embodiments are merely examples, and that those skilled in the art may reasonably design based on the above principles.

Furthermore, it will be understood by those skilled in the art that the drain/source region semiconductor strips 11/13 corresponding to the high zone F2 and the low zone F1 may be selected to be connected to either drain/source connection terminal 91a/91b, as long as all of the drain/source region semiconductor strips 11/13 (S/D) are led out. For example, in the second drain/source connection terminal group 92b, the drain/source connection terminals 91a/91b may be connected to the drain/source region semiconductor strips 11/13 in the 1st, 5th, 6th, and 8th memory subarray layers 1a of a column of semiconductor strip structures 1b; while in the first drain/source connection terminal group 92a, the drain/source connection terminals 91a/91b may be connected to the drain/source region semiconductor strips 11/13 in the 2nd, 3rd, 4th, and 7th memory subarray layers 1a of a column of semiconductor strip structures 1b. The present disclosure is not limited in this respect.

Referring further to FIG. 46, the exposed parts of the drain/source connection plug 94 may serve as the drain/source connection terminals 91a/91b. In some embodiments, to further increase the signal transmission speed, the drain/source connection plug 94 may be made of a material with a much less resistance than the drain/source region semiconductor strip 11/13. For example, the drain/source connection plug 94 may be made of any one or more of four metals: copper/titanium/tin/tungsten.

In order to prevent the contact between the channel semiconductor strip 12 and the drain/source connection plug 94 from causing a short circuit, a first insulating material 95a (as described in FIG. 53 below and related descriptions) may be arranged between the drain/source connection plugs 94 and the channel semiconductor strips 12, and the first insulating material 95a may be made of silicon oxide.

Further, in order to save the photomask and lead out the drain/source region semiconductor strips 11/13 at different heights in each column of the semiconductor strip structures 1b, as shown in FIG. 46, in each column of semiconductor strip structures 1b, positions of the drain/source region semiconductor strips 11/13 configured to be connected to the drain/source connection terminal subarray 9a are distributed in a step-like manner from top to bottom. In this way, each layer of first insulating material 95a and the corresponding drain/source region semiconductor strip 11/13 of the high zone F2 and the low zone F1 are at least partially exposed relative to the first insulating material 95a and drain/source region semiconductor strip 11/13 in the upper layer.

The first insulating material 95a is arranged between the adjacent drain region semiconductor strip 11 and the source region semiconductor strip 13. A filling material 95b and a second hard mask layer 99 are arranged on the step-like drain/source region semiconductor strips 11/13. The second hard mask layer 99 is disposed on a side surface of the filling material 95b away from the column of semiconductor strip structures 1b. Drain/source connection terminal holes 98 are defined in the filling material 95b, and each drain/source connection terminal hole 98 is filled with a conductive material to form the drain/source connection terminal 91a/91b and the drain/source connection plug 94. Since polycrystalline silicon has better fillability, the filling material 95b may be selected from polycrystalline silicon. When the filling material 95b is made of polysilicon, an insulating layer 95c may be further arranged on the step-like drain/source region semiconductor strips 11/13 and the filling material 95b is specifically arranged on the insulating layer 95c. It is understood by those skilled in the art that when the filling material 95b is made of an insulating material, such as silicon oxide, it is not necessary to form the insulating layer 95c on the step-like drain/source region semiconductor strips 11/13 and it is sufficient to fill the filling material 95b directly; in this case, a spacing dielectric layer on a side wall of the drain/source connection terminal hole 98 is not necessarily arranged.

It can be understood that the drain/source connection plug 94 is specifically inserted in the filling material 95b and extends to a surface of the corresponding drain/source region semiconductor strip 11/13 to be connected with it. The drain/source connection terminals 91a/91b are specifically disposed in the second hard mask layer 99 and are exposed through a side surface of the second hard mask layer 99 away from the filling material 95b. The position of a drain/source connection terminal 91a/91b corresponds to the position of a corresponding drain/source connection plug 94.

Specifically, as shown in FIG. 45, among the multiple gate strips 2, each gate strip in the column and the gate strip in the adjacent column are staggered in the row direction X. For example, each gate strip 2 in the first column and each gate strip 2 in the second column are staggered from each other in the column direction Y. Of course, each gate strip 2 in the same column and a corresponding gate strip 2, in an adjacent column, corresponding to the gate strip 2 in the row direction X, may be aligned with each other in the column direction Y. The staggered arrangement reduces the influence of the electric field between the corresponding two gate strips 2 in adjacent columns.

Specifically, further referring to FIG. 45, multiple isolation walls 3 distributed along the column direction Y are arranged on each of two sides of each column of semiconductor strip structures 1b. Each isolation wall 3 extends along the height direction Z to the substrate 81 to separate at least a part of two adjacent columns of semiconductor strip structures 1b. Each isolation wall 3 of each column of isolation walls 3, and a corresponding isolation wall 3, in an adjacent column, are staggered from each other in the column direction Y. For example, each isolation wall 3 of the multiple isolation walls 3 of the first column and each isolation wall 3 of the multiple isolation walls 3 of the second column are staggered from each other in the column direction Y. Of course, each isolation wall 3 of the multiple isolation walls 3 in each column may be aligned with a corresponding isolation wall 3, in an adjacent column, corresponding to the isolation wall 3 in the row direction X.

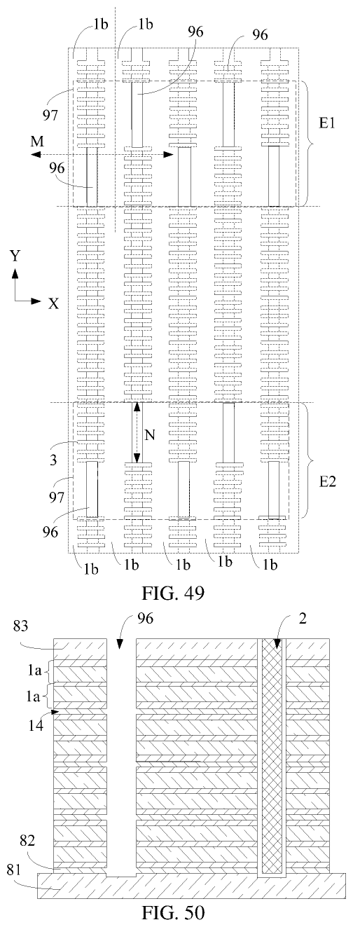

Specifically, in conjunction with FIG. 45 and FIG. 46, multiple drain/source holes 96 may be defined on the memory array 1 at a predetermined interval along the column direction Y (referring to FIGS. 49 and 50 below). Specifically, each drain/source hole 96 may be defined at a position of the memory array 1 distinct from the isolation wall 3 and the gate strip 2 to avoid the first insulating material 95a within the drain/source hole 96 from affecting the signal transmission of the drain/source region semiconductor strip 11/13.

Specifically, as shown in FIG. 46 and FIG. 49, the first drain/source connection terminal group 92a and the second drain/source connection terminal group 92b in the drain/source connection terminal subarray 9a corresponding to two adjacent columns of semiconductor strip structures 1b share the same drain/source hole 96.

The memory block 10 in the embodiments is provided by arranging a drain/source connection terminal array 9 at a predetermined interval in the column direction Y; each drain/source connection terminal array 9 includes multiple drain/source connection terminal subarrays 9a, each drain/source connection terminal subarray 9a corresponding to two adjacent columns of semiconductor strip structures 1b. Each drain/source connection terminal subarray 9a includes multiple drain/source connection terminals 91a/91b, and each drain/source connection terminal 91a/91b is connected to a drain/source region semiconductor strip 11/13 in a corresponding column of semiconductor strip structures 1b, respectively. Each drain/source connection terminal 91a/91b in each drain/source connection terminal subarray 9a is connected to a corresponding drain/source region semiconductor strip 11/13 in a corresponding column of semiconductor strip structures 1b; that is, the same drain/source region semiconductor strip 11/13 of any column of semiconductor strip structures 1b of the memory block 10 is connected to multiple corresponding drain/source connection terminals 91a/91b of multiple corresponding drain/source connection terminals 9a of corresponding columns of one or more drain/source connection terminal arrays 9. In this way, a part of the same drain/source region semiconductor strip 11/13 that is between two adjacent drain/source connection terminals 91a/91b may perform read (RD), program (PGM), and other operations directly through the drain/source connection terminals 91a/91b at corresponding positions. In contrast to leading through a connection line at the end of each drain/source region semiconductor strip 11/13 (i.e., the edge portion of the memory block 10) and performing related operations of the entire drain/source region semiconductor strip 11/13 through the connection line in the related art, the resistance may be reduced to facilitate signal transmission and improve the read (RD), program (PGM), and other operations of the memory block 10 in the present disclosure. In addition, by making the drain/source connection plug 94 made of any one or more of the four metals, copper/titanium/tin/tungsten, with better electrical conductivity, the effect of the resistance of the drain/source connection plug 94 on the signal transmission speed may be reduced.

In addition, the memory block 10 as shown in the above embodiments is arranged with multiple drain/source connection terminal arrays 9, each of which includes multiple drain/source connection terminal subarrays 9a, to achieve connection of the drain/source region semiconductor strips 11/13 in each column of the semiconductor strip structures 1b to the multiple drain/source connection terminals 91a/91b in the multiple drain/source connection terminal subarrays 9a, respectively, thereby achieving improvement of electrical performance.

However, it will be understood by those skilled in the art that the memory block 10 of the present disclosure may be arranged with only one drain/source connection terminal array 9, which may include multiple drain/source connection terminal subarrays 9a, to achieve connection of the drain/source region semiconductor strips 11/13 in each column of the semiconductor strip structures 1b to one drain/source connection terminal 9a/9b in one drain/source connection terminal subarray 9a. Therein, the drain/source connection terminal array 9 may be arranged at a non-edge position of the column of semiconductor strip structures 1b in the column direction Y, i.e., at a position of the column of semiconductor strip structures 1b in the column direction Y that is distinct from the first end and the last end. Since the drain/source connection terminal array 9 may be arranged at a position of the middle region of the column of semiconductor strip structures 1b in the column direction Y, its provision of the drain/source lead region relative to the edge also improves the electrical performance, reduces the resistance, facilitates the signal transmission, and improves the speed of the read (RD), programming (PGM), and other operations performed by the memory block 10.

Specifically, the memory block 10 corresponding to FIGS. 43 to 46 can be made by the following manufacturing method.

Referring to FIG. 47, FIG. 47 is a flowchart of a manufacturing method of a memory block according to further another embodiment of the present disclosure. The manufacturing method includes operations at blocks illustrated herein.

At step S41: providing a semiconductor substrate.

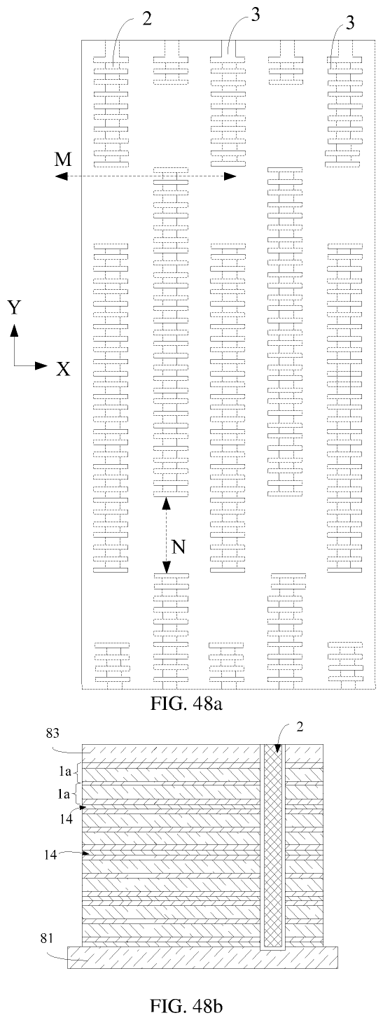

Referring to FIG. 48a and FIG. 48b, FIG. 48a is a top view of a semiconductor substrate according to an embodiment of the present disclosure; and FIG. 48b is a cross-sectional view of the semiconductor substrate shown in FIG. 48a along line M. The semiconductor substrate includes a substrate 81, multiple memory subarray layers 1a formed on the substrate 81, and a first hard mask layer 83 arranged on a side surface of the multiple memory subarray layers 1a away from the substrate 81.

The multiple memory subarray layers 1a are sequentially stacked along a height direction Z perpendicular to the substrate 81. Each memory subarray layer 1a includes a drain region semiconductor layer, a channel semiconductor layer, and a source region semiconductor layer stacked along the height direction Z. The drain region semiconductor layer, channel semiconductor layer, and source region semiconductor layer in each memory subarray layer 1a include multiple drain region semiconductor strips 11, channel semiconductor strips 12, and source region semiconductor strips 13, respectively, distributed along a row direction X. Each drain region semiconductor strip 11, channel semiconductor strip 12, and source region semiconductor strip 13 extends along a column direction Y, respectively. Multiple gate strips 2 distributed in the column direction Y are arranged between two adjacent columns of drain region semiconductor strips 11, channel semiconductor strips 12, and source region semiconductor strips 13, and each gate strip 2 extends along the height direction Z.

Multiple isolation walls 3 and multiple gate strips 2 may be further arranged on the semiconductor substrate, the multiple isolation walls 3 and multiple gate strips 2 extending along the height direction Z to the substrate 81, respectively. Other specific structures and manufacturing methods of the semiconductor substrate can be described in the specific structures and manufacturing methods of the memory block provided in any of the above embodiments, which will not be repeated herein.

At step S42: forming a drain/source hole array in the semiconductor substrate at every predetermined interval along the column direction.

Referring to FIG. 49 to FIG. 50, FIG. 49 is a top view of defining drain/source holes 96 in the semiconductor substrate; FIG. 50 is a cross-sectional view of the semiconductor substrate shown in FIG. 49 along line M. Specifically, multiple drain/source holes 96 may be defined in the semiconductor substrate by etching at positions distinct from the gate strips 2 and the isolation walls 3; that is, the semiconductor substrate is not arranged with the isolation walls 3 at positions corresponding to the drain/source holes 96 to leave specific regions for defining the drain/source holes 96. Each drain/source hole 96 extends along the height direction Z to the substrate 81, and multiple gate strips 2, multiple isolation walls 3, and multiple drain/source holes 96 of multiple drain/source hole arrays 97 in the same column form a spacing structure. Along the row direction X, multiple spacing structures are distributed for dividing each memory subarray layer 1a into multiple columns of drain region semiconductor strips 11, channel semiconductor strips 12, and source region semiconductor strips 13 along the row direction X. A column of drain region semiconductor strips 11, channel semiconductor strips 12, and source region semiconductor strips 13 in the multiple memory subarray layers 1a is defined as a column of semiconductor strip structures 1b.

Specifically, multiple drain/source holes 96 in each drain/source holes array 97 distributed along the row direction X are aligned with each other in the column direction Y. Alternatively, as shown in FIG. 49, for the multiple drain/source holes 96 in each drain/source holes array 97 distributed along the row direction X, two adjacent drain/source holes 96 are staggered with each other in the column direction Y. Based on this staggered arrangement, an overall high resistance caused by the column of semiconductor strip structures 1b being too narrow in localized places may be avoided.

In some embodiments, multiple drain/source holes 96 may be defined in the semiconductor substrate at intervals of N rows of memory cells to form multiple drain/source holes arrays 97; that is, N rows of memory cells may be arranged between two adjacent regions of the memory cells, such as regions E1 and E2. N may be a natural number greater than or equal to 1. In other embodiments, M rows of memory cells are arranged between two adjacent drain/source holes 96 in the same column, and M may be a natural number greater than or equal to 1. Of course, the distance between each adjacent two regions along the column direction Y may be unequal, i.e., the multiple drain/source holes array 97 may be arranged at non-equal spacing. Alternatively, some of the regions are arranged equally spaced between each adjacent two regions, and the remaining part of the regions are arranged non-equally spaced between each adjacent two regions.

In some embodiments, in the same region (e.g., E1), two adjacent columns (e.g., the first and second columns) of semiconductor strip structures 1b share the same drain/source hole 96. Another drain/source hole 96 is also defined in two adjacent columns (e.g., the first and second columns) of semiconductor strip structures 1b in a region E2 of the semiconductor substrate spaced at a predetermined distance L from region E1.

In conjunction with FIG. 49, in the same row region (e.g., E1), either column of semiconductor strip structures 1b shares a drain/source hole 96 with the left column of semiconductor strip structures 1b, relative to the left column of semiconductor strip structures 1b, and shares another drain/source hole 96 with the right column of semiconductor strip structures 1b, relative to the right column of semiconductor strip structures 1b. That is, for either column of semiconductor strip structures 1b, in the same horizontal region, a left part thereof shares one drain/source hole 96 with one column of semiconductor strip structures 1b, and a right part thereof shares another drain/source hole 96 with another column of semiconductor strip structures 1b.

As shown in FIG. 49, in some embodiments, memory cells in the column of semiconductor strip structures 1b at the edge do not function as storage and are used as virtual memory cells. As described above, the column of semiconductor strip structure 1b at the edge shares the same drain/source hole 96 with the adjacent column of semiconductor strip structures 1b to make the corresponding drain/source connection terminal subarray 9. Therefore, the drain/source connection terminal subarray 9a may include only drain/source connection terminals 91a/91b corresponding to a non-edge column of semiconductor strip structures 1b, and drain/source connection terminals 91a/91b corresponding to the non-edge column of semiconductor strip structures 1b will be led out. Of course, it is understood by those skilled in the art that, in order to ensure the consistency of the manufacturing process of the drain/source connection terminal subarray 9a, the drain/source connection terminal subarray 9a may further include drain/source connection terminals 91a/91b corresponding to the column of semiconductor strip structures 1b at the edges, and a part of the drain/source region semiconductor strips 11/13 of the non-edge column of semiconductor strip structures 1b is led out. The drain/source connection terminals 91a/91b corresponding to the column of semiconductor strip structures 1b at the edges may not be connected to the connection line and are not involved in the actual storage operation.

At step S43: forming a corresponding drain/source connection terminal subarray through the drain/source holes.

Each drain/source hole 96 correspondingly forms a corresponding drain/source connection terminal subarray 9a, and multiple drain/source connection terminal subarrays 9a correspondingly formed by multiple drain/source holes 96 in each drain/source hole array 97 constitute a drain/source connection terminal array 9, and each drain/source connection terminal subarray 9a includes multiple drain/source connection terminals 91a/91b. Each drain/source connection terminal 91a/91b is configured to be connected to a corresponding drain/source region semiconductor strip 11/13 of a corresponding column of semiconductor strip structures 1b.

The same drain/source region semiconductor strip 11/13 in each column of semiconductor strip structures 1b is connected to multiple drain/source connection terminals 91a/91b of multiple drain/source connection terminal subarrays 9a in multiple drain/source connection terminal arrays 9.

The same drain/source region semiconductor strip 11/13 in each column of semiconductor strip structures 1b is correspondingly connected to multiple corresponding drain/source connection terminals 91a/91b of multiple corresponding drain/source connection terminal subarrays 9a in corresponding columns in the multiple drain/source connection terminal arrays 9, thereby reducing resistance, facilitating signal transmission, and increasing the speed of this memory block 10 for read (RD), programming (program. PGM) and other operations.

Referring to FIGS. 51-FIG. 60, FIGS. 51-FIG. 60 illustrate structural schematic views of specific processes of step S43.

In some embodiments, as shown in FIG. 48b, a first single-crystal sacrificial semiconductor layer 82 or a virtual memory subarray layer is epitaxially grown on the substrate 81 of the semiconductor substrate; two memory subarray layers 1a and a second single-crystal sacrificial semiconductor layer 14 are formed on the first single-crystal sacrificial semiconductor layer 82 by epitaxial growth alternately in sequence until uppermost two memory subarray layers 1a are formed; or the second single-crystal sacrificial semiconductor layer 14 and the two memory subarray layers 1a are formed by epitaxial growth alternately in sequence on the virtual memory subarray layer; during the formation of the gate strips 2 through the word line holes 4, a part of the first single-crystal sacrificial semiconductor layer 82 and/or the second single-crystal sacrificial semiconductor layer 14 is replaced with an insulating barrier layer through the word line holes 4.

In some embodiments, step S43 specifically includes the following.

Step S431: removing a remaining part of the first single-crystal sacrificial semiconductor layer 82 and/or the second single-crystal sacrificial semiconductor layer 14 by the drain/source holes 96, as shown in FIG. 51. After removing the remaining part of the first single-crystal sacrificial semiconductor layer 82 and/or the second single-crystal sacrificial semiconductor layer 14, multiple first filling slots 14b are defined.

Step S432: etching parts of the channel semiconductor strips 12 in the columns of semiconductor strip structures 1b through the drain/source holes 96 to remove the parts of the channel semiconductor strips 12 and expose parts of the drain/source region semiconductor strips 11/13.

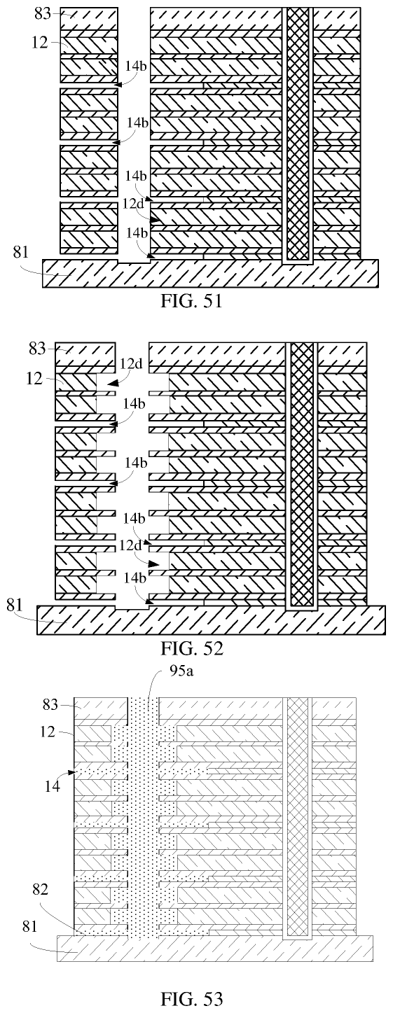

The specific process of step S432 can be referred to the specific process of step A involved in the above embodiments and can achieve the same or similar technical effect. The structure of the product after processing by step S432 can be seen in FIG. 52, which is a schematic view of the structure shown in step S56 after partial removal of the channel semiconductor strips 12. The space defined after partial removal of the channel semiconductor strips 12 are defined hereinafter as second filling slots 12d.

Step S433: filling a first insulating material 95a in the drain/source holes 96 to cover the exposed channel semiconductor strips 12.

As shown in FIG. 53, FIG. 53 is a schematic view of the structure after filling the first insulating material 95a in the drain/source holes 96. In some embodiments, the region where the remaining parts after removal of the first single-crystal sacrificial semiconductor layer 82 and the second single-crystal sacrificial semiconductor layer 14 were located (i.e., the first filling slots 14b) is filled with the first insulating material 95a to replace the remaining parts of the first single-crystal sacrificial semiconductor layer 82 and the second single-crystal sacrificial semiconductor layer 14 with the first insulating material 95a. In addition, each of the second filling slots 12d is filled with the first insulating material 95a to cover the exposed part of the channel semiconductor strips 12, thereby isolating the channel semiconductor strips 12 from the drain region semiconductor strips 11 and the source region semiconductor strips 13 by the first insulating material 95a filled in the second filling slots 12d.

In some embodiments, after step S433, the method may further include: thinning the first hard mask layer 83. For example, the first hard mask layer 83 may be thinned by chemical mechanical polishing.

Step S434: etching a drain/source connection terminal subarray region corresponding to each drain/source hole 96 to form a step-like structure.

The step-like structure includes multiple steps, each step including a part of a corresponding drain/source region semiconductor strip 11/13. The formation of the step-like structure facilitates the subsequent formation of the drain/source connection plugs 94 to connect the corresponding drain/source region semiconductor strips 11/13.

As shown in FIG. 58, the step-like structure formed by the etched drain/source connection terminal subarray region corresponding to the drain/source hole 96 will form the drain/source connection terminals of the high zone F2 and low zone F1 in the drain/source hole 96.

In some embodiments, the drain/source connection terminal subarray region corresponding to the drain/source hole 96 is etched, the drain/source region semiconductor strips 11/13 in the step-like structure may be all drain/source region semiconductor strips 11/13 of the low zone F1 or all drain/source region semiconductor strips 11/13 of the high zone F2. For example, in a second drain/source end group 92b, the drain/source ends 91a/91b may be connected to a drain/source region semiconductor strip 11/13 of the low zone F1 of a column of semiconductor strip structures 1b; and in a first drain/source end group 92a, the drain/source ends 91a/91b may be connected to a drain/source region semiconductor strip 11/13 of the low zone F1 of another column of semiconductor strip structures 1b. Alternatively, in a second drain/source end group 92b, the drain/source ends 91a/91b may be connected to a drain/source region semiconductor strip 11/13 of the high zone F2 of a column of semiconductor strip structures 1b; and in a first drain/source connection terminal group 92a, the drain/source connection terminals 91a/91b may be connected to a drain/source region semiconductor strip 11/13 of the high zone F2 of another column of semiconductor strip structures 1b.

In other embodiments, some of the drain/source region semiconductor strips 11/13 in the step-like structure are drain/source region semiconductor strips 11/13 of the low zone F1 and the others are drain/source region semiconductor strips 11/13 of the high zone F2. That is, the drain/source region semiconductor strip 11/13 corresponding to the high zone F2 and the low zone F1 may be connected to either drain/source connection 91a/91b selectively, as long as all the drain/source region semiconductor strips 11/13 (S/D) are led out. For example, in the second drain/source connection terminal group 92b, the drain/source connection terminals 91a/91b may be connected to the drain/source region semiconductor strips 11/13 in the 1st, 5th, 6th, and 8th memory subarray layers 1a of a column of semiconductor strip structures 1b; while in the first drain/source connection terminal group 92a, the drain/source connection terminals 91a/91b may be connected to the drain/source region semiconductor strips 11/13 in the 2nd, 3rd, 4th, and 7th memory subarray layers 1a of a column of semiconductor strip structures 1b.

The following is an example of forming the step-like structure shown in FIG. 58, in which the drain/source connection terminals of the high zone F2 and the low zone F1 are formed in the drain/source hole 96. There are various methods to form the step-like structure shown in FIG. 58, and it is only required to adjust the lithography and etching processes. One of the embodiments is shown below.

Step S434 specifically includes the following.

Step A′: removing parts of the first insulating material 95a and the drain/source region semiconductor strip 11/13 in the high zone F2 of the drain/source connection terminal subarray region corresponding to the drain/source hole 96.

Referring to FIG. 54, FIG. 54 is a schematic view of the structure of the semiconductor substrate after removal of parts of the first insulating material 95a and the drain/source region semiconductor strip 11/13 in the high zone F2 of the drain/source hole 96. The first insulating material 95a and the drain/source region semiconductor strip 11/13 may be removed by etching to expose the first insulating material 95a of the low zone F1.

The drain/source connection terminal subarray region of the first insulating material 95a and the drain/source region semiconductor strip 11/13 of the high zone F2 being a first-type drain/source connection terminal subarray region is removed, and the drain/source connection terminal subarray region of the first insulating material 95a and the drain/source region semiconductor strip 11/13 of the high zone F2 being a second-type drain/source connection terminal subarray region is not removed.

Step B′: simultaneously performing multi-step etching on the first insulating material 95a and the drain/source region semiconductor strip 11/13 of the low zone F1 in the first-type drain/source connection terminal subarray region, and the first insulating material 95a and the drain/source region semiconductor strip 11/13 of the high zone F2 in the second-type drain/source connection terminal subarray region, to form the step-like structure.

Each step-like structure includes multiple steps, each step including a part of a corresponding drain/source region semiconductor strip 11/13 and a part of the first insulating material 95a wrapping the part of the drain/source region semiconductor strip 11/13. Each step of the high zone F2 and the low zone F1 extends at least partially relative to a previous step.

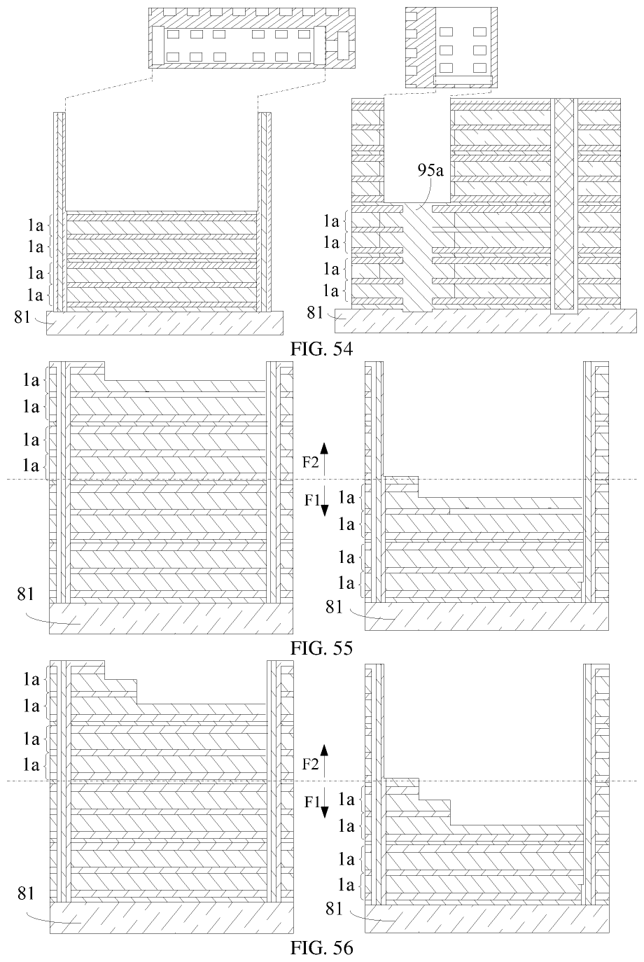

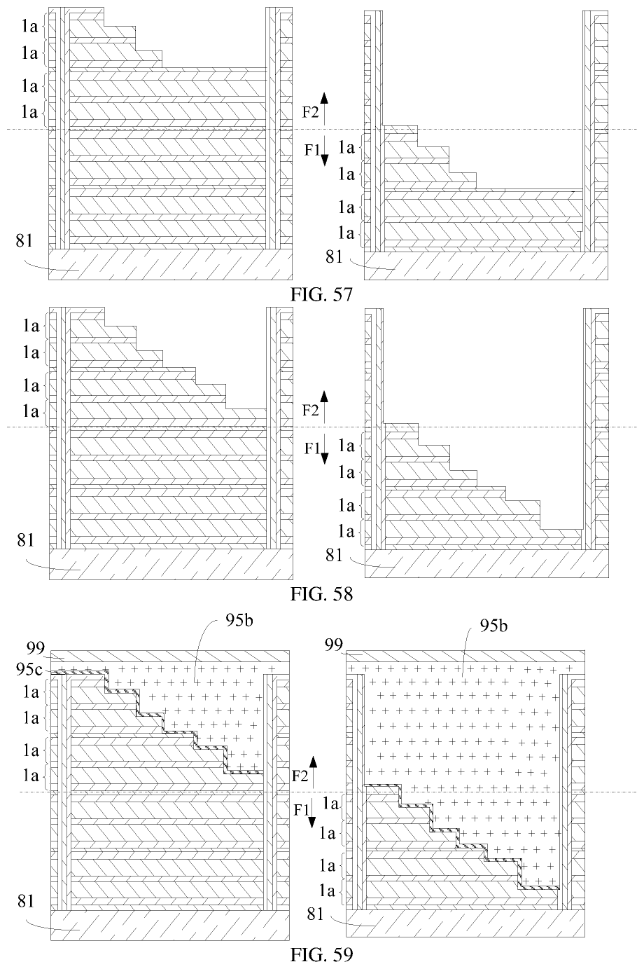

In some embodiments, referring to FIGS. 55-58, FIGS. 55-58 illustrate structural schematic views of specific processes for multi-step etching of the structure shown in FIG. 54. The semiconductor substrate including eight memory subarray layers 1a, with two adjacent memory subarray layers 1a including sequentially stacked drain region semiconductor layer, channel semiconductor layer, source region semiconductor layer, channel semiconductor layer, and drain region semiconductor layer to share the same source region semiconductor layer, is taken as an example. As shown in FIG. 55, the first insulating material 95a and the drain/source region semiconductor strip 11/13 of the low zone F1 of the semiconductor substrate, and the first insulating material 95a and the drain/source region semiconductor strip 11/13 of the high zone F2 of the semiconductor substrate are etched simultaneously using a first mask to form a first step. Afterwards, as shown in FIG. 56, the first insulating material 95a and the drain/source region semiconductor strip 11/13 of the low zone F1, and the first insulating material 95a and the drain/source region semiconductor strip 11/13 of the high zone F2 of the structure shown in FIG. 55 are simultaneously etched for a second time using a second mask to form a second step. Then, as shown in FIG. 57, the first insulating material 95a and the drain/source region semiconductor strip 11/13 of the low zone F1, and the first insulating material 95a and the drain/source region semiconductor strip 11/13 of the high zone F2 in the structure shown in FIG. 56 are simultaneously etched for a third time using a third mask to form a third step. In this way, fourth and fifth etchings are continued to be executed using different masks to form a step-like structure with six steps as shown in FIG. 58.

It will be understood by those skilled in the art that the present disclosure requires a total of six etching steps (one step in step A′ and five steps in step B′) to form the six-step step-like structure.

It is understood by those skilled in the art that if the drain/source region semiconductor strips 11/13 in the eight memory subarray layers 1a are etched in a step-like manner without dividing the low zone F1 and high zone F2, 11 steps are required to be formed since the same column of drain/source region semiconductor strips of the eight memory subarray layers 1a include 12 drain/source region semiconductor strips 11/13, i.e., 11 steps of etching are required. Therefore, the above method of the present disclosure can simplify the process steps and reduce the preparation cost.

Among them, the specific process of photomask etching is the same or similar to the related art, which can be found in the related art and will not be repeated herein. The structure of the product after step S434 can be shown in FIG. 59, where each layer of the first insulating material 95a and the drain/source region semiconductor strip 11/13 in each of the high zone F2 and the low zone F1 is at least partially exposed with respect to the first insulating material 95a and the drain/source region semiconductor strip 11/13 in the previous layer.

Step S435: filling the step-like structure with a filling material 95b, and forming a second hard mask layer 99 on the filling material 95b.

The structure of the product after processing by step S435 can be seen in FIG. 59, which is a schematic view of the structure filled with a filling material 95b in the structure shown in FIG. 58 and forming a second hard mask layer 99 on the filling material 95b. Since polycrystalline silicon has better fillability, the filling material 95b may be selected from polycrystalline silicon. When the filling material 95b is selected to be made of polysilicon, before step S435, the method may further include: depositing an insulating layer 95c on the step-like structure such that the insulating layer 95c wraps around an end of a part of the drain region/source region semiconductor strip 11/13 in the step-like structure, thereby preventing leakage problems between the filling material 95b and the step-like structure. Of course, the filling material 95b may be made of an insulating material, such as silicon oxide. It is understood by those skilled in the art that when the filling material 95b is made of an insulating material, depositing an insulating layer 95c on the step-like structure becomes an optional step.

Step S436: defining multiple drain/source connection terminal holes 98 in each drain/source connection terminal subarray region, and filling each drain/source connection terminal hole with a conductive material to form a drain/source connection plug.

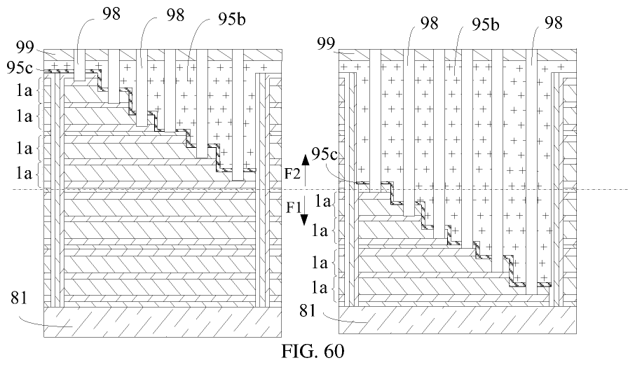

Referring to FIG. 60, FIG. 60 is a schematic view of the structure with multiple drain/source connection terminal holes 98 defined on the structure shown in FIG. 59. Each drain/source connection terminal hole 98 extends from a side surface of the second hard mask layer 99 away from the filling material 95b to the surface of a corresponding drain/source region semiconductor strip 11/13.

In some embodiments, when the filling material 95b is selected to be made of polycrystalline silicon, after the defining the multiple drain/source connection terminal holes 98 and before the filling with the conductive material, step S436 may further include: forming a spacing dielectric layer on a side wall of each drain/source connection terminal hole 98. In other words, the spacing dielectric layer is formed on the side wall of the drain/source connection terminal hole 98 before filling the filling material 95b. It is understood by those skilled in the art that when the filling material 95b is made of an insulating material, such as silicon oxide, then forming the spacing dielectric layer on the surface of the side wall of each drain/source connection terminal hole 98 becomes an optional step, and only filling the drain/source connection terminal hole 98 directly with the filling material 95b is sufficient.

Apart of the drain/source connection plug 94 exposed outside of the second hard mask layer 99 may serve as the drain/source connection terminal 91a/91b. An end of each drain/source connection plug 94 is connected to a corresponding drain/source region semiconductor strip 11/13 in a step-like structure. In the embodiments, the drain/source connection terminal subarray region with the first insulating material 95a and the drain/source region semiconductor strip 11/13 of the high zone F2 removed is the first-type drain/source connection terminal subarray region; the drain/source connection terminal subarray region without the first insulating material 95a and the drain/source region semiconductor strip 11/13 of the high zone F2 removed is the second-type drain/source connection terminal subarray region. Multiple drain/source connection terminals 91a/91b formed in the first-type drain/source connection terminal subarray region constitute the first-type drain/source connection terminal subarray, configured to be connected to the drain/source region semiconductor strips 11/13 of the low zone F1 (such as the drain/source region semiconductor strips 11/13 corresponding to the 5th-8th memory subarray layer 1a), respectively; multiple drain/source connection terminals 91a/91b formed in the second-type drain/source connection terminal subarray region constitute the second-type drain/source connection terminal subarray, configured to be connected to the drain/source region semiconductor strips 11/13 of the high zone F2 (such as the drain/source region semiconductor strips 11/13 corresponding to the 1st-4th memory subarray layer 1a), respectively. It is understood that the column of semiconductor strip structures 1b in which a corresponding drain/source region semiconductor strip 11/13 of the high zone F2 is located is in the same column as the column of semiconductor strip structures 1b in which a corresponding drain/source region semiconductor strip 11/13 of the low zone F1 is located.

In the manufacturing method of a memory block provided by the embodiments of the present disclosure, multiple drain/source holes 96 are defined on the semiconductor substrate at a predetermined interval along the column direction Y, and multiple drain/source connection terminal subarrays 9a are formed through the drain/source holes 96; each drain/source hole 96 correspondingly forms a corresponding drain/source connection terminal subarray 9a, and multiple drain/source connection terminal arrays 9a formed corresponding to multiple drain/source apertures 96 in each drain/source hole array 97 constitute a drain/source connection terminal array 9; each drain/source connection terminal subarray 9a includes multiple drain/source connection terminals 91a/91b, each drain/source connection terminal 91a/91b being configured to be connected to a corresponding drain/source region semiconductor strip 11/13 in a corresponding column of semiconductor strip structures 1b; that is, the same drain/source region semiconductor strip 11/13 in each column of semiconductor strip structures 1b is correspondingly connected to multiple corresponding drain/source connection terminals 91a/91b of multiple corresponding drain/source connection terminals subarray 9a in multiple corresponding columns in multiple drain/source connection terminal arrays 9, such that a part of the same drain/source region semiconductor strip 11/13 that is between two adjacent drain/source connection terminals 91a/91b may directly transmit signals through the drain/source connection terminals 91a/91b at the corresponding positions, for performing read (RD), program (PGM), and other operations; compared with leading through a connection line at the end of each drain/source region semiconductor strip 11/13 (i.e., the edge portion of the memory block 10) and performing related operations of the entire drain/source region semiconductor strip 11/13 through the connection line, the resistance may be reduced to facilitate signal transmission and improve the read (RD), program (PGM), and other operations of the memory block 10 in the present disclosure.

The above is only some embodiments of the present disclosure, and is not intended to limit the scope of the present disclosure. Any equivalent structure or equivalent process transformation using the contents and the accompanying drawings of the present disclosure, or any direct or indirect application in other related technical fields, is included in the scope of the present disclosure.

What is claimed is:

1. A memory block, comprising:
a memory array, comprising: a plurality of memory cells distributed in a three-dimensional array; wherein the memory array comprises a plurality of memory subarray layers stacked sequentially along a height direction, and each memory subarray layer comprises a drain region semiconductor layer, a channel semiconductor layer, and a source region semiconductor layer stacked along the height direction; in each memory subarray layer, the drain region semiconductor layer comprises a plurality of drain region semiconductor strips distributed along a row direction, the channel semiconductor layer comprises a plurality of channel semiconductor strips distributed along the row direction, and the source region semiconductor layer comprises a plurality of source region semiconductor strips distributed along the row direction; each drain region semiconductor strip, each channel semiconductor strip, and each source region semiconductor strip extend along a column direction; a plurality of gate strips distributed along the column direction are arranged on each side of each column drain region semiconductor strip, channel semiconductor strip, and source region semiconductor strip, each gate strip extending along the height direction; in the plurality of memory subarray layers, the plurality of drain region semiconductor strips, the plurality of channel semiconductor strips, and the plurality of source region semiconductor strips, that are disposed in a same column, are defined as a column of the semiconductor strip structures; and
a plurality of drain/source connection terminal arrays; wherein each of the plurality of drain/source connection terminal arrays is arranged at a predetermined interval in the column direction; each drain/source connection terminal array comprises a plurality of drain/source connection terminal subarrays arranged along the row direction, and each drain/source connection terminal subarray comprises a plurality of drain/source connection terminals; each drain/source connection terminal is connected to a corresponding drain/source region semiconductor strip of a corresponding column of the semiconductor strip structures, wherein the corresponding drain/source region semiconductor strip is a corresponding drain region semiconductor strip or a corresponding source region semiconductor strip;
wherein in each column of the semiconductor strip structures, a same drain/source region semiconductor strip is connected to several of the plurality of drain/source connection terminals of several of the plurality of drain/source connection terminal subarrays of several of the plurality of drain/source connection terminal arrays.

2. The memory block according to claim 1, wherein,
each drain/source connection terminal subarray corresponds to two adjacent columns of the semiconductor strip structures, and comprises a first drain/source connection terminal group and a second drain/source connection terminal group;
wherein the first drain/source connection terminal group comprises a plurality of first drain/source connection terminals, each configured to be connected to a corresponding drain/source region semiconductor strip of one of the two adjacent columns of the semiconductor strip structures; the second drain/source connection terminal group comprises a plurality of second drain/source connection terminals, each configured to be connected to a corresponding drain/source region semiconductor strip of the other of the two adjacent columns of the semiconductor strip structures.

3. The memory block according to claim 2, wherein,
each drain/source connection terminal array comprises a plurality of first-type drain/source connection terminal subarrays and a plurality of second-type drain/source connection terminal subarrays alternately distributed along the row direction;
wherein the first drain/source connection terminal group of each first-type drain/source connection terminal subarray is configured to be connected to a plurality of the drain/source region semiconductor strips in a low zone of one of the two adjacent columns of the semiconductor strip structures; the second drain/source connection terminal group of each first-type drain/source connection terminal subarray is configured to be connected to a plurality of the drain/source region semiconductor strips in a low zone of the other of the two adjacent columns of the semiconductor strip structures;
wherein the first drain/source connection terminal group of each second-type drain/source connection terminal subarray is configured to be connected to a plurality of the drain/source region semiconductor strips in a high zone of one of the two adjacent columns of the semiconductor strip structures; the second drain/source connection terminal group of each second-type drain/source connection terminal subarray is configured to be connected to a plurality of the drain/source region semiconductor strips in a high zone of the other of the two adjacent columns of the semiconductor strip structures.

4. The memory block according to claim 2, wherein,
the plurality of drain/source connection terminal arrays comprise a plurality of first-type drain/source connection terminal arrays and a plurality of second-type drain/source connection terminal arrays alternately distributed along the column direction in a same column;
wherein the first drain/source connection terminal group of each drain/source connection terminal subarray of each first-type drain/source connection terminal array is configured to be connected to a plurality of the drain/source region semiconductor strips in a low zone of one of the two adjacent columns of the semiconductor strip structures; the second drain/source connection terminal group of each drain/source connection terminal subarray of each first-type drain/source connection terminal array is configured to be connected to a plurality of the drain/source region semiconductor strips in a low zone of the other of the two adjacent columns of the semiconductor strip structures;
wherein the first drain/source connection terminal group of each drain/source connection terminal subarray of each second-type drain/source connection terminal array is configured to be connected to a plurality of the drain/source region semiconductor strips in a high zone of one of the two adjacent columns of the semiconductor strip structures; the second drain/source connection terminal group of each drain/source connection terminal subarray of each second-type drain/source connection terminal array is configured to be connected to a plurality of the drain/source region semiconductor strips in a high zone of the other of the two adjacent columns of the semiconductor strip structures.

5. The memory block according to claim 1, wherein the memory block satisfies at least one of:
the drain/source region semiconductor strips of each column of the semiconductor strip structures are respectively connected to several of the plurality of drain/source connection terminals of two adjacent drain/source connection end subarrays in the row direction; and
the drain/source region semiconductor strips of each column of the semiconductor strip structures are respectively connected to several of the plurality of drain/source connection ends of two adjacent drain/source connection end subarrays in the column direction.

6. The memory block according to claim 1, wherein,
the plurality of drain/source connection terminal subarrays, distributed in the row direction, of each drain/source connection terminal array are aligned with each other in the column direction; or
each adjacent two of the plurality of drain/source connection terminal subarrays, distributed in the row direction, of each drain/source connection terminal array are staggered with each other in the column direction.

7. The memory block according to claim 1, wherein,
the plurality of gate strips in adjacent two columns are staggered in the row direction; or
the plurality of gate strips in adjacent two columns are aligned in the row direction.

8. The memory block according to claim 1, wherein,
a plurality of isolation walls distributed along the column direction are arranged on each of two sides of each column of the semiconductor strip structures; each isolation wall extends along the height direction to a substrate to separate at least parts of two corresponding adjacent columns of the semiconductor strip structures.

9. The memory block according to claim 2, wherein,
the first drain/source connection terminal group and the second drain/source connection terminal group in each drain/source region connection terminal subarray share a same drain/source hole.

10. The memory block according to claim 1, wherein,
the plurality of drain/source semiconductor strips are distributed in a step-like manner from top to bottom in positions of the plurality of drain/source connection terminal subarrays in each column of semiconductor strip structures; an insulating layer is arranged on the plurality of the drain/source region semiconductor strips that are step-like, and a filling material is arranged on the insulating layer; the filling material comprises a polysilicon filling material.

11. The memory block according to claim 1, wherein each drain region semiconductor strip, channel semiconductor strip, and source region semiconductor strip comprises a body structure and a plurality of protrusions arranged and spaced on two sides of the body structure; each protrusion extends in the column direction from the body structure toward a corresponding gate strip in a direction deviating from the body structure.

12. A memory block, comprising:
a memory array, comprising: a plurality of memory cells distributed in a three-dimensional array; wherein the memory array comprises a plurality of memory subarray layers stacked sequentially along a height direction, and each memory subarray layer comprises a drain region semiconductor layer, a channel semiconductor layer, and a source region semiconductor layer stacked along the height direction; in each memory subarray layer, the drain region semiconductor layer comprises a plurality of drain region semiconductor strips distributed along a row direction, the channel semiconductor layer comprises a plurality of channel semiconductor strips distributed along the row direction, and the source region semiconductor layer comprises a plurality of source region semiconductor strips distributed along the row direction; each drain region semiconductor strip, each channel semiconductor strip, and each source region semiconductor strip extend along a column direction; a plurality of gate strips distributed along the column direction are arranged on each side of each column drain region semiconductor strip, channel semiconductor strip, and source region semiconductor strip, each gate strip extending along the height direction; in the plurality of memory subarray layers, the plurality of drain region semiconductor strips, the plurality of channel semiconductor strips, and the plurality of source region semiconductor strips, that are disposed in a same column, are defined as a column of the semiconductor strip structures; and
a drain/source connection terminal array, comprising a plurality of drain/source connection terminal subarrays; wherein each drain/source connection terminal subarray comprises a plurality of drain/source connection terminals arranged along the row direction; each drain/source connection terminal is connected to a corresponding drain/source region semiconductor strip of a corresponding column of the semiconductor strip structures, wherein the corresponding drain/source region semiconductor strip is a corresponding drain region semiconductor strip or a corresponding source region semiconductor strip.

13. The memory block according to claim 12, wherein,
the drain/source connection terminal array is arranged at a non-edge position of the corresponding column of the semiconductor strip structures in the column direction.

14. A manufacturing method of a memory block, comprising:
providing a semiconductor substrate; wherein the semiconductor substrate comprises a substrate and a plurality of memory subarray layers formed on the substrate; each memory subarray layer comprises a drain region semiconductor layer, a channel semiconductor layer, and a source region semiconductor layer stacked along a height direction; wherein a plurality of isolation walls and a plurality of gate strips are arranged on the semiconductor substrate, each isolation wall and each gate strip extending along the height direction to the substrate;
forming a plurality of drain/source hole arrays in the semiconductor substrate at a predetermined interval along a column direction; wherein each drain/source hole array comprises a plurality of drain/source holes distributed along a row direction, each drain/source hole extending along the height direction to the substrate; the plurality of gate strips, the plurality of isolation walls, and the plurality of drain/source holes of a plurality of the drain/source hole arrays, that are in the same column, form a spacing structure; along the row direction, a plurality of the spacing structures are distributed for dividing each memory subarray layer into a plurality of columns of drain region semiconductor strips, channel semiconductor strips, and source region semiconductor strips along the row direction; in the plurality of memory subarray layers, some of the plurality of drain region semiconductor strips, some of the plurality of channel semiconductor strips, and some of the plurality of source region semiconductor strips, that are disposed in a same column, are defined as a column of semiconductor strip structures; and
forming a corresponding drain/source connection terminal subarray through several of the plurality of drain/source holes; wherein each drain/source hole correspondingly forms a corresponding drain/source connection terminal subarray, and a plurality of the drain/source connection terminal subarrays correspondingly formed by several of the plurality of drain/source holes in each drain/source hole array constitute a drain/source connection terminal array; each drain/source connection terminal subarray comprises a plurality of drain/source connection terminals, each drain/source connection terminal is configured to be connected to a corresponding drain/source region semiconductor strip of a corresponding column of the semiconductor strip structures, wherein the corresponding drain/source region semiconductor strip is a corresponding drain region semiconductor strip or a corresponding source region semiconductor strip;
wherein in a same column of the semiconductor strip structures, each drain/source region semiconductor strip is connected to several of the plurality of drain/source connection terminals of several of the plurality of drain/source connection terminal subarrays of several of the plurality of drain/source connection terminal arrays.

15. The manufacturing method according to claim 14, wherein,
the plurality of drain/source hole subarrays, distributed in the row direction, of each drain/source hole array are aligned with each other in the column direction; or
each adjacent two of the plurality of drain/source hole subarrays, distributed in the row direction, of each drain/source hole array are staggered with each other in the column direction.

16. The manufacturing method according to claim 14, wherein,
the forming a corresponding drain/source connection terminal subarray through several of the plurality of drain/source holes comprises:
etching parts of the plurality of channel semiconductor strips in a corresponding column of the semiconductor strip structures through the several of the plurality of drain/source holes, to remove the parts of plurality of the channel semiconductor strips and expose parts of a plurality of the drain/source region semiconductor strips;
filling a first insulating material in each drain/source hole to cover exposed parts of plurality of the channel semiconductor strips;
etching a drain/source connection terminal subarray region corresponding to each drain/source hole to form a step-like structure;
filling a filling material on the step-like structure, and forming a second hard mask layer on the filling material; and
defining a plurality of drain/source connection terminal holes in the drain/source connection terminal subarray region, and filling each drain/source connection terminal hole with a conductive material to form a drain/source connection plug; wherein a part of the drain/source connection plug exposed outside the second hard mask is configured as a corresponding drain/source connection terminal, and each drain/source connection plug is connected to a corresponding drain/source region semiconductor strip of a corresponding column of the semiconductor strip structures.

17. The manufacturing method according to claim 16, wherein each step-like structure comprises a plurality of steps, each step comprising a part of a corresponding drain/source region semiconductor strip;
the plurality of drain/source region semiconductor strips in the step-like structure are all drain/source region semiconductor strips in a low zone or all drain/source region semiconductor strips in a high zone; or
some of the plurality of drain/source region semiconductor strips in the step-like structure are drain/source region semiconductor strips of the low zone, and the others of the plurality of drain/source region semiconductor strips in the step-like structure are drain/source region semiconductor strips of the high zone.

18. The manufacturing method according to claim 16, wherein the etching a drain/source connection terminal subarray region corresponding to each drain/source hole to form a step-like structure comprises:
removing parts of the first insulating material and the plurality of drain/source region semiconductor strips in a high zone of the drain/source connection terminal subarray region corresponding to the drain/source hole; wherein the drain/source connection terminal subarray region where parts of the first insulating material and the plurality of drain/source region semiconductor strips of the high zone are removed is a first-type drain/source connection terminal subarray region, and the drain/source connection terminal subarray region where the first insulating material and the plurality of drain/source region semiconductor strips of the high zone are not removed is a second-type drain/source connection terminal subarray region; and
simultaneously performing multi-step etching on the first insulating material and the plurality of drain/source region semiconductor strips in a low zone in the first-type drain/source connection terminal subarray region, and the first insulating material and the plurality of drain/source region semiconductor strips of the high zone in the second-type drain/source connection terminal subarray region, to form the step-like structure; wherein the step-like structure comprises a plurality of steps, each step comprising a part of a corresponding drain/source region semiconductor strip and a part of the first insulating material wrapping the part of the corresponding drain/source region semiconductor strip; each step of the high zone and the low zone extends at least partially relative to an upper step;
wherein the first-type drain/source connection terminal subarray region and the second-type drain/source connection terminal subarray region formed with the step-like structure are filled with the filling material; the plurality of drain/source connection terminal holes are defined on each of the first-type drain/source connection terminal subarray region and the second-type drain/source connection terminal subarray region; the plurality of drain/source connection terminals formed in the first-type drain/source connection terminal subarray region constitute a first-type drain/source connection terminal subarray, and the plurality of drain/source connection terminals formed in the second-type drain/source connection terminal subarray region constitute a second-type drain/source connection terminal subarray.

19. The manufacturing method according to claim 16, wherein,
a first single-crystal sacrificial semiconductor layer or a virtual memory subarray layer is epitaxially grown on the substrate of the semiconductor substrate; two memory subarray layers and a second single-crystal sacrificial semiconductor layer are formed on the first single-crystal sacrificial semiconductor layer by epitaxial growth alternately in sequence until uppermost two memory subarray layers are formed; or the second single-crystal sacrificial semiconductor layer and the two memory subarray layers are formed by epitaxial growth alternately in sequence on the virtual memory subarray layer; during a formation of the plurality of gate strips through a plurality of word line holes, a part of the first single-crystal sacrificial semiconductor layer and/or the second single-crystal sacrificial semiconductor layer is replaced with an insulating isolation layer through the plurality of word line holes;
wherein before the etching parts of the plurality of channel semiconductor strips in a corresponding column of the semiconductor strip structures through the plurality of drain/source holes, the method further includes:
removing a remaining part of the first single-crystal sacrificial semiconductor layer and/or the second single-crystal sacrificial semiconductor layer through the plurality of drain/source holes;
when performing the filling a first insulating material in each drain/source hole to cover exposed parts of plurality of the channel semiconductor strips, the method further includes:
filling a region where the removed remaining parts of the first single-crystal sacrificial semiconductor layer and the second single-crystal sacrificial semiconductor layer were located with the first insulating material, to replace the remaining parts of the first single-crystal sacrificial semiconductor layer and the second single-crystal sacrificial semiconductor layer with the first insulating material.

20. The manufacturing method according to claim 16, wherein the filling material comprises a polysilicon;
before the filling a filling material on the step-like structure, and forming a second hard mask layer on the filling material, the method further comprises:
depositing an insulating layer on the step-like structure, such that the insulating layer covers an end of a part of the plurality of drain region/source region semiconductor strips in the step-like structure.
